(19) United States
(12) Patent Application Publication
(10) Pub. No.: US 2008/0251874 A1
(43) Pub. Date: Oct. 16, 2008

(54) Solid-state image capturing Device, method for the same, and electronic information device

(75) Inventor: Shouichi Ishibe, Fukuyama-shi (JP)

Correspondence Address: Edwards Angell Palmer & Dodge LLP, P.O.Box 55874, Boston, MA, 02205, US

(73) Assignee: Sharp Kabushiki Kaisha, Osaka (JP)

(21) Appl. No.: 12/076,773

(22) Filed: Mar. 21, 2008

(30) Foreign Application Priority Data
Mar. 22, 2007 (JP) 2007-074998

(51) Int. Cl. H01L 31/0232; H01L 31/18

(52) U.S. Cl. 257/432; 438/70; 257/E31.127

(57) ABSTRACT

A solid-state image capturing device according to the present invention is provided, in which a plurality of conductive films is formed via respective insulation films, and an optical waveguide is formed above a light receiving section, a plurality of light receiving sections is provided in a surface portion of a semiconductor substrate, and the plurality of conductive films is formed on a region other than a region right above the light receiving section, wherein a plural-layered optical waveguide tube is formed as the optical waveguide, with the same material as at least one of the plural-layered conductive films.

This Nonprovisional Application claims priority under 35 U.S.C. §119(a) on Patent Application 2007-074998 filed in Japan on Mar. 22, 2007, the entire contents of which are hereby incorporated by reference.

### BACKGROUND OF THE INVENTION

1. Field of the Invention

The present invention relates to: a solid-state image capturing device (e.g., CMOS image sensor, CCD image sensor and the like) where an optical waveguide region is formed on each of the plurality of light receiving sections formed on a semiconductor substrate; a method for manufacturing the solid-state image capturing device; and an electronic information device using the solid-state image capturing apparatus as an image capturing section.

2. Description of the Related Art

A conventional solid-state image capturing device is known to have a structure in which an interlayer insulation film is processed on each of the light receiving sections that are a plurality of photoelectric conversion sections for each converting a light of subject into signal charge and an optical waveguide region is formed to have a well structure above each of the light receiving sections, thereby enhancing the light focusing efficiency upon a light receiving section region.

An exemplary specific structure of a conventional solid-state image capturing device having such an optical waveguide structure will be described with reference to FIG. 11.

FIG. 11 is a longitudinal cross-sectional view showing an exemplary essential structure of a conventional solid-state image capturing device 100. It should be noted that FIG. 11 shows a structure of a single light receiving section and a peripheral portion around the light receiving section in a CMOS image sensor that is the conventional solid-state image capturing device 100.

In the conventional solid-state image capturing device 100 in FIG. 11, a plurality of light receiving sections 102, such as photodiodes each functioning as a photoelectric conversion section, is formed in two dimensions in a surface layer of a semiconductor substrate 101. In addition, gate electrode films 104 that are lead electrodes are provided to be adjacent to a portion above the light receiving section 102 and on the surface of the semiconductor substrate 101 via a gate insulation film 103.

A plurality of interlayer insulation films 106 (first insulation film 106a, second insulation film 106b, third insulation film 106d, fourth insulation film 106e) and a plurality of wiring layers 107 (first wiring layer 107a, second wiring layer 107b, third wiring layer 107c) are formed above the gate electrode film 104 to have a sandwich structure. More specifically, the first insulation film 106a is formed above the gate electrode film 104 that is located over the semiconductor substrate 101. The first wiring layer 107a is formed on the first insulation film 106a. The second insulation film 106b is formed on the first wiring layer 107a. The second wiring layer 107b is formed on the second insulation film 106b. In a similar manner, the third insulation film 106c, the third wiring layer 107c and the fourth insulation film 106d are sequentially formed in this order over the second wiring layer 107b.

In addition, contact plugs 105 (first contact plug 105a, second contact plug 105b, third contact plug 105c) each made from a conductive material are formed between the wiring layers 107 and the semiconductor substrate 101 (not shown), between the wiring layer 107 and the gate electrode film 104 and between the wiring layers 107 to electrically connect between the wiring layers 107 and the semiconductor substrate 101, between the wiring layer 107 and the gate electrode film 104 and between the wiring layers 107. In some cases, the contact plugs 105 are formed using the same material as that for the wiring layers 107. In other cases, the contact plugs 105 are formed using a different material using such as tungsten, for example, when the wiring layers 107 are formed using aluminum.

Further, color filters 108 having red (R) color, green (G) color and blue (B) color that are arranged for respective light receiving sections 102 are formed on the fourth insulation film 106d. A fifth insulation film 106e is formed on the color filters 108. Microlenses 109 for focusing light upon the respective light receiving sections are formed on the fifth insulation films 106e. The fourth insulation film 106d is formed as a planarization film prior to the formation of a passivation film and color filter. The fifth insulation film 106e is formed as a planarization film prior to the formation of microlens.

Further, according to the conventional solid-state image capturing device 100, an opening (hole for forming a waveguide) for becoming an optical waveguide is formed between the fourth insulation film 106d and a stopper layer 110 located at the top surface side of the first insulation film 106a right above the light receiving section 102. Waveguide films 111 (first optical waveguide film 111a, second optical waveguide film 111b, third optical waveguide film 111a) are formed to fill the inside of the opening for the purpose of light propagation. In this case, the first optical waveguide film 111a and the second optical waveguide film 111b are formed inside the hole for forming the waveguide, and the first optical waveguide film 111a and the second optical waveguide film 111b at the bottom of the hole for forming the waveguide is removed by etching to expose the surface of the stopper layer 110. Thereafter, the third optical waveguide film 111e is filled in the hole for forming the waveguide where the first optical waveguide film 111a and the second optical waveguide film 111b are formed on the side wall of the hole.

With the structure described above, light of a subject, which is focused upon microlenses 109, is guided into optical waveguide films 111 from the fourth insulation film 106d via color filters 108 having respective colors, and it is guided toward light receiving section side via the optical waveguide films 111.

Each of References 1-7 will be described here.

Reference 1 proposes a conventional solid-state image capturing device, in which a portion above a light receiving section is dug to form an opening after a planarization film is formed, and transparent films having a high refractive index inside the opening are multiply embedded to form an optical waveguide. This solid-state image capturing device intends to enhance light focusing efficiency by its optical waveguide structure. The transparent films each having a high refractive index here correspond to the optical waveguide films 111 in FIG. 11.

Reference 2 proposes a conventional solid-state image capturing device, in which a layer having concave lens structure is provided between a light receiving section and the upper most surface layer, a well-like excavated structure is provided at the bottom portion of the concave lens structure, and an etching stopper film is formed at the bottom portion of the well-like excavated structure. The etching stopper film here corresponds to a stopper layer 110 provided in the bottom portion of a hole for forming an optical waveguide in FIG. 11.

Reference 3 proposes a conventional solid-state image capturing device having an optical waveguide structure with improved efficiencies for total reflection of light and wavelength dependency in order to increase a focusing efficiency therein. In this structure, a waveguide of an optical waveguide region is configured with materials with different refractive indices, guiding a light into a light receiving section by refraction of light. This optical waveguide structure corresponds to a first optical waveguide film 111a, a second optical waveguide 111b and a third optical waveguide film 111c in FIG. 11.

Reference 4 proposes a conventional solid-state image capturing device which has a columnar single-layered structure as an optical waveguide structure with the intention of improved focusing efficiency and miniaturization.

References 5 and 6 propose a conventional solid-state image capturing device, in which crystal defects due to metal diffusion generated at the time of processing an optical waveguide structure is inhibited to improve characteristics of a light receiving section. For example, in the method for manufacturing a conventional solid-state image capturing device described in Reference 5, crystal defects due to metal diffusion generated at the time of processing an optical waveguide structure is inhibited by forming hydrogen-containing plasma silicon nitride films and performing an annealing process in a hydrogen atmosphere. Further, an etching stopper film is also provided in regions other than a light receiving section, so that the penetration of hydrogen is prevented thus improving characteristics of a light receiving section. In addition, with respect to a conventional solid-state image capturing device disclosed in Reference 6, a predetermined interval is provided between an end of the optical waveguide region at a light receiving section side and a light receiving surface on the light receiving section.

Reference 7 proposes a conventional solid-state image capturing device with an optical waveguide structure having a space provided therein for relieving stress as well as reducing a leakage current and crack.

Next, FIGS. 12-15 describe in detail respective steps of manufacturing an insulation film 106, a contact plug 105 and a wiring layer 107 according to a method for manufacturing a conventional solid-state image capturing device 100 in FIG. 11.

FIGS. 12-15 are each a top view describing a step of manufacturing the conventional solid-state image capturing devices.

As shown in FIG. 12, subsequent to the formation of the gate electrode film 104, first, the first insulation film 106a is grown with a SiO₂ material such as BPSG (Boron Phosphor Silicate Glass) and/or high-density plasma SiO₂ (HDP-SiO₂) on the gate electrode film 104. The first insulation film 106a is formed to have the surface thereof polished by CMP (chemical mechanical polish) mainly for the purpose of planarization in order to ease the process at the next step.

Next, after the polishing of a surface of the first insulation film 106a, to form the first contact plug 105a, a photosensitive resist film is applied over the first insulation film 106a and is exposed to light and developed to have a predetermined patterned shape, and anisotropic etching is performed on the first insulation film 106a using the patterned resist film as a mask. After the etching for the first insulation film 106a, a metal film for contact plugs is grown by metal sputtering. The metal film made from tungsten, for example, for contact plugs can also be grown with CVD (Chemical vapor deposition). Additionally, a barrier metal film is sputtered prior to metal sputtering in order to prevent silicidation with the foundation. Subsequently, the entire surface of the first insulation film 106a is etched to remove the sputtered film on the first insulation film 106a to simultaneously form a first contact plug 105a embedded in a hole of the first insulation film 106a. This etching for the entire metal surface on the first insulation film 106a can be performed, for example, by polishing with CMP. FIG. 12 is a top view of the shape formed at the steps described above. FIG. 12 shows photodiodes (light receiving sections 102) and gate electrode films 104 that are not present on the same plane for the purpose of clarifying the locational relationship with the first contact plug 105a.

Further, as shown in FIG. 13, in order to form the first wiring layer 107a over the substrate having the first contact plug 105a formed thereon, a metal film is grown by metal sputtering. Thereafter photosensitive resist film is applied over the metal film and is exposed to light and developed to have a predetermined patterned shape, and anisotropic etching is performed on the metal film using the patterned photoresist film as a mask. As a result, a first wiring 107a is formed as a predetermined shape on the substrate having the first contact plug 105a formed thereon. FIG. 13 is a top view of the shape formed by the steps described above. FIG. 13 also shows photodiodes (light receiving sections 102), gate electrode films 104 and the first contact plug 105a that are not present on the same plane as the first wiring 107a for the purpose of clarifying the locational relationship with them. Further, two kinds of adjacent belt patterns are shown as the first wiring 107a.

Subsequently, a second insulation film 106b is grown with a SiO₂ material such as BPSG (Boron Phosphor Silicate Glass) and/or high-density plasma SiO₂ (HDP-SiO₂) on the substrate having the first wiring film 107a formed thereon. The second insulation film 106b is formed to have the surface thereof polished by CMP (chemical mechanical polish) mainly for the purpose of planarization in order to ease the process at the next step.

After polishing the surface of the second insulation film 106b, in order to form a second contact plug 105b, a photosensitive resist material is applied over the second insulation film 106b and is exposed to light and developed to have a predetermined patterned shape, and anisotropic etching is performed on the second insulation film 106b using the patterned resist film as a mask. After the etching, a metal film for contact plugs is grown on the second insulation film 106b by metal sputtering. The metal film made from tungsten, for example, for contact plugs can also be grown with CVD. Additionally, a barrier metal film is sputtered prior to metal sputtering in order to prevent silicidation with the foundation. Subsequently, the entire surface of the second insulation film 106b is etched to remove the sputtered film on the second insulation film 106b, so that a second contact plug 105b embedded in the second insulation film 106b remains. This etching for the entire surface on the second insulation film 106b can be performed, for example, by polishing with CMP as well. FIG. 14 shows a top view of the shape of each portion formed at the steps described above. FIG. 14 shows photodiodes (light receiving sections 102) and gate electrode films 104 that are not present on the same plane as the second contact plug 105b for the purpose of clarifying the locational relationship with it.

Further, in order to form a second wiring 1071b over the substrate having the second contact plug 105b formed thereon, a metal film is grown by metal sputtering. Thereafter photosensitive resist film is applied over the metal film and is exposed to light and developed to have a predetermined patterned shape, and anisotropic etching is performed on the metal film using the patterned resist film as a mask. As a result, a first wiring 107b is formed to have a predetermined shape on the substrate having the first contact plug 105b formed thereon. FIG. 15 is a top view of the shape formed by the steps described above. FIG. 15 also shows photodiodes (light receiving sections 102), gate electrode films 104 and the second contact plug 105b that are not present on the same plane as the first wiring 107b for the purpose of clarifying the locational relationship with them. Further, two kinds of adjacent belt patterns are shown as the first wiring 107b.

Similarly, a third insulation film 106c, a third contact plug 105c a third wiring 107a and a fourth insulation film 106d are sequentially formed.

Thereafter an opening, which will be an optical waveguide 111, is formed from the fourth insulation film 106d to a stopper layer 110 provided at the surface side of the first insulation film 106a right above the light receiving section 102. Embedding this opening (a hole), an optical waveguide 111 (a first optical waveguide film 111a to a third optical waveguide film 111c) is formed.

Subsequently, color filters 108 having respective colors arranged therewith, a fifth insulation film 106e and microlenses 109 are sequentially formed thereby manufacturing a solid-state image capturing device 100 shown in FIG. 11.

FIGS. 16 and 17 show the light focusing effect by the optical waveguide 111 described above using a ray of light. With respect to a ray of light incident from above a microlens 109 to a respective light receiving section 102 in an image capturing region, FIG. 16 shows a case where a ray of light is incident with an angle of vertical direction (light L1 from the subject) to the center of the image capturing region of the solid-state image capturing device 100. Also, FIG. 17 shows a case where a ray of light is incident with an angle of oblique direction (light L2 from the subject) to the periphery of the image capturing region of the solid-state image capturing device 100. As shown in FIGS. 16 and 17, the ray of light (light L1 and L2) incident from above the microlens 109 is propagated by total reflection or refraction in the optical waveguide 111, being directed to the light receiving section 102 and effectively focused upon the light receiving sections 102.

Reference 1: Japanese Laid-Open Publication No. 11-121725

Reference 2: Japanese Laid-Open Publication No. 2000-150845

Reference 3: Japanese Laid-Open Publication No. 2003-249633

Reference 4: Japanese Laid-Open Publication No. 2005-191396

Reference 5: Japanese Laid-Open Publication No. 2004-207433

Reference 6: Japanese Laid-Open Publication No. 2005-322824

Reference 7: Japanese Laid-Open Publication No. 2005-340498

### SUMMARY OF THE INVENTION

However, conventional solid-state image capturing devices described above have the following problems. The problems will be described with reference to FIG. 11.

There is a need for a hole for forming an optical waveguide 111 to be opened above a light receiving section 102 in order to form a region for the optical waveguide 111 above the light receiving section 102. However, because the optical waveguide 111 is conventionally reaching adjacent right above the light receiving section 102, the light receiving section 102 sustains an etching damage upon processing a hole for forming an optical waveguide thereby causing a problem of deteriorating image quality characteristics.

Although materials with high refractive indices and materials with low refractive indices are used to obtain an excellent light focusing effect and a light propagating effect by the optical waveguide 111 to the light receiving section 102, there is also a problem of deteriorating image quality characteristics due to diffusion of impurities contained in such materials.

Further, because multi-layered films are formed using a plurality of materials with high refractive indices and material with low refractive indices to obtain an excellent light focusing effect and a light propagating effect by the optical waveguide 111 to the light receiving section 102, leakage current and cracks occur due to stress thereby also causing a problem of deteriorating image quality characteristics.

Therefore, a conventional solid-state image capturing device experiences deterioration of image quality characteristics in compensation for improving light focusing efficiency through processing a hole for forming an optical waveguide.

The present invention solves such conventional problems described above. The objective of the present invention is to provide a solid-state image capturing device capable of obtaining an excellent light focusing effect and light propagating effect by an optical waveguide without conventional etching damages, contamination due to impurities of film materials, or degradation of image quality characteristics due to stress from multiple layers; a method for manufacturing a solid-state image capturing device capable of effectively forming an optical waveguide region in combination with conventional steps of processing other than steps of processing a hole for forming an optical waveguide without processing a hole for forming an optical waveguide, and an electronic information device (e.g., digital camera, cell phone device equipped with camera and the like) using the solid-state image capturing device as an image capturing section.

A solid-state image capturing device according to the present invention is provided, in which a plurality of conductive films is formed via respective insulation films, and an optical waveguide is formed above a light receiving section, a plurality of light receiving sections is provided in a top surface portion of a semiconductor substrate, and the plurality of conductive films is formed on a region other than a region right above the light receiving section, wherein a plural-layered optical waveguide tube is formed as the optical waveguide, with the same material as at least one of the plural-layered conductive films, thereby the objective described above being achieved.

A solid-state image capturing device according to the present invention is provided, in which a plurality of conductive films is formed via respective insulation films and an optical waveguide is formed above a light receiving section, a plurality of light receiving sections is provided in a top surface portion of a semiconductor substrate, the plurality of conductive films is formed on a region other than a region right above the light receiving section, wherein a single-layered or plural-layered optical waveguide tube is formed as the optical waveguide, with the same material as that of either the conductive film or a contact plug among the conductive films of the plural-layered conductive films and the contact plugs electrically connecting between the semiconductor substrate and the conductive films and/or between the conductive films, thereby the objective described above being achieved.

Preferably, in a solid-state image capturing device according to the present invention, at least one of between the semiconductor substrate and the conductive layers, and between the plural-layered conductive films is electrically connected by a contact plug made from a conductive material, and at least one of the plural-layered optical waveguide tube portions is formed using the same material as the contact plug.

Still preferably, in a solid-state image capturing device according to the present invention, a gate electrode film is formed adjacent to the light receiving section, at least one of between the semiconductor substrate and the conductive films, between the gate electrode film and the conductive films and between the plural-layered conductive films is electrically connected by a contact plug made from a conductive material, wherein at least one of the plural-layered optical waveguide tube portions is formed using the same material as the contact plug.

Still preferably, in a solid-state image capturing device according to the present invention, the plural-layered optical waveguide tube is configured by sequentially laminating the optical waveguide tube portions formed at the same time with each of the plural-layered conductive films and the contact plugs.

Still preferably, in a solid-state image capturing device according to the present invention, the plural-layered optical waveguide tube is configured by sequentially laminating the optical waveguide tube portions formed at the same time with each of the sequentially laminated conductive films and the contact plugs.

Still preferably, in a solid-state image capturing device according to the present invention, a conductive film is at least a wiring film of the wiring films and a shading film.

Still preferably, in a solid-state image capturing device according to the present invention, the conductive film is a metal film.

Still preferably, in a solid-state image capturing device according to the present invention, the conductive film is made from at least one of copper, silver, aluminum and tungsten, or the alloy thereof.

Still preferably, in a solid-state image capturing device according to the present invention, the contact plug is made from the same material as the conductive film or the contact plug is made from a metal material different from the conductive film.

Still preferably, in a solid-state image capturing device according to the present invention, inner circumference surfaces of the plural-layered optical waveguide tube portions of the optical waveguide tube are at least aligned.

Still preferably, in a solid-state image capturing device according to the present invention, outer circumference surfaces of the plural-layered optical waveguide tube portions of the optical waveguide tube are not aligned.

Still preferably, in a solid-state image capturing device according to the present invention, each of the optical waveguide tube portions is adjusted to a size of the conductive film and the contact plug in the same layer.

Still preferably, in a solid-state image capturing device according to the present invention, an inner circumference of the optical waveguide tube is circular or elliptical and an external circumference of the optical waveguide tube is circular, elliptical, squared, or rectangular in the plain view.

Still preferably, in a solid-state image capturing device according to claim the present invention, the inner circumferential surface of the optical waveguide tube becomes wider as it get closer to an opening of the optical waveguide tube.

Still preferably, in a solid-state image capturing device according to the present invention, a taper is formed at an opening of the optical waveguide tube.

Still preferably, in a solid-state image capturing device according to the present invention, the optical waveguide tube is used as a part of one of a power supply line, a control line, a clock line and a signal line that are provided together with a signal reading circuit.

Still preferably, in a solid-state image capturing device according to the present invention, the plural-layered optical waveguide portions of the optical waveguide tube are used, besides as wirings of a signal reading circuit, as a part of one of a power supply line, control line, a clock line and a signal line provided in the signal reading circuit.

Still preferably, in a solid-state image capturing device according to the present invention, one layer or a plurality of layers of the optical waveguide tube portions are insulated from another adjacent optical waveguide tube portion by an insulation film that is as thin enough to insulate as possible for every wiring, power supply line, control line, clock line and signal line provided together with the signal reading circuit, the wirings of the signal reading circuit being also used for the optical waveguide tube portions.

Still preferably, in a solid-state image capturing device according to the present invention, the insulation film is an interlayer insulation film formed between a conductive film and another conductive film different from the conductive film.

Still preferably, in a solid-state image capturing device according to the present invention, a color filter is provided on the insulation film of the upper most layer, so that respective color corresponds to each of the light receiving sections, and a planarization film is formed on the color filter before forming a microlens, and a microlens is formed on the planarization film to correspond to each of the light receiving sections.

A solid-state image capturing device manufacturing method according to the present invention is provided for forming a plural-layered conductive films via respective insulation films, and forming an optical waveguide above a light receiving section, a plurality of light receiving sections being provided in a top surface portion of a semiconductor substrate in two dimensions and the plurality of conductive films being formed on a region other than a region right above the light receiving section, the method including: a conductive film/optical waveguide tube portion forming step of forming an optical waveguide tube portion that configures a part of the optical waveguide using the same material as a single-layered conductive film or the plural-layered conductive films at the same time when at least one of the single-layered conductive film or the plural-layered conductive films is processed, thereby the objective described above being achieved.

Preferably, in a solid-state image capturing device manufacturing method according to the present invention, at least one of between the semiconductor substrate and the conductive films, and between plural-layers of the conductive films is electrically connected by a contact plug made from a conductive material, the method further includes: a contact plug/optical waveguide tube portion forming step of forming an optical waveguide tube portion with the same material as the contact plug at the same time when the contact plug is processed and formed.

Still preferably, in a solid-state image capturing device manufacturing method according to the present invention, gate electrode films are formed adjacent to the light receiving section, and at least one of between the semiconductor substrate and the conductive films, and between a plural-layers of the conductive films is electrically connected by a contact plug made from a conductive material, the method further includes: a contact plug/optical waveguide tube portion forming step of forming an optical waveguide tube portion with the same material as the contact plug at the same time when processing and forming the contact plug.

Still preferably, a solid-state image capturing device manufacturing method according to the present invention includes: a first insulation film forming step of forming a first insulation film on the semiconductor substrate having the plurality of light receiving sections formed in a surface portion thereof in two dimensions; a first contact plug/first optical waveguide tube portion forming step of forming a first contact plug and a first optical waveguide tube portion simultaneously in the first insulation film; and a first wiring film/second optical waveguide tube portion forming step of forming a first wiring film and a second optical waveguide tube portion on the first insulation film having the first contact plug and the first optical waveguide tube portion formed therein.

Still preferably, a solid-state image capturing device manufacturing method according to the present invention includes: a first insulation film forming step of forming a first insulation film on the semiconductor substrate having the plurality of light receiving sections formed in two dimensions in a surface portion thereof; a first contact plug forming step of forming a first contact plug in the first insulation film; and a first wiring film/second optical waveguide tube portion forming step of simultaneously forming a first wiring film and a second optical waveguide tube portion on the first insulation film having the first contact plug formed therein.

Still preferably, in a solid-state image capturing device manufacturing method according to the present invention, the first contact plug/first optical waveguide tube portion forming step includes: a first resist film forming step of patterning a first resist film in the first insulation film to have shapes corresponding to the first contact plug and the first optical waveguide tube portion; a first recess shape forming step of processing first recess shapes corresponding to the first contact plug and the first optical waveguide tube portion in the first insulation film using the first resist film as a mask; a first metal film coating step of coating a first metal film on the first insulation film having the first recess shape formed therein; and a step of removing the first metal film on the entire first insulation film such that the first metal film remains in the first recess so as to form the first contact plug and the first optical waveguide tube portion in the first recess.

Still preferably, in a solid-state image capturing device manufacturing method according to the present invention, the first contact plug forming step includes: a first resist film forming step of patterning a first resist film on the first insulation film to have a shape corresponding to the first contact plug; a first recess shape forming step of processing a first recess shape corresponding to the first contact plug in the first insulation film using the first resist film as a mask; a first metal film coating step of coating a first metal film in the first insulation film having the first recess shape formed therein; and a step of removing the first metal film on the entire first insulation film such that the first metal film remains in the first recess so as to form the first contact plug in the first recess.

Still preferably, in a solid-state image capturing device manufacturing method according to the present invention, the first wiring film/second optical waveguide tube portion forming step includes: a second metal film coating step of coating a second metal film on the first insulation film having the first contact plug and the first optical waveguide tube portion formed therein; a second resist film forming step of patterning a second resist film on the second metal film to have shapes corresponding to the first wiring and the second optical waveguide tube portion; and a step of forming the first wiring and the second optical waveguide tube portion from the second metal film using the second resist film as a mask.

Still preferably, in a solid-state image capturing device manufacturing method according to the present invention, the first recess shapes are a recess shape for the first contact plug and a recess shape for the first optical waveguide tube portion.

Still preferably, a solid-state image capturing device manufacturing method according to the present invention includes: a second insulation film forming step of forming a second insulation film on the substrate having the first wiring and the second optical waveguide tube portion formed thereon; a second contact plug/third optical waveguide tube portion forming step of forming a second contact plug and a third optical waveguide tube portion simultaneously in the second insulation film; and a second wiring/fourth optical waveguide tube portion forming step of forming a second wiring and a fourth optical waveguide tube portion simultaneously on the second insulation film having the second contact plug and the third optical waveguide tube portion formed therein.

Still preferably, a solid-state image capturing device manufacturing method according to the present invention, the second contact plug/third optical waveguide tube portion forming step includes: a third resist film forming step of patterning a third resist film on the second insulation film to have shapes corresponding to the second contact plug and the third optical waveguide tube portion; a second recess shape forming step of processing second recess shapes corresponding to the second contact plug and the third optical waveguide tube portion in the second insulation film using the third resist film as a mask; a third metal film coating step of coating a third metal film in the second insulation film having the second recess shape formed therein; and a step of removing the third metal film on the entire second insulation film such that the third metal film remains in the second recesses so as to form the second contact plug and the third optical waveguide tube portion in the respective second recesses.

Still preferably, a solid-state image capturing device manufacturing method according to the present invention, the second wiring/fourth optical waveguide tube portion forming step includes: a fourth metal film coating step of coating a fourth metal film on the substrate having the second contact plug and the third optical waveguide tube portion formed therein; a fourth resist film forming step of patterning a fourth resist film on the fourth metal film to have shapes corresponding to the second wiring and the fourth optical waveguide tube portion; a step of forming the second wiring and the fourth optical waveguide tube portion from the fourth metal film using the fourth resist film as a mask.

Still preferably, a solid-state image capturing device manufacturing method according to the present invention, the second recess shapes are a recess shape for the second contact plug and a recess shape for the third optical waveguide tube portion.

Still preferably, a solid-state image capturing device manufacturing method according to the present invention includes: a third insulation film forming step of forming a third insulation film on the substrate having the second wiring and the fourth optical waveguide tube portion formed thereon; a third contact plug/fifth optical waveguide tube portion forming step of forming a third contact plug and a fifth optical waveguide tube portion simultaneously in the third insulation film; and a third wiring/sixth optical waveguide tube forming step of forming a third insulation film and a sixth optical waveguide tube portion on the third insulation film having the third contact plug and the fifth optical waveguide tube portion formed therein.

Still preferably, in a solid-state image capturing device manufacturing method according to the present invention, the third contact plug/fifth optical waveguide tube portion forming step includes: a fifth resist film forming step of patterning a fifth resist film on the third insulation film to have shapes corresponding to the third contact plug and the fifth optical waveguide tube portion; a third recess shape forming step of processing third recess shapes corresponding to the third contact plug and the fifth optical waveguide tube portion in the third insulation film using the fifth resist film as a mask; a fifth metal film coating step of coating a fifth metal film on the substrate having the third recess shape formed thereon; and a step of removing the fifth metal film on the entire third insulation film such that the fifth metal film remains in third recesses so as to form the third contact plug and the fifth optical waveguide tube portion in the respective third recesses.

Still preferably, in a solid-state image capturing device manufacturing method according to the present invention, the third wiring/sixth optical waveguide tube portion forming step includes: a sixth metal film coating step of coating a sixth metal film on the substrate having the third contact plug and the fifth optical waveguide tube portion formed therein; a sixth resist film forming step of patterning a sixth resist film in the sixth metal film to have shapes corresponding to the third wiring and the sixth optical waveguide tube portion; and a step of forming the third wiring and the sixth optical waveguide tube portion from the sixth metal film using the sixth resist film as a mask.

Still preferably, in a solid-state image capturing device manufacturing method according to the present invention, the third recess shape is a recess shape for the third contact plug and a recess shape for the fifth optical waveguide tube portion.

Still preferably, a solid-state image capturing device manufacturing method according to the present invention includes: an Nth (N is an integer greater than or equal to 2) insulation film forming step of forming an Nth insulation film on the substrate having the first wiring and the second optical waveguide tube portion formed thereon; an Nth contact plug/(2N−1)th optical waveguide tube portion forming step of simultaneously forming an Nth contact plug and a (2N−1)th optical waveguide tube portion in the Nth insulation film; and an Nth wiring/2Nth optical waveguide tube portion forming step of simultaneously forming an Nth wiring and a 2Nth optical waveguide tube portion on the substrate having the Nth contact plug and the (2N−1)th optical waveguide tube portion formed therein.

Still preferably, in a solid-state image capturing device manufacturing method according to the present invention, the Nth contact plug/(2N−1) optical waveguide tube portion forming step includes: a (2N−1)th resist film forming step of patterning a (2N−1)th resist film on the N insulation film to have shapes corresponding to an Nth contact plug and a (2N−1)th optical waveguide tube portion; an Nth recess shape forming step of processing Nth recess shapes corresponding to the Nth contact plug and the (2N−1)th optical waveguide tube portion in the Nth insulation film using the (2N−1)th resist film as a mask; a (2N−1)th metal film coating step of coating a (2N−1)th metal film on the substrate having the Nth recess shape formed therein; and a step of removing the (2N−1)th metal film on the entire Nth insulation film such that the (2N−1)th metal film remains in the Nth recesses so as to form the Nth contact plug and the (2N−1)th optical waveguide tube portion in the respective Nth recesses.

Still preferably, in a solid-state image capturing device manufacturing method according to the present invention, the Nth wiring/2Nth optical waveguide tube portion forming step includes: a 2Nth metal film coating step of coating a 2Nth metal film on the substrate having the Nth contact plug and the (2N−1)th optical waveguide tube portion formed therein; a 2Nth resist film forming step of patterning a 2Nth resist film on the 2Nth metal film to have shapes corresponding to the Nth wiring and the 2Nth optical waveguide tube portion; a step of forming the Nth wiring and the 2Nth optical waveguide tube portion from the 2N metal film using the 2Nth resist film as a mask.

Still preferably, a solid-state image capturing device manufacturing method according to the present invention includes: a first insulation film forming step of forming a first insulation film on the semiconductor substrate having a plurality of light receiving sections formed in a surface portion thereof in two dimensions; and a first wiring/first optical waveguide tube portion forming step of forming a first wiring and a first optical waveguide tube portion in the first insulation film.

Still preferably, in a solid-state image capturing device manufacturing method according to the present invention, the first wiring/first optical waveguide tube portion forming step includes: a first resist film forming step of patterning a first resist film in the first insulation film to have shapes corresponding to a first contact plug and a part of a first optical waveguide tube portion; a first recess shape forming step of processing first recess shapes corresponding to the first contact plug and the part of the first optical waveguide tube portion in the first insulation film using the first resist film as a mask; a second resist film forming step of patterning a second resist film on the first insulation film to have shapes corresponding to the first wiring integrated with the first contact plug and the first optical waveguide tube portion integrated with the part of the first optical waveguide tube portion; a second recess shape forming step of processing second recess shape corresponding to the first wiring and the first optical waveguide tube portion in the first insulation film using the second resist film as a mask; a first metal film coating step of coating a first metal film on the first insulation film having the second recess shape formed therein; and a step of removing the first metal film on the entire first insulation film such that the first metal film remains in the recess so as to form the first wiring and the first optical waveguide tube portion in the respective recesses.

Still preferably, in a solid-state image capturing device manufacturing method according to the present invention, the first wiring/first optical waveguide tube portion forming step includes: a first resist film forming step of patterning a first resist film on the first insulation film to have a shape corresponding to the first contact plug; a first recess shape forming step of processing a first recess shape corresponding to the first contact plug in the first insulation film using the first resist film as a mask; a second resist film forming step of patterning a second resist film on the first insulation film to have shapes corresponding to the first wiring integrated with the contact plug and the first optical waveguide tube portion; a second recess shape forming step of processing second recess shapes corresponding to the first wiring and the first optical waveguide tube portion in the first insulation film using the second resist film as a mask; a first metal film coating step of coating a first metal film on the first insulation film having the second recess shape formed therein; and a step of removing the first metal film on the entire first insulation film such that the first metal film remains in the recess so as to form the first wiring and the first optical waveguide tube portion in the respective recesses.

Still preferably, a solid-state image capturing device manufacturing method according to the present invention includes: a second insulation film forming step of forming a second insulation film on the first insulation film having the first wiring and the first optical waveguide tube portion provided therein; and a second wiring/second optical waveguide tube portion forming step of forming a second wiring and a second optical waveguide tube portion in the second insulation film.

Still preferably, in a solid-state image capturing device manufacturing method according to the present invention, the second wiring/second optical waveguide tube portion forming step includes: a third resist film forming step of patterning a third resist film on the second insulation film to have shapes corresponding to a second contact plug and a part of a second optical waveguide tube portion; a third recess shape forming step of processing third recess shapes corresponding to the second contact plug and the part of the second optical waveguide tube portion in the second insulation film using the third resist film as a mask; a fourth resist film forming step of patterning a fourth resist film on the second insulation film to have shapes corresponding to the second wiring integrated with the second contact plug and the second optical waveguide tube portion integrated with the part of the second optical waveguide tube portion; a fourth recess shape forming step of processing fourth recess shapes corresponding to the second wiring and the second optical waveguide tube portion in the second insulation film using the fourth resist film as a mask; a second metal film coating step of coating a second metal film on the second insulation film having the fourth recess shapes formed therein; and a step of removing the second metal film on the entire second insulation film such that the second metal film remains in recesses so as to form the second wiring and the second optical waveguide tube portion in the respective recesses.

Still preferably, a solid-state image capturing device manufacturing method according to the present invention includes: a third insulation film forming step of forming a third insulation film on the second insulation film provided with the second wiring and the second optical waveguide tube portion; and a third wiring/third optical waveguide tube portion forming step of forming a third wiring and a third optical waveguide tube portion in the third insulation film.

Still preferably, in a solid-state image capturing device manufacturing method according to the present invention, the third wiring/third optical waveguide tube portion forming step includes: a fifth resist film forming step of patterning a fifth resist film in the third insulation film to have shapes corresponding to a third contact plug and a part of a third optical waveguide tube portion; a fifth recess shape forming step of processing fifth recess shapes corresponding to the third contact plug and the part of the third optical waveguide tube portion in the third insulation film using the fifth resist film as a mask; a sixth resist film forming step of patterning a sixth resist film on the third insulation film to have shapes corresponding to the third wiring integrated with the third contact plug and the third optical waveguide tube portion integrated with the part of the third optical waveguide tube portion; a sixth recess shape forming step of processing sixth recess shapes corresponding to the third wiring and the third optical waveguide tube portion in the third insulation film using the sixth resist film as a mask; a third metal film coating step of coating a third metal film on the third insulation film having the sixth recess shape formed therein; a step of removing the third metal film on the entire third insulation film such that the third metal film remains in the recess so as to form the third wiring and the third optical waveguide tube portion in the respective recesses.

Still preferably, a solid-state image capturing device manufacturing method according to the present invention includes: an Nth (N is an integer greater than or equal to 2) insulation film forming step of forming an Nth insulation film on an (N−1)th insulation film provided with an (N−1)th wiring and an (N−1)th optical waveguide tube portion; and an Nth wiring/Nth optical waveguide tube portion forming step of forming an Nth wiring and an Nth optical waveguide tube portion in the Nth insulation film.

Still preferably, in a solid-state image capturing device manufacturing method according to the present invention, the Nth wiring/Nth optical waveguide tube portion forming step includes: a (2N−1)th resist film forming step of patterning a (2N−1)th resist film on the Nth insulation film to have shapes corresponding to an Nth contact plug and a part of a Nth optical waveguide tube portion; a (2N−1)th recess shape forming step of processing (2N−1)th recess shapes corresponding to the Nth contact plug and the part of the Nth optical waveguide tube portion in the Nth insulation film using the (2N−1)th resist film as a mask; a 2Nth resist film forming step of patterning a 2N resist film in the Nth insulation film to have shapes corresponding to an Nth wiring integrated with the Nth contact plug and an Nth optical waveguide tube portion integrated with the part of the Nth optical waveguide tube portion; a 2Nth recess shape forming step of processing 2Nth recess shapes corresponding to the Nth wiring and the Nth optical waveguide tube portion in the Nth insulation film using the 2N resist film as a mask; an Nth metal film coating step of coating an Nth metal film on the Nth insulation film having the (2N−1)th recess shape and the 2Nth recess shape formed therein; and

a step of removing the Nth metal film on the entire Nth insulation film such that the Nth metal film remains in the recesses so as to form the Nth wiring and the Nth optical waveguide tube portion in the respective recesses.

Still preferably, a solid-state image capturing device manufacturing method according to the present invention further includes: an (N+1)th insulation film forming step of forming an (N+1)th insulation film on the substrate having the Nth wiring and the 2Nth optical waveguide tube portion formed thereon; a color filter forming step of forming color filters arranged for respective colors on the (N+1)th insulation film; an (N+2)th insulation film forming step of forming an (N+2)th insulation film on the color filters; and a microlens forming step of forming microlenses on the (N+2)th insulation film.

A solid-state image capturing device manufacturing method according to the present invention is provided for forming a plural-layered conductive films via respective insulation films, and forming an optical waveguide above a light receiving section, a plurality of light receiving sections being provided in a top surface portion of a semiconductor substrate in two dimensions and the plural-layered conductive films being formed on a region other than a region right above the light receiving section, the method including: a contact plug/first optical waveguide tube portion forming step of forming an optical waveguide tube portion with the same material as the contact plug at the same time when the contact plug is processed and formed, the first optical waveguide tube portion configuring a part of the optical waveguide and the contact plug electrically connecting at least one of between the semiconductor substrate and plural-layered conductive films, and between the plural-layered conductive films, thereby the objective described above being achieved.

Preferably, a solid-state image capturing device manufacturing method according to the present invention includes: a conductive film/second optical waveguide tube portion forming step of forming a second optical waveguide tube portion so as to laminate it on the first optical waveguide tube portion simultaneously when a single-layered conductive film or at least one of plural-layered conductive films is formed, the second optical waveguide tube portion being formed using the same material as that for the conductive film, and the second optical waveguide tube portion configuring a part of the optical waveguide.

Still preferably, in a solid-state image capturing device manufacturing method according to the present invention, the contact plug/first optical waveguide tube portion forming step includes: a first insulation film forming step of forming a first insulation film on the semiconductor substrate; a first contact plug forming step of forming a first contact plug in the first insulation film; a first wiring film forming step of forming a first wiring on the first insulation film having the first contact plug formed therein; a second insulation film forming step of forming a second insulation film on the substrate having the first wiring formed thereon; and a second contact plug/first optical waveguide tube portion forming step of forming a second contact plug in the second insulation film and simultaneously forming a first optical waveguide tube portion in the second insulation film and the first insulation film or only in the second insulation film.

Still preferably, in a solid-state image capturing device manufacturing method according to the present invention, the contact plug/first optical waveguide tube portion forming step includes: a first insulation film forming step of forming a first insulation film on the semiconductor substrate; a first contact plug forming step of forming a first contact plug in the first insulation film; a first wiring film forming step of forming a first wiring film on the first insulation film having the first contact plug formed therein; a second insulation film forming step of forming a second insulation film on the substrate having the first wiring formed thereon; a second contact plug forming step of forming a second contact plug in the second insulation film; a second wiring film forming step of forming a second wiring on the second insulation film having the second contact plug formed therein; a third insulation film forming step of forming a third insulation film on the substrate having the second wiring formed thereon; and a third contact plug/first optical waveguide tube portion forming step of forming a first optical waveguide tube portion in the third insulation film, the second insulation film and the first insulation film or only in the third insulation film and the second insulation film simultaneously when a third contact plug is formed in the third insulation film.

Still preferably, in a solid-state image capturing device manufacturing method according to the present invention, the conductive film/second optical waveguide tube portion forming step includes: a second wiring forming step of forming a second wiring on the second insulation film having the second contact plug and the first optical waveguide tube portion formed therein; a third insulation film forming step of forming a third insulation film on the substrate having the second wiring formed thereon; a third contact plug/second optical waveguide tube portion partially forming step of forming a third contact plug and a part of a second optical waveguide tube portion in the third insulation film; and a third wiring/second optical waveguide tube forming step of forming a third wiring and the rest of the second optical waveguide tube portion on the third insulation film having the third contact plug and the part of the optical waveguide tube portion formed therein.

An electronic information device according to the present invention uses the solid-state image capturing device according to the present invention described above as an image capturing section, thereby the objective described above being achieved.

The functions of the present invention having the above structures are described hereinafter.

Conventionally, light focusing efficiency of a microlens greatly affects light receiving sensitivity, and therefore the distance between the microlens and a respective light receiving section has to be short within the range of its predetermined distance to guarantee excellent light focusing efficiency. If the distance between the microlens and the light receiving section becomes longer than the range of the predetermined distance, light will be focused at a desired location by the microlens and an optical waveguide tube will be used for directing the light efficiently to the light receiving section. If the optical waveguide tube is formed above the light receiving section, a step of forming the optical waveguide tube and materials for the step will be separately needed. For example, a step of processing a hole for forming an optical waveguide, a step of laminating two kinds of optical waveguide materials (into multi-layered films) for reflection or refraction in the hole for forming the optical waveguide, a step of removing by etching the bottom portion of the laminated multi-layered films and filling in the hole an optical waveguide material for transmitting light, and a step of polishing the surface of the optical waveguide are needed. During such steps, due to adverse effects to the periphery of the optical waveguide, particularly to the light receiving section, such as etching damage, contamination by impurities from film materials, and stress from multi-layered films, degradation of image quality characteristics occurs.

In order to solve the above problem, according to the present invention, gate electrode films are formed via gate insulation films on a substrate that has a plurality of light receiving sections formed on its surface, a plural-layered conductive films such as wiring layers and shading layers are formed via insulation films such as interlayer insulation films further over the gate electrode films; and between the semiconductor substrate and the conductive films, between the gate electrode films and the conductive films as well as between plural-layered conductive films are electrically connected by contact plugs made from a conductive material in contact holes in the insulation films. Further, a plurality of optical waveguide tube portions are vertically laminated in the corresponding location over the light receiving section using materials for the plural-layered conductive films or contact plugs.

Upon processing and forming the plural-layered conductive films and contact plugs, simultaneously, conductive material films that form conductive films and contact plugs over the light receiving sections are sequentially formed as a part of an optical waveguide. Therefore, without forming a hole for forming an optical waveguide as conventionally, it is possible to form an optical waveguide region together with multi-layered wirings by using only conventional steps of processing other than conventional steps of forming an optical waveguide. As a result, it is possible to obtain excellent light focusing effect and light propagating effect by the optical waveguide and to obtain a solid-state image capturing device that does not cause degradation of image quality characteristics as conventionally.

In this manner, according to the present invention, since a solid-state image capturing device having an optical waveguide region can be realized without providing a hole for forming a waveguide, the present invention can prevent the problem of a light receiving section from suffering etching damage, thus resulting in a deterioration of image quality characteristics in processing a hole for forming a waveguide while the present invention can enhance light usage efficiency. Further, since there is no need to coat a material with a high refractive index and a material with a low refractive index with CVD and the like and to form an optical waveguide region in a hole for forming a waveguide, it is possible to prevent a problem that impurities included in such materials are diffused toward the receiving section side, thus deteriorating the image quality characteristics, as conventionally occurred. Further, since there is no need to form multi-layered films by using a material with a high refractive index and a material with a low refractive index in order to obtain an effect of an optical waveguide, the conventional problem of leakage current and crack occurring due to stress thereby deteriorating image quality characteristics can be prevented. Further, according to the present invention, there is no need for a step exclusive for forming an optical waveguide, and an optical waveguide region is formed using a conventional processing step only with a design change for a resist film therefore significantly reducing the cost for processing semiconductors thus reducing a price for a solid-state image capturing device.

These and other advantages of the present invention will become apparent to those skilled in the art upon reading and understanding the following detailed description with reference to the accompanying figures.

### BRIEF DESCRIPTION OF THE DRAWINGS

FIG. 1 is a longitudinal cross-sectional view showing an exemplary essential structure of a solid-state image capturing device according to Embodiment 1 of the present invention.

FIG. 2 is a top view for describing a step of processing a first contact plug and a first optical waveguide tube portion in the solid-state image capturing device manufacturing method in FIG. 1.

FIG. 3 is a top view for describing a step of processing a first wiring and a second optical waveguide tube portion in the solid-state image capturing device manufacturing method in FIG. 1.

FIG. 4 is a top view for describing a step of processing a second contact plug and a third optical waveguide tube portion in the solid-state image capturing device manufacturing method in FIG. 1.

FIG. 5 is a top view for describing a step of processing a second wiring and a fourth optical waveguide tube portion in the solid-state image capturing device manufacturing method in FIG. 1.

FIG. 6 is a longitudinal cross-sectional view showing an optical path of incident light with an angle of vertical direction in the solid-state image capturing device in FIG. 1.

FIG. 7 is a longitudinal cross-sectional view showing an optical path of incident light with an angle other than vertical direction in the solid-state image capturing device in FIG. 1.

FIG. 8 is a longitudinal cross-sectional view showing an exemplary essential structure of a solid-state image capturing device 20A according to Embodiment 2 of the present invention.

FIG. 9 is a longitudinal cross-sectional view showing an exemplary essential structure of a solid-state image capturing device 20B according to Embodiment 3 of the present invention.

FIG. 10 is a longitudinal cross-sectional view showing an exemplary essential structure of a solid-state image capturing device 20C according to Embodiment 4 of the present invention.

FIG. 11 is a longitudinal cross-sectional view showing an exemplary essential structure of a conventional solid-state image capturing device.

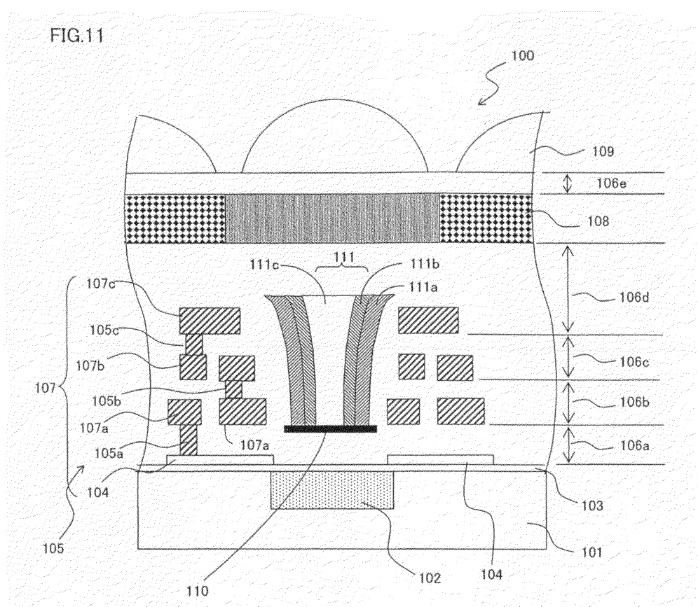

FIG. 12 is a top view for describing a step of processing a first contact plug in the conventional solid-state image capturing device manufacturing method in FIG. 11.

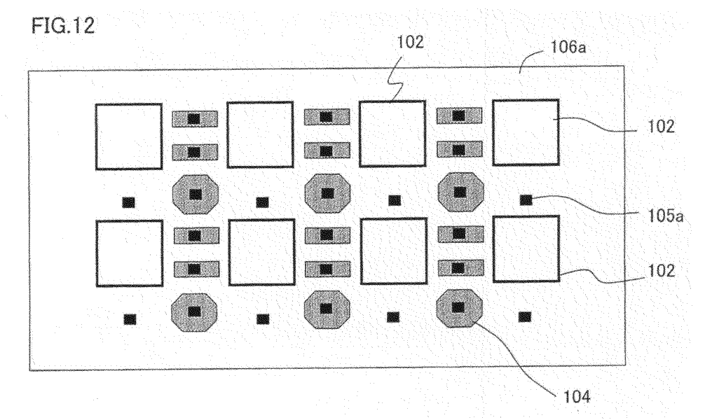

FIG. 13 is a top view for describing a step of processing a first wiring in the conventional solid-state image capturing device manufacturing method in FIG. 11.

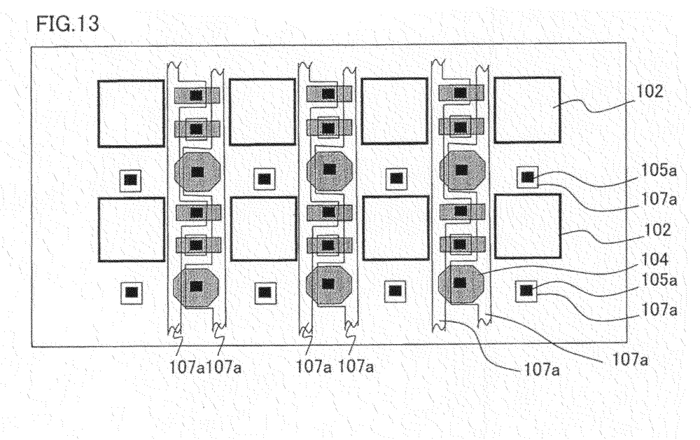

FIG. 14 is a top view for describing a step of processing a second contact plug in the conventional solid-state image capturing device manufacturing method in FIG. 11.

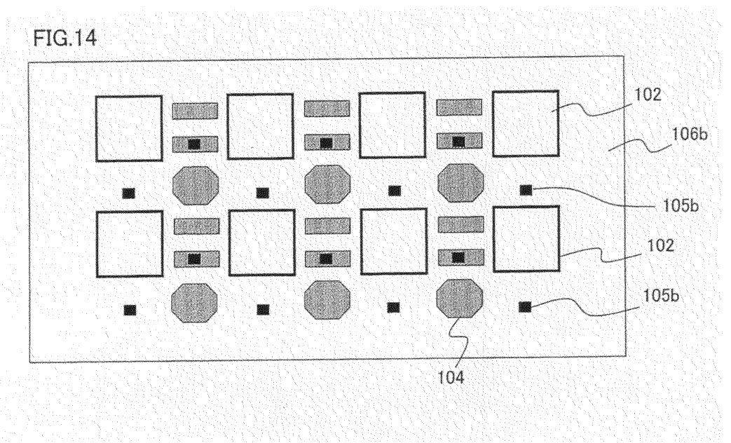

FIG. 15 is a top view for describing a step of processing a second wiring in the conventional solid-state image capturing device manufacturing method in FIG. 11.

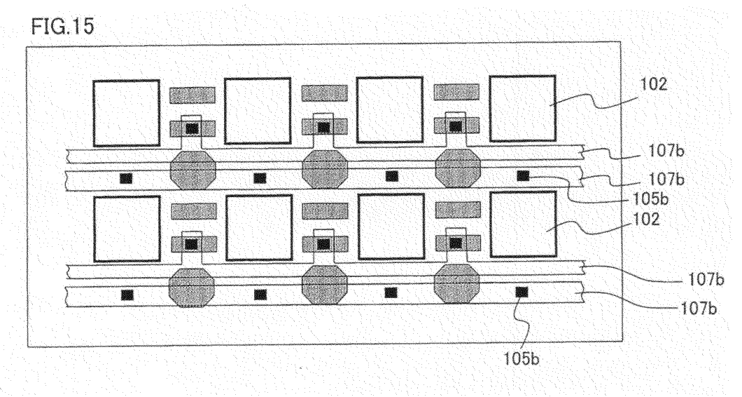

FIG. 16 is an essential structure longitudinal cross-sectional view showing an optical path of incident light with an angle of vertical direction in the solid-state image capturing device in FIG. 11.

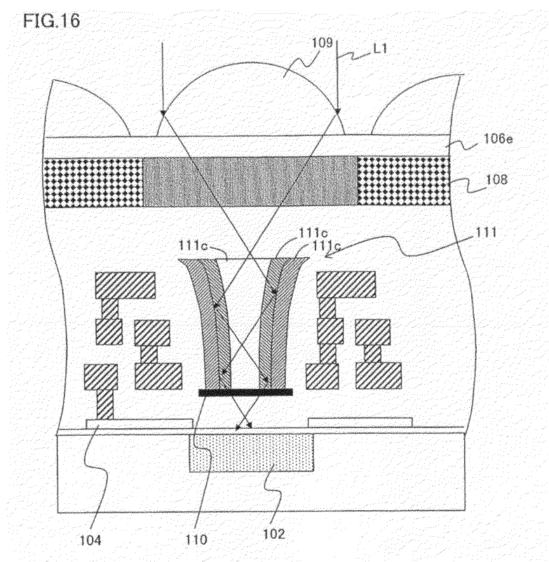

FIG. 17 is an essential structure longitudinal cross-sectional view showing an optical path of incident light with an angle of oblique direction in the solid-state image capturing device in FIG. 11.

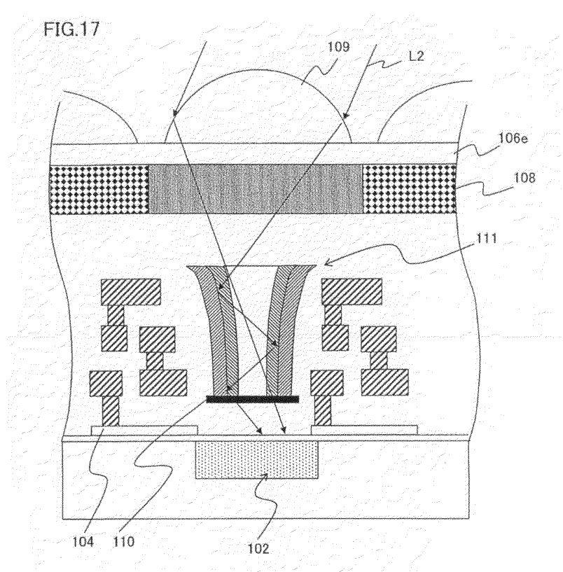

FIG. 18 is a longitudinal cross-sectional view showing an exemplary essential structure of a solid-state image capturing device according to Embodiment 5 of the present invention.

FIG. 19 is a top view for describing a step of processing a contact plug forming in the solid-state image capturing device manufacturing method in FIG. 18.

FIG. 20 is a longitudinal cross-sectional view showing an exemplary essential structure of a solid-state image capturing device according to Embodiment 6 of the present invention.

FIG. 21 is a longitudinal cross-sectional view showing an exemplary essential structure of a solid-state image capturing device according to Embodiment 7 of the present invention.

FIG. 22 is a longitudinal cross-sectional view showing an exemplary essential structure of a solid-state image capturing device according to Embodiment 8 of the present invention.

FIG. 23 is a block diagram showing an exemplary schematic structure of an electronic information device according to Embodiment 9 of the present invention using the solid-state image capturing apparatus as an image capturing section, the electronic information device including any one of the solid-state image capturing devices 20 and 20A-20G in Embodiments 1-8.

1 semiconductor substrate
2 light receiving section
3 gate insulation film
4 gate electrode film
5 contact plug
5a first contact plug
5b second contact plug
5c third contact plug
6 interlayer insulation film
6a, 16a first insulation film
6b, 16b second insulation film
6c, 16c third insulation film
6d, 16d fourth insulation film
6e fifth insulation film
7 wiring layer
7a, 17a first wiring
7b, 17b second wiring
7c, 17c third wiring
8 color filter
9 microlens
10, 10A-10G optical waveguide
10a, 10Aa, 10Ba first optical waveguide tube portion
10b, 10Ab, 10Bb, second optical waveguide tube portion
10c, 10Ac third optical waveguide tube portion
10d fourth optical waveguide tube portion
10e fifth optical waveguide tube portion
10f sixth optical waveguide tube portion
20, 20A-20G solid-state image capturing device
27c shading film
90 electronic information device
91 solid-state
92 memory section
93 display section
94 communication section
95 image output apparatus
271 taper

### DESCRIPTION OF THE PREFERRED EMBODIMENTS

Hereinafter, Embodiments 1 to 4 in which a solid-state image capturing device according to the present invention is applied to a CMOS image sensor and Embodiment 5 of an electronic information device (e.g., digital camera, cell phone device equipped with camera and the like) using the solid-state image capturing device according to any one of Embodiments 1 to 4 as an image capturing section will be described in detail with reference to the accompanying drawings.

### Embodiment 1

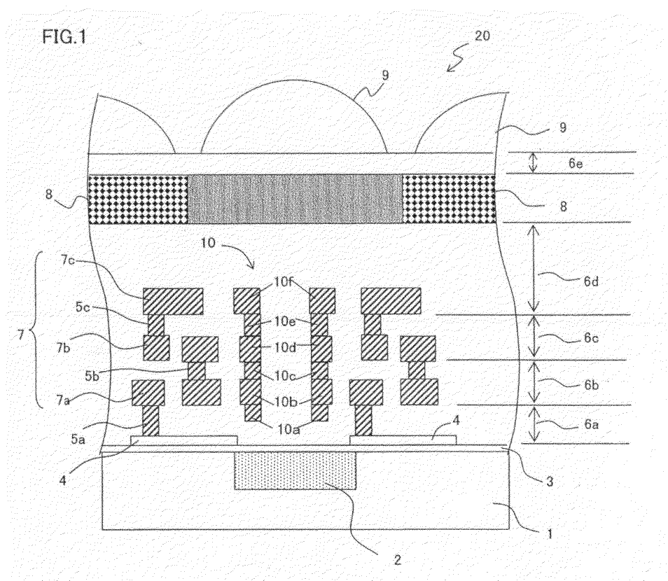

FIG. 1 is a longitudinal cross-sectional view showing an exemplary essential structure of a solid-state image capturing device 20 according to Embodiment 1.

In FIG. 1, for the solid-state image capturing device 20 of Embodiment 1, a plurality of light receiving sections 2 such as photodiodes and the like are formed in two dimensions in a surface layer (image capturing region) of a semiconductor substrate 1, wherein the plurality of light receiving sections 2 function as photoelectric conversion sections for converting light of subject into a signal charge. Additionally, gate electrode films 4 as a lead electrode is formed via a gate insulation film 3 on this semiconductor substrate 1, and over this substrate, a plurality of contact plugs 5 (a first contact plug 5a, second contact plug 5b and third contact plug 5c) and/or a plurality of interlayer insulation films 6 (a first insulation film 6a, second insulation film 6b, third insulation film 6c, and fourth insulation film 6d) and a plurality of wiring layers 7 (a first wiring 7a, second wiring 7b, and third wiring 7c) are respectively configured alternately to have a sandwich structure. Upon forming each one of the plural layers of contact plugs 5 and the plural layers of wiring layers 7, corresponding one of a plurality of tubular optical waveguide portion 10a-10f will be at the same time formed sequentially. Specifically, a first insulation film 6a is formed over the gate electrode film 4 and the light receiving section 2 on the semiconductor substrate 1, a first contact plug 5a and an optical waveguide tube portion 10a are formed in the first insulation film 6a, a first wiring 7a and an optical waveguide portion 10b are formed in the first insulation film 6a, a second insulation film 6b is formed in the first insulation film 6a, a second contact plug 5b and an optical waveguide portion 10c are formed on the second insulation film 6b, a second wiring 7b and an optical waveguide portion 10d are formed in the second insulation film 6b, a third insulation film 6c is formed on the second insulation film 6b, a third contact plug 5c and an optical waveguide portion 10e are formed in the third insulation film 6c, a third wiring 7c and an optical waveguide portion 10f are formed on the third insulation film 6c, and further a fourth insulation film 6d is formed on the third insulation film 6a.

Contact plugs 5 (first contact plug 5a, second contact plug 5b, third contact plug 5c) made from a conductive material (a metal material such as aluminum and tungsten) are formed between the wiring layers 7 and the semiconductor substrate 1, the wiring layers 7 and the gate electrode films 4, and in between the wiring layers 7 as needed for a circuit; and locations where circuits are provided as needed are electrically connected between the wiring layers 7 and the semiconductor substrate 1, the wiring layers 7 and the gate electrode films 4, and in between the wiring layers 7. These contact plugs 5 can be made from the same material as the wiring layers 7 (such as aluminum and copper) or can be made from a different metal material from aluminum, such as tungsten.

Further, color filters 8 are formed on the fourth insulation layer 6d corresponding to each light receiving section 2, wherein the color filters 8 are arranged for respective colors such as three primary colors (R, G, B), and a fifth insulation film 6e is formed on the color filters 8, and further microlenses 9 are formed for condensing lights for respective light receiving section 2 on the fifth insulation film 6e. This fourth insulation layer 6d is formed as a passivation film or a planarization film for forming a color filter prior to a color filter forming, and the fifth insulation film 6e is formed as a planarization film for forming a color filter prior to a microlens forming.

Further, in the solid-state image capturing device 20 according to Embodiment 1, optical waveguide tube portions 10a to 10f each having a cylindrical shape (ring shape, or the outer-circumference thereof is rectangle or square in a plain view and the inner-circumference thereof is circular in a plain view) formed using a conductive film material that configures the wiring layers 7 and a conductive material (metal material) that configures the contact plugs 5 are provided. The optical waveguide tube portions 10a to 10f are sequentially laminated in a longitudinal direction (direction vertical to the surface of the substrate) to configure the optical waveguide 10 for reflecting light on a metal surface of the inner side of the cylinder and propagating light toward the light receiving section 2 side.

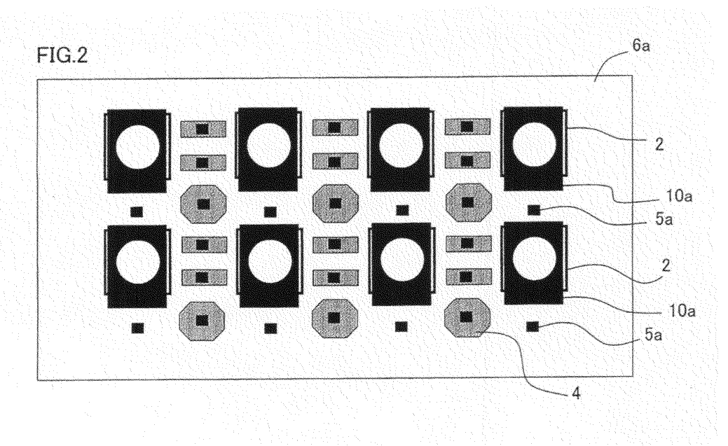

Next, each of the manufacturing steps in a method for manufacturing the solid-state image capturing device according to Embodiment 1 will be described in detail with reference to FIG. 2 to FIG. 5.

FIG. 2 to FIG. 5 are each a top view for describing a step of manufacturing the solid-state image capturing device 20 according to Embodiment 1 of the present invention.

As shown in FIG. 2, subsequent to the formation of the gate electrode film 4, first, the first insulation film 6a is grown using SiO₂ material such as BPSG (Boron Phosphor Silicate Glass) and/or high-density plasma SiO₂ (HDP-SiO₂) on the gate electrode film 4. The first insulation film 6a is formed to have the surface thereof polished by CMP (chemical mechanical polish) mainly for the purpose of planarization in order to ease the process at the next step.

Next, after the polishing of the first insulation film 6a, to form the first contact plug 5a and the first optical waveguide tube portion 10a, a photosensitive resist film is applied over the first insulation film 6a and is exposed to light and developed to have a predetermined patterned shape, and anisotropic etching is performed on the first insulation film 6a using the patterned resist film as a mask. As a pattern for this resist film, in addition to the shape processing for the first contact plug 5a, a shape processing for the first optical waveguide portion 10a is performed to simultaneously form the shape of the first insulation film 6a (including the same step) due to forming the first contact plug 5a and the first optical waveguide portion 10a. After the etching for the first insulation film 6a, a metal film for contact plugs is grown by metal sputtering on the first insulation layer 6a. The metal film made from tungsten, for example, for contact plugs can also be grown with CVD (Chemical vapor deposition). Additionally, a barrier metal film is sputtered prior to metal sputtering in order to prevent silicidation with the foundation. Subsequently, the entire surface of the first insulation film 6a is etched to remove a sputtered film on the first insulation film 6a to simultaneously form a first contact plug 5a and first optical waveguide tube portion 10a embedded in holes of the first insulation film 6a. This etching for the entire surface can be performed, for example, by polishing with CMP. FIG. 2 shows a top view of the shape formed at the steps described above. FIG. 2 shows photodiodes (light receiving sections 2) and gate electrode films 4 that are not present on the same plane as the first contact plug 5a and the first optical waveguide tube portion 10a for the purpose of clarifying the locational relationship with them.

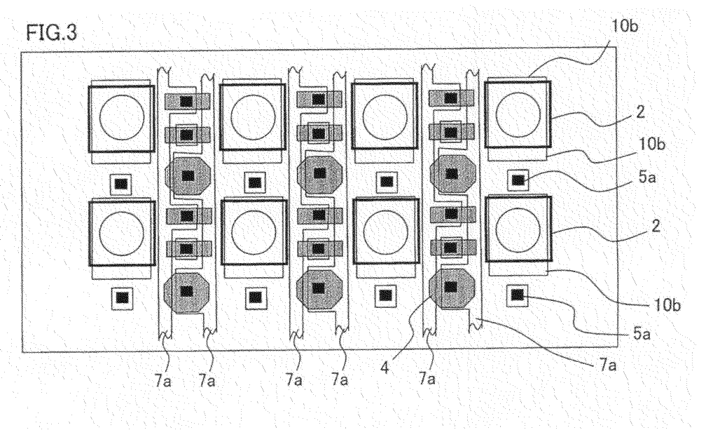

Further, as shown in FIG. 3, in order to form the first wiring 7a and the second optical waveguide tube portion 10b over the substrate having the first contact plug 5a and the first optical waveguide tube portion 10a formed thereon, a metal film is grown by metal sputtering. Thereafter photosensitive resist film is applied over the metal film and is exposed to light and developed to have a predetermined patterned shape, and anisotropic etching is performed on the metal film using the patterned resist film as a mask. For a pattern of the resist mask film, the shape of the first wiring 7a as well as a corresponding shape of the second optical waveguide tube portion 10b are formed, so that the first wiring 7a and the second optical waveguide tube portion 10b are formed simultaneously with the same metal material. FIG. 3 shows a top view of the shape formed by the steps described above. FIG. 3 also shows photodiodes (light receiving sections 1), gate electrode films 4 and the first contact plug 5a that are not present on the same plane as the first wiring 7a and the second optical waveguide tube portion 10b for the purpose of clarifying the locational relationship with them. Further, two kinds of adjacent belt patterns are shown as the first wiring 7a.

Next, the second insulation film 6b is film grown with SiO₂ material such as BPSG (Boron Phosphor Silicate Glass) and high-density plasma SiO₂ (HDP-SiO₂) on the substrate having the first wiring 7a and the second optical waveguide tube portion 10b formed thereon. The surface of the second insulation film 6b is polished by CMP mainly for the purpose of planarization so as to facilitate the following step.

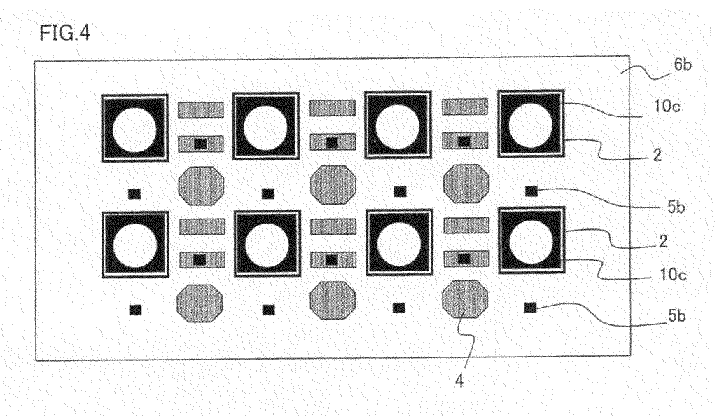

After polishing the second insulation film 6b, in order to form a second contact plug 5b and a third optical waveguide tube portion 10c, a photosensitive resist film is applied over the second insulation film 6b and is exposed to light and developed to have a predetermined patterned shape, and anisotropic etching is performed on the second insulation film 6b using the patterned resist film as a mask. For a pattern of the resist mask film, the shape of the second contact plug 5b and the shape of the third optical waveguide tube portion 10c are processed to simultaneously form the shape of the second insulation film 6b for forming the second contact plug 5b and the third optical waveguide tube portion 10c. After the etching, a metal film for a contact plug is grown on the second insulation film 6b by metal sputtering. The metal film made from tungsten, for example, for contact plugs can also be grown with CVD. Additionally, a barrier metal film is sputtered prior to metal sputtering in order to prevent silicidation with the foundation. Subsequently, the entire surface of the second insulation film 6b is etched to remove a sputtered film on the second insulation film 6b to simultaneously form a second contact plug 5b and a third optical waveguide tube portion 10c. This etching for the entire surface can be performed, for example, by polishing with CMP. FIG. 4 shows a top view of the shape formed at the steps described above. FIG. 4 shows photodiodes (light receiving sections 2) and gate electrode films 4 that are not present on the same plane as the second contact plug 5b and the third optical waveguide tube portion 10c for the purpose of clarifying the locational relationship with them.

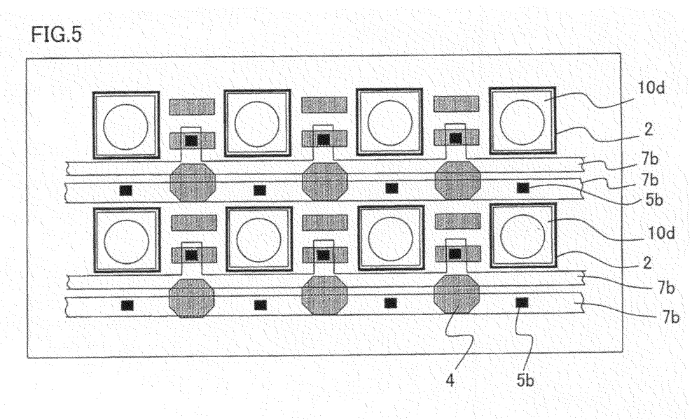

Further, in order to form a second wiring 7b and a fourth optical waveguide tube portion 10d on the substrate having the second contact plug 5b and the third optical waveguide tube portion 10c formed thereon, a metal film is grown by metal sputtering and in turn a photosensitive resist film is applied over the metal film and is exposed to light and developed to have a predetermined patterned shape, and anisotropic etching is performed on the metal film using the patterned resist film as a mask. For a pattern of the resist mask film, the shape of the second wiring 7b as well as the shape of the fourth optical waveguide tube portion 10d are processed, so that corresponding shapes with the second wiring 7b and the fourth optical waveguide tube portion 10d are simultaneously formed. The second wiring 7 band the fourth optical waveguide tube portion 10d are formed by etching. FIG. 5 shows a top view of the shape formed at the steps described above. FIG. 5 shows photodiodes (light receiving sections 2), gate electrode films 4 and the second contact plug 5b that are not present on the same plane as the second wiring 7b and the fourth optical waveguide tube portion 10d for the purpose of clarifying the locational relationship with them. Further, two kinds of belt patterns being adjacent with each other and extending to the left and right are shown as the second wiring 7b.

Similarly, a third insulation film 60, a third contact plug 5a and a fifth optical waveguide tube portion 10e, a third wiring 70 and a sixth optical waveguide tube portion 10f, and a fourth insulation film 6d are sequentially formed.

Thereafter, color filters 8 arranged for respective colors are formed on the fourth insulation layer 6d used as a planarization film and a fifth insulation layer 6e used as a planarization film is formed on the color filters 8. Further, microlenses 9 are formed on the color filters 8 so that a solid-state image capturing device 20 that has optical waveguides 10 (optical waveguide tube portion 10a-10f) shown in FIG. 1 is manufactured.

The method described above for manufacturing the solid-state image capturing device 20 will be described in a more simplified manner.

The method for manufacturing the solid-state image capturing device 20 to form the wiring film of the first layer includes: a first insulation film forming step of forming a first insulation film 6a on the semiconductor substrate, wherein a plurality of light receiving sections 2 are formed in two dimensions and gate electrode films 4 are formed adjacent to the light receiving sections 2; a first resist film forming step of patterning a first resist film on the first insulation film 6a to have shapes corresponding to the first contact plug 5a and the first optical waveguide tube portion 10a; a first recess shape forming step of processing a first recess shape corresponding to the first contact plug 5a and the first optical waveguide tube portion 10a in the first insulation film 6a using the first resist film as a mask; a first metal film coating step of coating a first metal film on the substrate having the first recess shape formed thereon; a step of removing the first metal film on the entire first insulation film 6a such that the first metal film remains in the recess so as to form the first contact plug 5a and the first optical waveguide tube portion 10a in respective recesses; a second metal film coating step of coating a second metal film on the substrate having the first contact plug 5a and the first optical waveguide tube portion 10a formed thereon; a second resist film forming step of patterning a second resist film in the second metal film to have shapes corresponding to the first wiring 7a and the second optical waveguide tube portion 10b; a step of forming the first wiring 7a and the second optical waveguide tube portion 10b from the second metal film using the second resist film as a mask; and a second insulation film forming step of forming a second insulation film 6b on the substrate having the first wiring 7a and the second optical waveguide tube portion 10b formed thereon.

The method for manufacturing the solid-state image capturing device 20 to form the wiring film of the second layer includes: a third resist film forming step of patterning a third resist film on the second insulation film 6b to have shapes corresponding to the second contact plug 5b and the third optical waveguide tube portion 10c; a second recess shape forming step of processing a second recess shape corresponding to the second contact plug 5b and the third optical waveguide tube portion 10c in the second insulation film 6b using the third resist film as a mask; a third metal film coating step of coating a third metal film on the substrate having the second recess shape formed thereon; a step of removing the third metal film on the entire second insulation film 6b such that the third metal film remains in the second recesses so as to form the second contact plug 5b and the third optical waveguide tube portion 10a respectively in the respective second recesses; a fourth metal film coating step of coating a fourth metal film on the substrate having the second contact plug 5b and the third optical waveguide tube portion 10c formed thereon; a fourth resist film forming step of patterning a fourth resist film in the fourth metal film to have shapes corresponding to a second wiring 7b and a fourth optical waveguide tube portion 10d; a step of forming the second wiring 7b and the fourth optical waveguide tube portion 10d from the fourth metal film using the fourth resist film as a mask; and a third insulation film forming step of forming a third insulation film 6c on the substrate having the second wiring 7b and the fourth optical waveguide tube portion 10d formed thereon.

The method for manufacturing the solid-state image capturing device 20 to form the wiring film of the third layer includes: a fifth resist film forming step of patterning a fifth resist film on the third insulation film 6a to have shapes corresponding to the third contact plug 5a and the fifth optical waveguide tube portion 10e; a third recess shape forming step of processing a third recess shape corresponding to the third contact plug 5c and the fifth optical waveguide tube portion 10e in the third insulation film 60 using the fifth resist film as a mask; a fifth metal film coating step of coating a fifth metal film on the substrate having the third recess shape formed thereon; a step of removing the fifth metal film on the entire third insulation film 6c such that the fifth metal film remains in third recesses so as to form the third contact plug 5c and the fifth optical waveguide tube portion 10e respectively in the respective third recesses; a sixth metal film coating step of coating a sixth metal film on the substrate having the third contact plug 5c and the fifth optical waveguide tube portion 10e formed thereon; a sixth resist film forming step of patterning a sixth resist film in the sixth metal film to have shapes corresponding to the third wiring 70 and the sixth optical waveguide tube portion 10f; a step of forming the third wiring 70 and the sixth optical waveguide tube portion 10f from the sixth metal film using the sixth resist film as a mask; and a fourth insulation film forming step of forming a fourth insulation film 6d on the substrate having the third wiring 7a and the sixth optical waveguide tube portion 10f formed thereon.

As described above, three layers of wiring films are used in Embodiment 1 of the present invention. However, the present invention is not limited to this. Alternatively, the number of wiring films can be one or two. Still alternatively, the number of wiring films can be four or more. Further, the case where the arbitrary N number of the wiring films is used will be described.

The method for manufacturing the solid-state image capturing device 20 to form the wiring film of the Nth layer includes, in addition to the steps described above: a (2N−1)th resist film forming step of patterning a (2N−1)th resist film on the N insulation film 6 to have shapes corresponding to an Nth contact plug 5 and a (2N−1)th optical waveguide tube portion; an Nth recess shape forming step of processing an Nth recess shape corresponding to the Nth contact plug 5 and the (2N−1)th optical waveguide tube portion in the Nth insulation film 6 using the (2N−1)th resist film as a mask; a (2N−1)th metal film coating step of coating a (2N−1)th metal film on the substrate having the Nth recess shape formed thereon; a step of removing the (2N−1)th metal film on the entire Nth insulation film 6 such that the (2N−1)th metal film remains in the Nth recesses so as to form the Nth contact plug 5 and the (2N−1)th optical waveguide tube portion respectively in the respective Nth recesses; a 2Nth metal film coating step of coating a 2Nth metal film on the substrate having the Nth contact plug 5 and the (2N−1) th optical waveguide tube portion formed thereon; a 2Nth resist film forming step of patterning a 2Nth resist film in the 2Nth insulation film to have shapes corresponding to the Nth wiring 7 and the 2Nth optical waveguide tube portion; a step of forming the Nth wiring 7 and the 2Nth optical waveguide tube portion from the 2N metal film using the 2Nth resist film as a mask; and an (N+1)th insulation film forming step of forming an (N+1)th insulation film 6 on the substrate having the Nth wiring 7 and the 2Nth optical waveguide tube portion formed thereon. Further, the method for manufacturing the solid-state image capturing device 20 further includes: a color filter forming step of forming color filters arranged for respective colors on the (N+1)th insulation film 6; an (N+2)th insulation film forming step of forming an (N+2)th insulation film on the color filters; and a microlens forming step of forming microlenses on the (N+2)th insulation film.

Here, effects of condensation of light with an optical waveguide 10 according to Embodiment 1 of the present invention will be described.

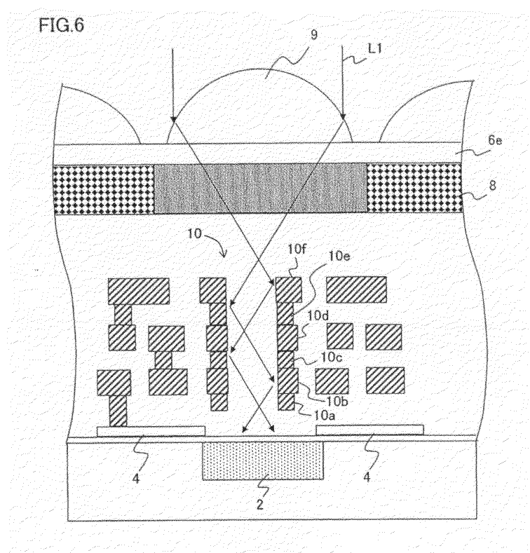

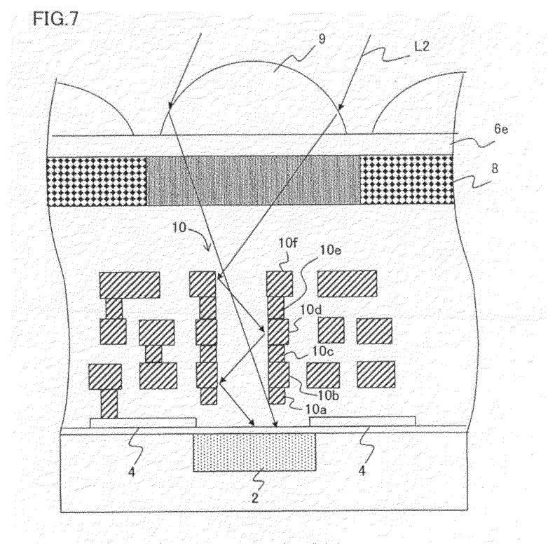

FIGS. 6 and 7 show an effect of the focus of light with an optical waveguide 10 using a ray of light L. FIG. 6 shows a case where a ray of light incident from above a microlens 9 is incident with an angle of vertical direction a ray of light L1: at the center of the image capturing region) with respect to the image capturing region of the solid-state image capturing device 20, and FIG. 7 shows a case where a ray of light incident from above a microlens 9 is incident with an angle of oblique direction other than the vertical direction (a ray of light L2: at the periphery of the image capturing region). As shown in FIGS. 6 and 7, the rays of light L1 and L2 incident from above a microlens 9 are totally reflected by metal surfaces of the tubular optical waveguide 10 consisting of optical waveguide tube portions 10a-10f, being directed to the light receiving section 2 and effectively focused upon the light receiving section 2.

As described above, in Embodiment 1 of the present invention, when a wiring layer 7 and a contact plug 5 are formed, respective wiring films (conductive films; metal films) are sequentially laminated and formed over a light receiving section 2 as optical waveguide tube portions for improving focusing efficiency. Thus, there is no need to form a hole for an optical waveguide and separately coat a film for an optical waveguide region as conventionally, and therefore, it is possible to obtain a solid-state image capturing device 20 having an optical waveguide 10 over a light receiving section 2 without degradation of image quality characteristics and stress from multiple layers and the like due to damages from etching, contamination by impurities from film materials. In addition, because the optical waveguide tube portions 10a-10f forming the optical waveguide 10 are formed simultaneously as respective wiring layers 7 and contact plugs 5 are formed, it is possible to manufacture a solid-state image capturing device 20 having an optical waveguide region without separately adding a step of processing an optical waveguide region. Further, there is no need to process an etching stopper layer of an optical waveguide forming hole, and further, there is no need to consider a hydrogen sintering effect for preventing damages from etching that occur when processing an optical waveguide forming hole. Further, there will be no need for forming an optical waveguide film in an optical waveguide film hole with CVD and the like. Further, there will be no need for considering degradation of device characteristics because of stress from forming multiple layers. Further, the step of manufacturing an optical waveguide region including the optical waveguide region can easily form an optical waveguide over a light receiving section by simply altering the pattern of a photomask in a conventional forming condition, thereby simplifying the step of manufacturing a solid-state image capturing device.

Although not described in Embodiment 1 of the present invention, dual damascene structure and its manufacturing method can be employed for manufacturing each of the contact plugs 5, interlayer insulation films 6, wiring layers 7 and optical waveguide tube portions 10a-10f. In that case, after forming a groove for the contact plugs 5, wiring layers 7 and optical waveguide tube portions 10a-10f in the interlayer insulation films 6, the groove is subject to metal sputtering and then subject to CMP processing and patterning processing, so that the contact plugs 5, wiring layers 7 and optical waveguide tube portions 10a-10f are formed.

### Embodiment 2

Embodiment 1 has described the case where an optical waveguide 10 is formed by sequentially laminating a plurality of tubular optical waveguide tube portions 10a to 10f with one layer vertically at one time as the contact plugs 5 or wiring layers 7 being formed.

Embodiment 2 describes a case where two layers of the optical waveguide tube portions 10a to 10f are simultaneously laminated at one time (with lower layers being smaller size-wise and upper layers larger), yet depending on the alignment accuracy of the optical waveguide tube portions 10a to 10f, to reduce unevenness of the alignment of the metal surfaces resulting from vertically laminating the optical waveguide tube portions 10a to 10f.

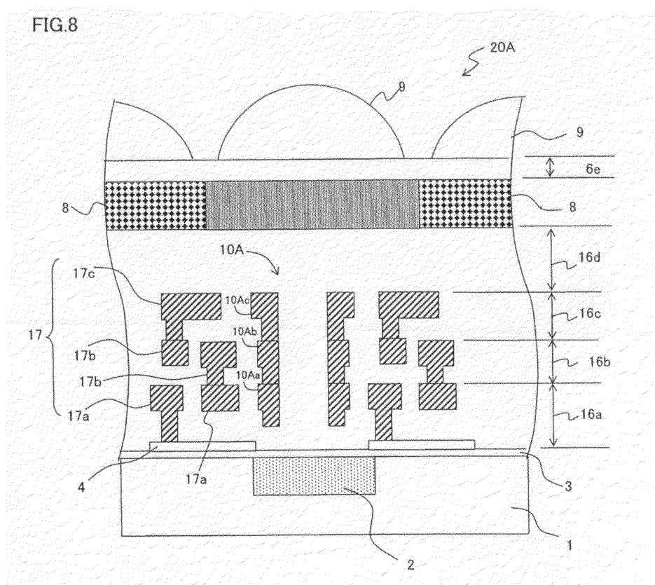

FIG. 8 is a longitudinal cross-sectional view showing an exemplary essential structure of a solid-state image capturing device 20A according to Embodiment 2 of the present invention. Members attaining similar effects as those shown in FIG. 1 are denoted with the same reference numerals as used in FIG. 1 and the descriptions therefore will be omitted.

In the solid-state image capturing device 20A in FIG. 8, a plurality of light receiving sections 2 are provided in two dimensions on a semiconductor substrate and gate electrode films 4 are provided to be adjacent to the light receiving sections 2. On the semiconductor substrate, plural-layered interlayer insulation films 16 (a first insulation layer 16a, a second insulation layer 16b and a third insulation layer 16c) are sequentially formed, and wiring layers 17 (a first wiring 17a, a second wiring 17b, and a third wiring 17c), each formed by the integration of a contact plug and a wiring layer according to Embodiment 1 are also sequentially formed for the respective interlayer insulation films 16. As the wiring layers 17, in which the contact plugs and wiring layers according to Embodiment 1 are integrated, are formed, at the same time respective tubular plural layers of optical waveguide tube portions 10Aa to 10Ac are sequentially formed. Specifically, a first insulation film 16a is formed over the gate electrodes 4 and light receiving section 2 on the semiconductor substrate 1; a wiring layer 17a formed by the integration of a contact plug and a wiring layer, a wiring layer 17a without a contact plug, and an optical waveguide tube portion 10Aa (corresponding to the type where the optical waveguide tube portion 10a and 10b according to Embodiment 1 are integrated) are formed in the first insulation film 16a; a second insulation film 16b is formed on the first insulation film 16a; a wiring layer 17b integrated with a contact plug and a wiring layer, a wiring layer 17b without a contact plug, and an optical waveguide tube portion 10Ab (corresponding to the type where the optical waveguide tube portion 10c and 10d of the above Embodiment 1 are integrated) are formed in the second insulation film 16b; a third insulation film 16c is formed on the second insulation film 16b; a wiring layer 17a integrated with a contact plug and a wiring layer, a wiring layer 17c without a contact plug, and an optical waveguide tube portion 10Ac (corresponding to the type where the optical waveguide tube portion 10e and 10f of the above Embodiment 1 are integrated) are formed on the third insulation film 16c; and further a fourth insulation film 16d is formed on the third insulation film 16c.

Next, manufacturing steps in a method for manufacturing the solid-state image capturing device 20A according to Embodiment 2 will be described.

Subsequent to the formation of the gate electrode films 4, first, the first insulation film 16a is grown on the gate electrode films 4 using SiO₂ material such as BPSG (Boron Phosphor Silicate Glass) or high-density plasma SiO₂ (HDP-SiO₂). The first insulation film 16a is formed to have the surface thereof polished by CMP (chemical mechanical polish) mainly for the purpose of planarization in order to ease the process at the next step.

Next, after the polishing of the first insulation film 16a, to form a recess such as a hole or a groove of a contact plug and a part of a first optical waveguide tube portion 10Aa to the gate electrode 4, a photosensitive resist material is applied over the first insulation film 16a and is exposed to light and developed to have a predetermined patterned shape, and anisotropic etching is performed on the first insulation film 16a using the patterned resist film as a mask. As a pattern for this resist film, in addition to the shape processing for the contact plug portion, a shape processing for the part of the first optical waveguide portion 10Aa is performed to simultaneously form the shape of the first insulation film 16a due to forming the contact plug and the part of the first optical waveguide portion 10Aa. Further in a similar way, in order to form a recess such as a hole or a groove of the first wiring 17a integrated with a contact plug portion as well as the first optical waveguide tube portion 10Aa integrated with a part of the first optical waveguide tube portion 10Aa, a photosensitive resist film is applied over the first insulation film 16a and is exposed to light and developed to have a predetermined patterned shape, and anisotropic etching is performed on the first insulation film 16a using the patterned resist film as a mask. As a pattern for this resist film, in addition to the first wiring 17a, a shape processing for the first optical waveguide portion 10Aa is performed to simultaneously form the shape of the first insulation film 16a due to forming the first wiring 17a and the first optical waveguide portion 10Aa.

After the etching for the first insulation film 16a, a metal film for contact plugs or wirings is grown by metal sputtering on the first insulation film 16a. The metal film made from aluminum or tungsten, for example, for contact plugs or wirings can also be grown with CVD. Additionally, a barrier metal film is sputtered prior to metal sputtering in order to prevent silicidation with the foundation. Subsequently, the entire surface of the first insulation film 16a is etched to remove the sputtered film on the first insulation film 16a to simultaneously form a first wiring 17a and a first optical waveguide tube portion 10Aa embedded in holes of the first insulation film 16a. This etching for the entire surface can be performed, for example, by polishing with CMP.

Subsequently in the similar manner, a second insulation film 16b is formed on the first insulation film 16a, a second wiring 17b and a second optical waveguide tube portion 10Ab are simultaneously embedded and formed in the second insulation film 16b, and a third insulation film 16a is formed on the second insulation film 16b, a third wiring 17c and a third optical wave guide tube portion 10Ac are simultaneously embedded and formed in the third insulation film 16c, and further a fourth insulation film 16d is formed.

Then, color filters 8 arranged for respective colors are formed on the fourth insulation film 16d used as a planarization film to correspond to respective light receiving sections 2; a fifth insulation film 16e as a planarization film is formed on the color filters 8; and microlenses 9 are formed on the fifth insulation film 16e. As a result, a solid-state image capturing device 20A having an optical waveguide 10A (optical waveguide tube portions 10Aa-10Ac) as shown in FIG. 8 is manufactured.

The method described above for manufacturing the solid-state image capturing device 20A will be described in a more simplified manner.

The method for manufacturing the solid-state image capturing device 20A to form the wiring film of the first layer includes: a first insulation film forming step of forming a first insulation film 16a on the semiconductor substrate, wherein a plurality of light receiving sections 2 are formed in two dimensions and gate electrode films 4 are formed adjacent to the light receiving sections 2; a first resist film forming step of patterning a first resist film in the first insulation film 16a to have shapes corresponding to the first contact plug to the gate electrode films 4 and a part of the first optical waveguide tube portion 10Aa; a first recess shape forming step of processing a first recess shape corresponding to the contact plug and the part of the first optical waveguide tube portion 10Aa in the first insulation film 16a using the first resist film as a mask; a second resist film forming step of patterning a second resist film on the first insulation film 16a to have shapes corresponding to the first wiring 17a integrated with the contact plug portion and the first optical waveguide tube portion 10Aa integrated with the part of the first optical waveguide tube portion 10Aa; a second recess shape forming step of processing a second recess shape corresponding to the first wiring 17a and the first optical waveguide tube portion 10Aa in the first insulation film 16a using the second resist film as a mask; a first metal film coating step of coating a first metal film on the first insulation film 16a having the first recess shape and the second recess shape formed therein; a step of removing the first metal film on the entire first insulation film 16a such that the first metal film remains in the recess so as to form the first wiring 17a and the first optical waveguide tube portion 10Aa in the respective recesses.

The method for manufacturing the solid-state image capturing device 20A to form the wiring film of the second layer includes: a second insulation film forming step of forming a second insulation film 16b on the first insulation film 16a having a first wiring 17a and a first optical waveguide tube portion 10Aa formed thereon; a third resist film forming step of patterning a third resist film in the second insulation film 16b to have shapes corresponding to a contact plug and a part of a second optical waveguide tube portion 10Ab; a third recess shape forming step of processing third recess shapes corresponding to the contact plug and the part of the second optical waveguide tube portion 10Ab in the second insulation film 16b using the third resist film as a mask; a fourth resist film forming step of patterning a fourth resist film on the second insulation film 16b to have shapes corresponding to the second wiring 17b integrated with the contact plug and the second optical waveguide tube portion 10Ab integrated with the part of the second optical waveguide tube portion 10ab; a fourth recess shape forming step of processing a fourth recess shape corresponding to the second wiring 17b and the second optical waveguide tube portion 10Ab in the second insulation film 16b using the fourth resist film as a mask; a second metal film coating step of coating a second metal film on the second insulation film 16b having the third recess shape and the fourth recess shape formed thereon; and a step of removing the second metal film on the entire second insulation film 16b such that the second metal film remains in the recesses so as to form the second wiring 17b and the second optical waveguide tube portion 10Ab in the respective recesses.

The method for manufacturing the solid-state image capturing device 20A to form the wiring film of the third layer includes: a third insulation film forming step of forming a third insulation film 16a on the second insulation film 16b provided with the second wiring 17b and the second optical waveguide tube portion 10Ab; a fifth resist film forming step of patterning a fifth resist film in the third insulation film 16c to have shapes corresponding to the contact plug and a part of the third optical waveguide tube portion 10Ac; a fifth recess shape forming step of processing fifth recess shapes corresponding to the contact plug and the part of the third optical waveguide tube portion 10Ac in the third insulation film 16a using the fifth resist film as a mask; a sixth resist film forming step of patterning a sixth resist film on the third insulation film 16c to have shapes corresponding to the third wiring 17c integrated with the contact plug and the third optical waveguide tube portion 10Ac integrated with the part of the third optical waveguide tube portion 10Ac; a sixth recess shape forming step of processing sixth recess shapes corresponding to the third wiring 17a and the third optical waveguide tube portion 10AC in the third insulation film 160 using the sixth resist film as a mask; a third metal film coating step of coating a third metal film on the third insulation film 16a having the fifth recess shape and the sixth recess shape formed thereon; and a step of removing the third metal film on the entire third insulation film 16c such that the third metal film remains in the recesses so as to form the third wiring 17c and the third optical waveguide tube portion 10Ac in the respective recesses.

As described above, three layers of wiring films are used in Embodiment 2 of the present invention. However, the present invention is not limited to this. Alternatively, the number of wiring films can be one or two. Still alternatively, the number of wiring films can be four or more. Further, the case where the arbitrary N number of the wiring films is used will be described.

The method for manufacturing the solid-state image capturing device 20 to form the wiring film of the Nth layer includes, in addition to the steps described above: an Nth insulation film forming step of forming an Nth insulation film 16 on an (N−1)th insulation film 16 provided with an (N−1)th wiring 17 and an (N−1)th optical waveguide tube portion; a (2N−1)th resist film forming step of patterning a (2N−1)th resist film on the Nth insulation film 16 to have shapes corresponding to a contact plug and a part of the Nth optical waveguide tube portion; a (2N−1)th recess shape forming step of processing (2N−1)th recess shapes corresponding to the contact plug and the part of the Nth optical waveguide tube portion in the Nth insulation film 16 using the (2N−1)th resist film as a mask; a 2Nth resist film forming step of patterning a 2Nth resist film in the Nth insulation film 16 to have shapes corresponding to the Nth wiring 17 integrated with the contact plug and the Nth optical waveguide tube portion integrated with the part of the Nth optical waveguide tube portion; a 2Nth recess shape forming step of processing 2Nth recess shapes corresponding to the Nth wiring 17 and the Nth optical waveguide tube portion in the Nth insulation film 16 using the 2Nth resist film as a mask; an Nth metal film coating step of coating an Nth metal film on the Nth insulation film 16 having the (2N−1)th recess shape and the Nth recess shape formed thereon; and a step of removing the Nth metal film on the entire Nth insulation film 16 such that the Nth metal film remains in the recesses so as to form the Nth wiring 17 and the Nth optical waveguide tube portion in the respective recesses. Additionally, the method for manufacturing the solid-state image capturing device 20 further includes: a color filter forming step of forming color filters 8 arranged for respective colors to correspond to respective light receiving sections 2 on the (N+1)th insulation film 6; an (N+2)th insulation film forming step of forming an (N+2)th insulation film on the color filters 8; and a microlens forming step of forming microlenses 9 on the (N+2)th insulation film.

According to Embodiment 2 of the present invention, optical waveguide tube portions equivalent to two layers in Embodiment 1 are simultaneously embedded, so that it is more likely to facilitate the alignment of the inner surfaces of the optical waveguide 10A, thereby reducing optical feedback and enhancing reflection.

### Embodiment 3

Embodiment 1 has described the case where an optical waveguide 10 is formed by sequentially laminating a plurality of tubular optical waveguide tube portions 10a to 10f with one layer vertically at one time as the contact plugs 5 or wiring layers 7 being formed, and Embodiment 2 has described the case where two layers of the optical waveguide tube portions 10a to 10f are simultaneously laminated at one time to reduce unevenness of the alignment of the metal surfaces resulting from vertically laminating the optical waveguide tube portions 10a to 10f. Embodiment 3 describes a case where three or five of the lower layers of the optical waveguide tube portions 10a to 10f are laminated at one time to reduce unevenness of the alignment of the metal surfaces resulting from vertically laminating the optical waveguide tube portions 10a to 10f.

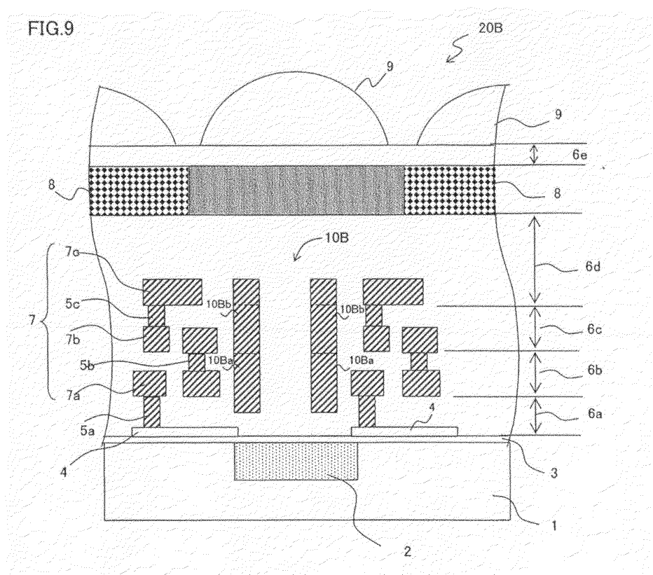

FIG. 9 is a longitudinal cross-sectional view showing an exemplary essential structure of a solid-state image capturing device 20B according to Embodiment 3 of the present invention. Members attaining similar effects as those shown in FIG. 1 are denoted with the same reference numerals as used in FIG. 1 and the descriptions therefore will be omitted.

In the solid-state image capturing device 20B of Embodiment 3 in FIG. 9, a plurality of light receiving sections 2 are provided in two dimensions on a semiconductor substrate and gate electrode films 4 are provided to be adjacent to the light receiving sections 2. On the semiconductor substrate, plural-layered contact plugs 5 (a first contact plug 5a, a second contact plug 5b and a third contact plug 5c) and/or a plurality of interlayer insulation films 6 (a first insulation film 6a, second insulation film 6b, third insulation film 6c, and fourth insulation film 6d) and a plurality of wiring layers 7 (a first wiring 7a, second wiring 7b, and third wiring 7a) are respectively configured alternately to have a sandwich structure. Upon forming the second contact plugs 5b, 5c and the third wiring layers 7c, corresponding tubular optical waveguide portions 10Ba and 10Bb will be at the same time formed sequentially, thereby forming an optical waveguide 10B. Specifically, a first insulation film 6a is formed over the gate electrode films 4 and the light receiving sections 2 on the semiconductor substrate 1, a first contact plug 5a is formed in the first insulation film 6a, a first wiring 7a is formed on the first insulation film 6a, a second insulation film 6b is formed on the first wiring 7a, a second contact plug 5b and an optical waveguide portion 10Ba are formed in the second insulation film 6b, a second wiring 7b is formed on the second insulation film 6b, a third insulation film 6a is formed on the second insulation film 6b, a third contact plug 5a and a part of an optical waveguide portion 10Bb are formed in the third insulation film 6c, a third wiring 7a and the rest of the optical waveguide tube portion 10Bb are formed on the third insulation film 6a, and further a fourth insulation film 6d is formed on the third insulation film 6a.

In this case, for example, a method is provided for a solid-state image capturing device for forming a plurality of conductive films via respective insulation films on a region other than a region right above the light receiving section and forming an optical waveguide above a light receiving section, a plurality of light receiving sections being provided in a top surface portion of a semiconductor substrate. The method includes: a contact plug/first optical waveguide tube portion forming step of forming a first optical waveguide tube portion simultaneously when a contact plug is formed, the first optical waveguide tube portion being formed using the same material as that for the contact plug, the contact plug being used for electrically connecting at least one of between the semiconductor substrate and the conductive films, and the plurality of conductive films, the first optical waveguide tube portion forming a portion of an optical waveguide; and a conductive film/second optical waveguide tube portion forming step of forming a second optical waveguide tube portion on the first optical waveguide tube portion simultaneously when a single-layered conductive film or at least one of plural-layered conductive films is formed, the second optical waveguide tube portion being formed using the same material as that for the conductive film.

The contact plug/first optical waveguide tube portion forming step includes: for example, a first insulation film forming step of forming a first insulation film on a semiconductor substrate; a first contact plug forming step of forming a first contact plug in the first insulation film; a first wiring film forming step of forming a first wiring (a first wiring film) on the first insulation film having the first contact plug formed therein; a second insulation film forming step of forming a second insulation film on the substrate having the first wiring formed thereon; and a second contact plug/first optical waveguide tube portion forming step of forming a second contact plug in the second insulation film and forming a first optical waveguide tube portion in the second insulation film and the first insulation film at the same time. Further, the conductive film/second optical waveguide tube portion forming step includes: for example, a second wiring forming step of forming a second wiring on the second insulation film having the second contact plug and the first optical waveguide tube portion formed therein; a third insulation film forming step of forming a third insulation film on the substrate having the second wiring formed thereon; a third contact plug/second optical waveguide tube portion partially forming step of forming a third contact plug and a part of a second optical waveguide tube portion in the third insulation film; and a third wiring/second optical waveguide tube forming step of forming a third wiring and the rest of the second optical waveguide tube portion on the third insulation film having the third contact plug and the part of the optical waveguide tube portion formed therein.

As described above, it has been described that three layers of the optical waveguide tube portions 10a-10c of the optical waveguide tube portions 10a-10f according to Embodiment 1 of the present invention are simultaneously embedded. However, the present invention is not limited to this. Alternatively, it is also possible to simultaneously embed five layers of the optical waveguide tube portions 10a-10e of the optical waveguide tube portions 10a-10f according to Embodiment 1 described above.

In this case, the contact plug/first optical waveguide tube portion forming step includes: a first insulation film forming step of forming a first insulation film on a semiconductor substrate; a first contact plug forming step of forming a first contact plug in the first insulation film; a first wiring film forming step of forming a first wiring on the first insulation film having the first contact plug formed therein; a second insulation film forming step of forming a second insulation film on the substrate having the first wiring formed thereon; a second contact plug forming step of forming a second contact plug in the second insulation film; a second wiring film forming step of forming a second wiring on the second insulation film having the second contact plug formed therein; a third insulation film forming step of forming a third insulation film on the substrate having the second wiring formed thereon; and a third contact plug/first optical waveguide tube portion forming step of forming a third contact plug in the third insulation film and forming a first optical waveguide tube portion in the third insulation film, the second insulation film and the first insulation film at the same time.

### Embodiment 4

Embodiment 4 describes a case where a shading film is formed on a plurality of wiring layers, the shading film integrated with the top portion of the optical waveguide tube portion.

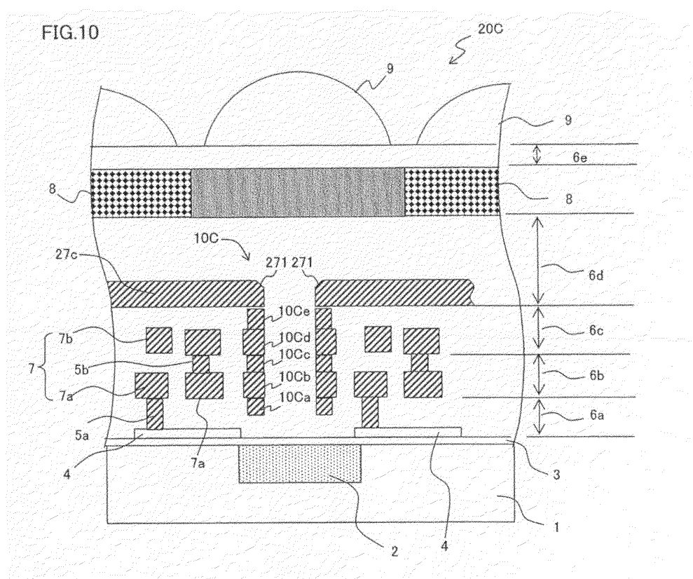

FIG. 10 is a longitudinal cross-sectional view showing an exemplary essential structure of a solid-state image capturing device 20C according to Embodiment 4 of the present invention. Members attaining similar effects as those shown in FIG. 1 are denoted with the same reference numerals as used in FIG. 1 and the descriptions therefore will be omitted.

In the solid-state image capturing device 20C of Embodiment 4 in FIG. 10, a plurality of light receiving sections 2 are provided in two dimensions on a semiconductor substrate and gate electrode films 4 are provided to be adjacent to the light receiving sections 2. On the semiconductor substrate, plural-layered contact plugs 5 (a first contact plug 5a, a second contact plug 5b and a third contact plug 5c) and/or a plurality of interlayer insulation films 6 (a first insulation film 6a, second insulation film 6b, third insulation film 6c, and fourth insulation film 6d) and a plurality of wiring layers 7 (a first wiring 7a and second wiring 7b) are respectively configured alternately to have a sandwich structure. Upon forming a plurality of the contact plugs 5b and a plurality of the wiring layers 7c, corresponding tubular optical waveguide portions 10Ca to 10Ce will be at the same time formed sequentially, and further a shading film 27a will be formed, thereby forming an optical waveguide 10C. Specifically, a first insulation film 6a is formed over the gate electrode films 4 and the light receiving sections 2 on the semiconductor substrate 1, a first contact plug 5a and a first optical waveguide tube portion 10Ca are formed in the first insulation film 6a, a first wiring 7a and an optical waveguide tube portion 10Cb are formed on the first insulation film 6a, a second insulation film 6b is formed on the first insulation film 6a, a second contact plug 5b and an optical waveguide portion 10Ce are formed in the second insulation film 6b, a second wiring 7b and an optical waveguide tube portion 10Cd are formed on the second insulation film 6b, a third insulation film 6a is formed on the second insulation film 6b, a third contact plug 5c (not shown) and an optical waveguide tube portion 10Ce are formed in the third insulation film 6c, a thin insulation film is formed on the insulation film 6c, and thereafter, via the thin insulation film, a shading film 27c having the third wiring 7a and the optical waveguide tube portion 10f of Embodiment 1 connected with each other is formed instead of forming the third wiring 7c and the optical waveguide tube portion 10f, and further, a fourth insulation film 6d is formed on the shading film 27a.

In this case, the shading film 27c and the optical waveguide tube portions 10Ca-10Ce located therebelow, both of which form the optical waveguide 10C, are insulated from each other with a thin insulation film, so that the integrated optical waveguide tube portions 10Ca-10Ce are used as wirings such as a control line, a signal line, a power supply line or a clock line. As a matter of fact, instead of insulating with a thin insulation film, the shading film 27c and the optical waveguide tube portions 10Ca-10Ce, both of which form the optical waveguide 10c, can be integrated as one, so that integrated shading film 27a and optical waveguide tube portions 10Ca-10Ce are used as wirings such as a control line, a signal line, a power supply line or a clock line. Further, thin insulation films can be interposed between the optical waveguide tube portions 10Ca-10Ce in order to further divide them. In this case, two systems of wirings and optical waveguide tube portions can be commonly shared.

Further, the shading film 27a forming the entrance for the optical waveguide tube portion can have a large taper 271 at the corner of the shading film 270 by adjusting etching conditions and the like, so that a portion or all of the opening of each optical waveguide tube portion can be larger. It is necessary to consider that forming a taper at the corner results in a taper being also formed at the corner where a taper is not needed.

As described above, according to Embodiment 4 of the present invention, limitation of spaces for the manufacturing can be reduced by integrating the shading film 27a with the top portion of the optical waveguide tube portion and commonly sharing them as well as by using a part or all of each of the tube portions of the optical waveguide 10C itself as a wiring. Also, it is possible to cause light to be incident into only the optical waveguide 10C using the shading film 27c on the top layer. Further, it is possible that a taper 271 is added in the inner corner of the shading film 27a forming the top portion of the optical waveguide tube portion depending on etching conditions and the like, so that the opening of the optical waveguide 10C can be wider for more incident light.

### Embodiment 5

Embodiment 1 has described the case where an optical waveguide 10 is formed by sequentially laminating a plurality of tubular optical waveguide tube portions 10a to 10f with one layer vertically at one time as the contact plugs 5 or wiring layers 7 being formed. Embodiment 5 describes a case where a first optical waveguide tube portion is not formed only when a first contact plug at the lowest location is formed (at the time of a first contact plug forming step) and this is applied to Embodiment 1 of the present invention.

The reason being that if etching is performed to have the recess shape of the first optical waveguide tube portion above the light receiving section 2 simultaneously with etching to have the recess shape of the first contact plug at the lowest location, the depths of both the recess shape of the first contact plug and the recess shape of the first optical waveguide tube portion will be the same, and the position of the bottom portion of the recess shape of the light receiving section 2 will be close to and above the light receiving section 2, thereby resulting in etching damage in the light receiving section 2.

In order to prevent the etching damage in the light receiving section 2, although not described in Embodiments 1 to 4, it is necessary to construct an etching stop layer in the bottom portion of the recess shape of the first optical waveguide tube portion or use two photo resist films with different patterns to separately yet sequentially form the recess shape of the first contact plug and the recess shape of the first optical waveguide tube portion so far away as to reduce the damage to the light receiving section 2. The etching stop layer in this case is coated excluding the wide light receiving center portion above the light receiving section 2, whose surface area is significantly smaller than that of the prior art that covers almost all the area above the light receiving section 2, thereby significantly reducing adverse effects by the etching stop layer on the light receiving section 2. Further, in the case where both of the recess shape of the first contact plug and the recess shape of the first optical waveguide tube portion are separately yet sequentially formed using two photoresist films of different patterns, despite a demerit of having more steps for processing, the depth of the recess shape of the first optical waveguide tube portion are able to be shallower than the depth of the recess shape of the first contact plug, thereby reducing or preventing etching damages to the light receiving section 2. In view of this, the first optical waveguide tube portion is formed at the same time (or at the same step) when the first contact plug is formed (first contact plug forming step) in Embodiments 1 through 4.

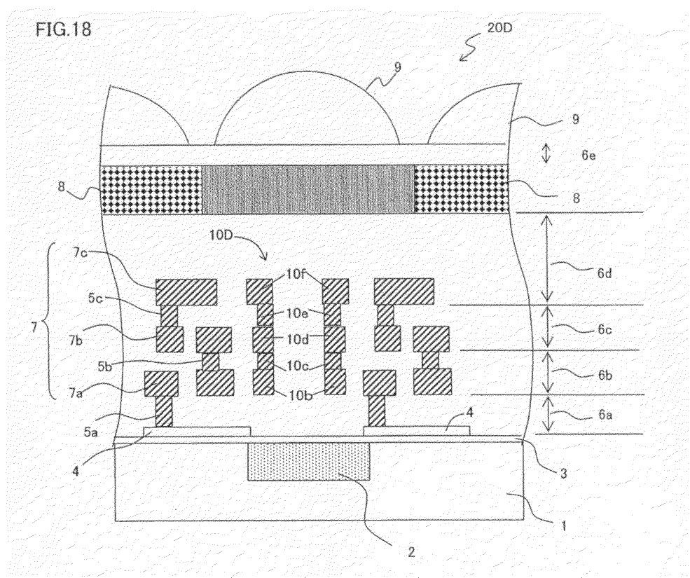

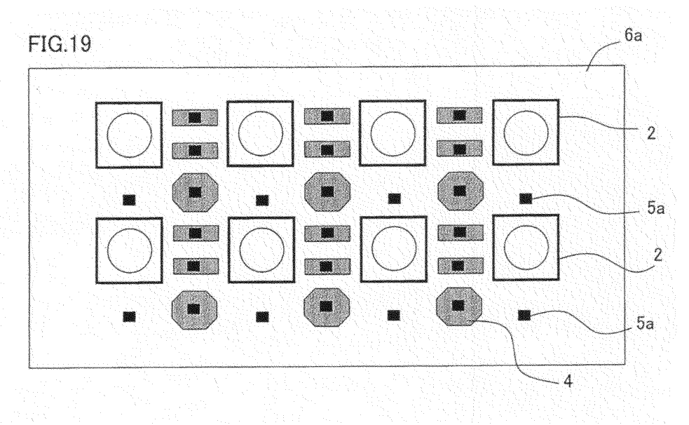

FIG. 18 is a longitudinal cross-sectional view showing one exemplary essential structure of a solid-state image capturing device 20D according to Embodiment 5 of the present invention. FIG. 19 is a top view for describing a contact plug forming step for the solid-state image capturing device 20D in FIG. 18.

As shown in FIGS. 18 and 19, in order to manufacture the solid-state image capturing device 20D, subsequent to the formation of the gate electrode film 4, first, the first insulation film 6a is grown using a SiO₂ material such as BPSG (Boron Phosphor Silicate Glass) and/or high-density plasma SiO₂ (HDP-SiO₂) on the gate electrode film 4. The surface of the first insulation film 6a is polished by CMP mainly for the purpose of planarization so as to facilitate the following step. This is the same as the case for Embodiment 1.

Next, after the polishing of the first insulation film 6a, to form the first contact plug 5a (the first optical waveguide tube portion 10a is not formed), a photosensitive resist material is applied over the first insulation film 6a and is exposed to light and developed to have a predetermined patterned shape, and anisotropic etching is performed on the first insulation film 6a using the patterned resist film as a mask. The shape of the first contact plug 5a is processed using the resist film as a mask.

After the etching for the first insulation film 6a, a metal film for contact plugs is grown by metal sputtering on the first insulation layer 6a. The metal film made from tungsten, for example, for contact plugs can also be grown with CVD. Additionally, a barrier metal film is sputtered prior to metal sputtering in order to prevent silicidation with the foundation. Subsequently, the entire surface of the first insulation film 6a is etched to remove a sputtered film on the first insulation film 6a to form a first contact plug 5a embedded in a hole (recess shape) of the first insulation film 6a. This etching for the entire surface can be performed, for example, by polishing with CMP. FIG. 19 shows a top view of the shape formed at the steps described above. FIG. 19 shows photodiodes (light receiving sections 2) and gate electrode films 4 that are not present on the same plane as the first contact plug 5a for the purpose of clarifying the locational relationship with the first contact plug 5a.

The steps thereafter is repeatedly formed as in the case of Embodiment 1 to form an optical waveguide 10D thereby manufacturing a solid-state image capturing device 20D according to Embodiment 5 of the present invention.

The method described above for manufacturing the solid-state image capturing device 20D will be more generalized and simply described.

The method for manufacturing the solid-state image capturing device 20D to form the wiring film of the first layer includes: a first insulation film forming step of forming a first insulation film 6a on the semiconductor substrate, wherein a plurality of light receiving sections 2 are formed in two dimensions and gate electrode films 4 are formed adjacent to the light receiving sections 2; a first resist film forming step of patterning a first resist film in the first insulation film 6a to have a shape corresponding to the first contact plug 5a; a first recess shape forming step of processing a first recess shape corresponding to the first contact plug 5a in the first insulation film 6a using the first resist film as a mask; a first metal film coating step of coating a first metal film on the substrate having the first recess shape formed thereon; a step of removing the first metal film on the entire first insulation film 6a such that the first metal film remains in the recess so as to form the first contact plug 5a in the respective recess; a second metal film coating step of coating a second metal film on the substrate having the first contact plug 5a formed thereon; a second resist film forming step of patterning a second resist film on the second metal film to have shapes corresponding to the first wiring 7a and the second optical waveguide tube portion 10b; a step of forming a first wiring 7a and the second optical waveguide tube portion 10b from the second metal film using the second resist film as a mask; and a second insulation film forming step of forming a second insulation film 6b on the substrate having the first wiring 7a and the second optical waveguide tube portion 10b formed thereon. Because the method for manufacturing the solid-state image capturing device 20D does not form a first optical waveguide tube portion 10a, the second optical waveguide tube portion 10b is the lowest optical waveguide tube portion.

In addition to the above description, the method for manufacturing the solid-state image capturing device 20D includes: a (2N−1)th (N is an integer greater than or equal to 2) resist film forming step of patterning a (2N−1)th resist film in an Nth insulation film 6 to have shapes corresponding to an Nth contact plug 5 and an (2N−1) th optical waveguide tube portion; an Nth recess shape forming step of processing an Nth recess shape corresponding to the Nth contact plug 5 and the (2N−1)th optical waveguide tube portion in the Nth insulation film 6 using the (2N−1) th resist film as a mask; a (2N−1)th metal film coating step of coating a (2N−1)th metal film on the substrate having the Nth recess shape formed thereon; a step of removing the (2N−1)th metal film on the entire Nth insulation film 6 such that the (2N−1)th metal film remains in the Nth recess so as to form the Nth contact plug 5 and the (2N−1) th optical waveguide tube portion in the respective Nth recesses; a 2Nth metal film coating step of coating a 2Nth metal film on the substrate having the Nth contact plug 5 and the (2N−1)th optical waveguide tube portion formed thereon; a 2Nth resist film forming step of patterning a 2Nth resist film on the 2Nth metal film to have shapes corresponding to an Nth wiring 7 and a 2Nth optical waveguide tube portion; a step of forming the Nth wiring 7 and the 2Nth optical waveguide tube portion from the 2Nth metal film using the 2Nth resist film as a mask; and an (N+1)th insulation film forming step of forming an (N+1)th insulation film 6 on the substrate having the Nth wiring 7 and the 2N optical waveguide tube portion formed thereon. Further, the method for manufacturing the solid-state image capturing device 20D includes: a color filter forming step of forming color filters 8 arranged for respective colors on the (N+1)th insulation film 6; an (N+2)th insulation film forming step of forming an (N+2)th insulation film on the color filters; and a microlens forming step of forming a microlenses on the (N+2)th insulation film.

### Embodiment 6

Embodiment 2 has described a case where two layers of the optical waveguide tube portions 10a to 10f are simultaneously laminated at one time (with lower layers being smaller size-wise and upper layers larger), depending on the alignment accuracy of the optical waveguide tube portions 10a to 10f, to reduce unevenness of the alignment of the metal surfaces resulting from vertically laminating the optical waveguide tube portions 10a to 10f. Embodiment 6 describes a case where a part of a lower portion of a first optical waveguide tube portion 10Aa is not formed only when a first contact plug is formed (at the time of a first contact plug forming step) and this is applied to Embodiment 2 of the present invention. The reason why a part of a lower portion of the first optical waveguide tube portion 10Aa is not formed is that if etching is performed to have the recess shape of the first optical waveguide tube portion at the same time when etching is performed to have the recess shape of the first contact plug, the depths of both the recess shape of the first contact plug and the recess shape of the first optical waveguide tube portion will be the same, and the position of the bottom portion of the recess shape of the light receiving section 2 will be close to and above the light receiving section 2, thereby resulting in etching damage to the light receiving section 2.

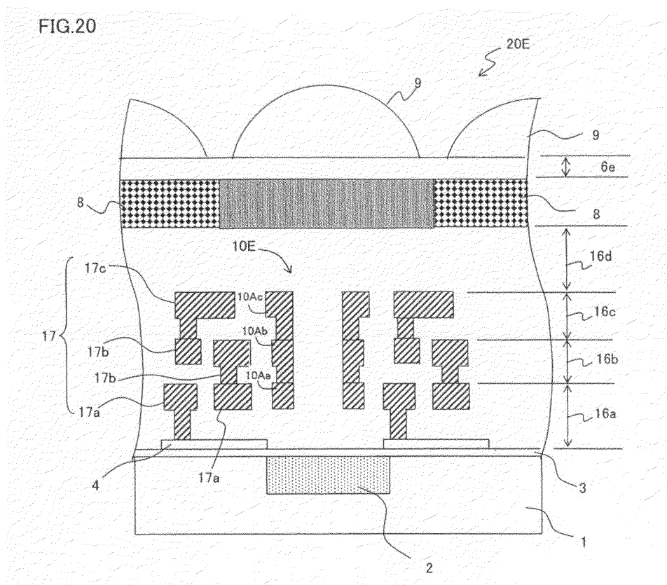

FIG. 20 is a longitudinal cross-sectional view showing another exemplary essential structure of a solid-state image capturing device 20E according to Embodiment 6 of the present invention.

As shown in FIG. 20, in order to manufacture the solid-state image capturing device 20E, subsequent to the formation of the gate electrode film 4, first, the first insulation film 16a is grown using a SiO₂ material such as BPSG (Boron Phosphor Silicate Glass) and/or high-density plasma SiO₂ (HDP-SiO₂) on the gate electrode film 4. The surface of the first insulation film 16a is polished by CMP mainly for the purpose of planarization so as to facilitate the following step.

Next, after the polishing of the first insulation film 16a, to form a recess such as a hole or a groove of a contact plug portion to the gate electrode film 4, a photosensitive resist material is applied over the first insulation film 16a and is exposed to light and developed to have a predetermined patterned shape, and anisotropic etching is performed on the first insulation film 16a using the patterned resist film as a mask. For a pattern for the resist mask film, the shape processing for the contact plug portion is performed, so that the recess shape of the first insulation film 16a is formed due to forming the contact plug. Further in the same manner, to form a recess such as a hole or a groove of the first wiring 17a integrated with the contact plug portion and the first optical waveguide tube portion 10Aa, another photosensitive resist material is applied over the first insulation film 16a and is exposed to light and developed to have a predetermined patterned shape, and anisotropic etching is performed on the first insulation film 16a using the patterned resist film as a mask. Using the resist film as a mask, in addition to the first wiring 17a with which the contact plug portion is integrated, a shape processing for the first optical waveguide portion 10Aa is performed to simultaneously form the shape of the first insulation film 16a due to forming the first wiring 17a and the first optical waveguide portion 10Aa.

After the etching for the first insulation film 16a, a metal film for contact plugs or wirings is grown by metal sputtering on the first insulation layer 16a. The metal film made from aluminum or tungsten, for example, for contact plugs or wiring can also be grown with CVD. Additionally, a barrier metal film is sputtered prior to metal sputtering in order to prevent silicidation with the foundation. Subsequently, the entire surface of the first insulation film 16a is etched to remove a sputtered film on the first insulation film 16a to simultaneously form the first wiring 17a and the first optical waveguide tube portion 10Aa embedded in respective holes (recess shape) of the first insulation film 16a. This etching for the entire surface can be performed, for example, by polishing with CMP.

Subsequent to the formation of the first wiring 17a and the first optical waveguide tube portion 10Aa, a second insulation film 16b is grown using a SiO₂ material such as BPSG (Boron Phosphor Silicate Glass) and/or high-density plasma SiO₂ (HDP-SiO₂) on the first insulation film 16a. The surface of the second insulation film 16b is polished by CMP mainly for the purpose of planarization so as to facilitate the following step.

After polishing the second insulation film 16b, in order to form a recess such as a hole or a groove of a contact plug portion to the predetermined first wiring 17a and a part of a second optical waveguide tube portion 10Ab, a photosensitive resist film is applied over the second insulation film 16b and is exposed to light and developed to have a predetermined patterned shape, and anisotropic etching is performed on the second insulation film 16b using the patterned resist film as a mask. For a pattern of the resist mask film, in addition to the shape processing of the contact plug portion, a shape processing for the part of the second optical waveguide tube portion 10Ab is performed to simultaneously form the shape of the second insulation film 16b due to forming of the contact plug and the part of the second optical waveguide tube portion 10Ab. Further in the similar manner, to form a recess such as a hole or a groove of the second wiring 17b integrated with the contact plug portion and the second optical waveguide tube portion 10Ab integrated with the part of the second optical waveguide tube portion 10Ab, a photosensitive resist material is applied over the second insulation film 16b and is exposed to light and developed to have a predetermined patterned shape, and anisotropic etching is performed on the second insulation film 16b using the patterned resist film as a mask. For a pattern for the resist mask film, in addition to the second wiring 17b, a shape processing for the second optical waveguide portion 10Ab is performed to simultaneously form the shape of the second insulation film 16b due to forming the second wiring 17b and the second optical waveguide portion 10Ab.

After the etching on the second insulation film 16b, a metal film for contact plugs or wirings is grown by metal sputtering on the second insulation layer 16b. The metal film made from aluminum or tungsten, for example, for contact plugs or wiring can also be grown with CVD. Additionally, a barrier metal film is sputtered prior to metal sputtering in order to prevent silicidation with the foundation. Subsequently, the entire surface of the second insulation film 16b is etched to remove a sputtered film on the second insulation film 16b to form a second wiring 17b and a second optical waveguide tube portion 10Ab embedded in respective holes (recess shape) of the second insulation film 16b. This etching for the entire surface can be performed, for example, by polishing with CMP.

The steps thereafter are repeatedly formed as in the case of Embodiment 2 to form an optical waveguide 10E thereby manufacturing a solid-state image capturing device 20E according to Embodiment 6 of the present invention.

The method described above for manufacturing the solid-state image capturing device 20E will be more generalized and simply described.

The method for manufacturing the solid-state image capturing device 20E to form the wiring film of the first layer includes: a first insulation film forming step of forming a first insulation film 16a on the semiconductor substrate, wherein a plurality of light receiving sections 2 are formed in two dimensions and gate electrode films 4 are formed adjacent to the light receiving sections 2; a first resist film forming step of patterning a first resist film on the first insulation film 16a to have a shape corresponding to the contact plug on the gate electrode 4; a first recess shape forming step of processing a first recess shape corresponding to the contact plug in the first insulation film 16a using the first resist film as a mask; a second resist film forming step of patterning a second resist film on the first insulation film 16a to have shapes corresponding to the first wiring 17a integrated with the contact plug and the first optical waveguide tube portion 10Aa; a second recess shape forming step of processing second recess shapes corresponding to the first wiring 17a integrated with the contact plug portion and the first optical waveguide tube portion 10Aa in the first insulation film 16a using the second resist film as a mask; a first metal film coating step of coating a first metal film on the first insulation film 16a having the first recess shape and the second recess shape formed therein; and a step of removing the first metal film on the entire first insulation film 16a such that the first metal film remains in the recess so as to form the first wiring 17a integrated with the contact plug portion and the first optical waveguide tube portion 10Aa in the respective recesses.

In addition to the above description, the method for manufacturing the solid-state image capturing device 20E includes: an Nth (N is an integer greater than or equal to 2) insulation film forming step of forming an Nth insulation film 16 on an (N−1)th insulation film 16 having an (N−1)th wiring 17 and an (N−1)th optical waveguide tube portion provided therein; a (2N−1)th resist film forming step of patterning a (2N−1)th resist film on the Nth insulation film 16 to have shapes corresponding to a contact plug and a part of an Nth optical waveguide tube portion; a (2N−1)th recess shape forming step of processing (2N−1)th recess shapes corresponding to the contact plug and the part of the Nth optical waveguide tube portion in the Nth insulation film 16 using the (2N−1)th resist film as a mask; a 2N resist film forming step of patterning a 2Nth resist film on the Nth insulation film 16 to have shapes corresponding to the Nth wiring 17 integrated with the contact plug and the Nth optical waveguide tube portion integrated with the part of the optical waveguide tube portion; a 2Nth recess shape forming step of processing 2Nth recess shapes corresponding to the Nth wiring 17 and the Nth optical waveguide tube portion in the Nth insulation film 16 using the 2Nth resist film as a mask; an Nth metal film coating step of coating an Nth metal film on the Nth insulation film 16 having the (2N−1)th recess shape and the 2Nth recess shapes formed therein; and a step of removing the Nth metal film on the entire Nth insulation film 16 such that the Nth metal film remains in the recesses so as to form the Nth wiring 17 and the Nth optical waveguide tube portion in the respective recesses. Further, the method for manufacturing the solid-state image capturing device 20E includes: a color filter forming step of forming color filters 8 arranged for respective colors to correspond to light receiving sections 2 on an (N+1)th insulation film 6; an (N+2)th insulation film forming step of forming an (N+2)th insulation film on the color filters 8; and a microlens forming step of forming microlenses 9 on the (N+2)th insulation film.

### Embodiment 7

Embodiment 3 has described the case where lower three or five layers of the optical waveguide tube portions 10a to 10f are simultaneously laminated at one time to reduce unevenness of the alignment of the metal surfaces of the light reflecting surface resulting from vertically laminating the optical waveguide tube portions 10a to 10f. Embodiment 7 describes a case where a part of a lower portion of a tubular optical waveguide tube portion 10Ba is not formed at the same time only when a lowest contact plug 5a is formed and subsequently similar steps described above in Embodiment 3 will follow. The reason why a part of a lower portion of an optical waveguide tube portion is not formed is that if etching is performed to have the recess shape of the first optical waveguide tube portion simultaneously with etching to have the recess shape of the first contact plug, the depths of both the recess shape of the first contact plug and the recess shape of the first optical waveguide tube portion will be the same, and the position of the bottom portion of the recess shape of the light receiving section 2 will be close to and above a light receiving section 2, thereby resulting in etching damage in the light receiving section 2.

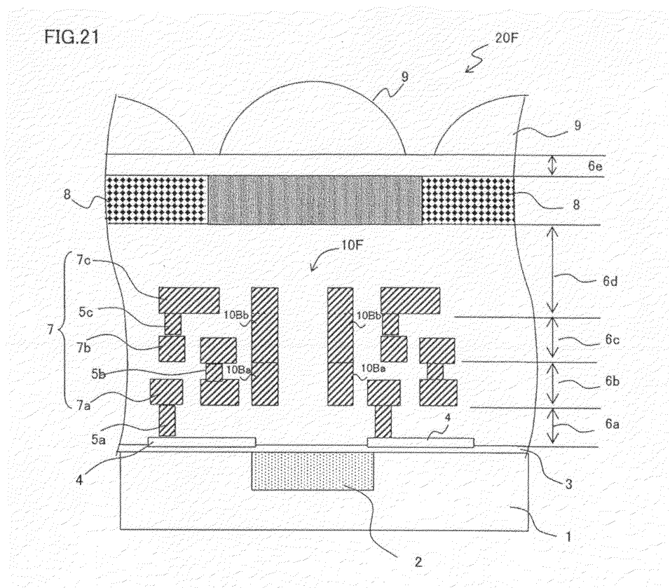

FIG. 21 is a longitudinal cross-sectional view showing still another exemplary essential structure of a solid-state image capturing device 20F according to Embodiment 7 of the present invention.

In the method for manufacturing the solid-state image capturing device 20F as shown in FIG. 21, a first insulation film 6a is formed over a gate electrode 4 and a light receiving section 2 on a semiconductor substrate 1; a first contact plug 5a is formed in the first insulation film 6a; a first wiring 7a is formed on the first contact plug 5a; a second insulation film 6b is formed on the first insulation film 6a; a second contact plug 5b and an optical waveguide tube portion 10Ba are formed in the second insulation film 6b; a second wiring 7b is formed on the second insulation film 6b; a third insulation film 6a is formed on the second insulation film 6b: a third contact plug 5c and a part of an optical waveguide tube portion 10Bb are in the third insulation film 6c; a third wiring 7c and the rest of the optical waveguide tube portion 10Bb are formed on the third contact plug 5a and the optical waveguide tube portion 10Bb; and a fourth insulation film 6d is formed on the third insulation film 6c.

In this case, for example, a method is provided to manufacture a solid-state image capturing device for forming a plurality of conductive films via respective insulation films on a region other than a region right above a light receiving section and forming an optical waveguide above the light receiving section, a plurality of light receiving sections being provided in a top surface portion of a semiconductor substrate. The method includes: a contact plug/first optical waveguide tube portion forming step of forming a first optical waveguide tube portion simultaneously when a contact plug is formed, the first optical waveguide tube portion being formed using the same material as that for the contact plug, the contact plug being used for electrically connecting at least one of between the semiconductor substrate and the conductive films, and the plurality of conductive films, the first optical waveguide tube portion forming a portion of an optical waveguide; and a conductive film/second optical waveguide tube portion forming step of forming a second optical waveguide tube portion on the first optical waveguide tube portion simultaneously when at least one of a single-layered conductive film or plural-layered conductive films is formed, the second optical waveguide tube portion being formed using the same material as that for the conductive film forming a part of the optical waveguide.

The contact plug/first optical waveguide tube portion forming step includes: for example, a first insulation film forming step of forming a first insulation film on a semiconductor substrate; a first contact plug forming step of forming a first contact plug in the first insulation film; a first wiring film forming step of forming a first wiring (a first wiring film) on the first insulation film having the first contact plug formed therein; a second insulation film forming step of forming a second insulation film on the substrate having the first wiring formed thereon; and a second contact plug/first optical waveguide tube portion forming step of forming a second contact plug in a second insulation film and forming a first optical waveguide tube portion only in the second insulation film at the same time. Further, the conductive film/second optical waveguide tube portion forming step includes: for example, a second wiring forming step of forming a second wiring on the second insulation film having the second contact plug and the first optical waveguide tube portion formed therein; a third insulation film forming step of forming a third insulation film on the substrate having the second wiring formed thereon; a third contact plug/second optical waveguide tube portion partially forming step of forming a third contact plug and a part of a second optical waveguide tube portion in the third insulation film; and a third wiring/second optical waveguide tube forming step of forming a third wiring and the rest of the second optical waveguide tube portion on the third insulation film having the third contact plug and the part of the second optical waveguide tube portion formed therein.

The steps described above can also be applied to the case where four layers of the optical waveguide tube portions 10b-10e according to Embodiment 1 are simultaneously embedded.

In this case, the contact plug/first optical waveguide tube portion forming step includes: a first insulation film forming step of forming a first insulation film on a semiconductor substrate; a first contact plug forming step of forming a first contact plug in the first insulation film; a first wiring film forming step of forming a first wiring (a first wiring film) on the first insulation film having the first contact plug formed therein; a second insulation film forming step of forming a second insulation film on the substrate having the first wiring formed thereon; a second contact plug forming step of forming a second contact plug in the second insulation film; a second wiring film forming step of forming a second wiring film on the second insulation film having the second contact plug formed therein; a third insulation film forming step of forming a third insulation film on the substrate having the second wiring formed thereon, and a third contact plug/first optical waveguide tube portion forming step of forming a third contact plug in the third insulation film and forming a first optical waveguide tube portion only in the third insulation film and the second insulation film at the same time.

### Embodiment 8

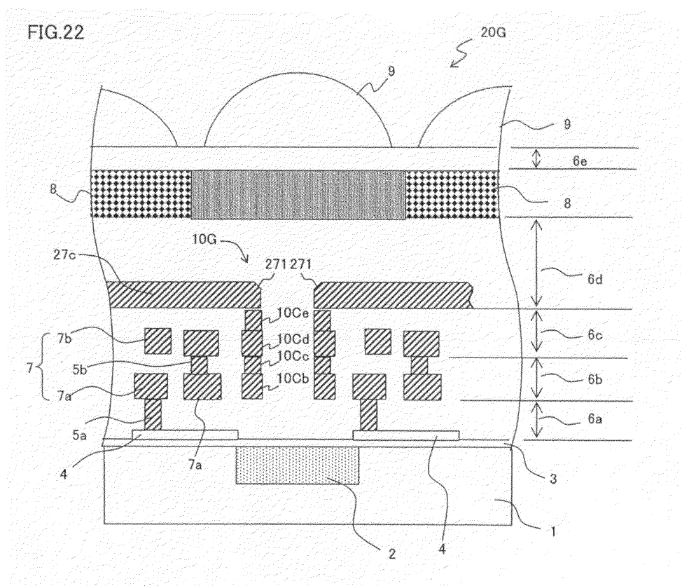

Embodiment 4 of the present invention has described the case where, in order to further reduce limitation of spaces for the manufacturing, the shading film 27c with the top portion of the optical waveguide tube portion are integrated and commonly shared, the optical waveguide tube portions 10Ca-10Ce themselves (similar to Embodiment 1) are commonly shared as some wirings, and a taper 271 is added to a light entrance portion, whereas Embodiment 8 of the present invention describes a case where the lowest optical waveguide tube portion 10Ca is not formed. The reason is the same as that of the case where the lowest optical waveguide tube portion 10a according to Embodiment 1 is not formed. FIG. 22 shows a solid-state image capturing device 20G with an optical waveguide 10G having the structure described above over a light receiving section 2. FIG. 22 shows a case where a first optical waveguide tube portion is not formed upon forming a first contact plug (at a first contact plug forming step), and this case is applied to FIG. 10 of Embodiment 4.

Embodiment 8 has described the case where a first optical waveguide tube portion is not formed upon forming a first contact plug applied to Embodiment 4. However the present invention is not limited to this. Alternatively, the above case can be adapted to both Embodiments 5 and 6. Needless to say, Embodiment 4 described above can be adapted to any of Embodiments 1 to 3.

### Embodiment 9

Embodiment 9 describes an electronic information device having, for example, a digital camera (e.g., digital video camera, digital still camera), an image input camera (e.g., monitoring camera, door intercom camera, car-mounted camera such as a car-mounted backside monitoring camera, camera for television telephone and camera for cell phone), and an image input device (e.g., scanner, facsimile and cell phone device equipped with camera) using a solid-state image capturing apparatus including any one of a solid-state image capturing devices 20 and 20A-20G according to Embodiments 1 to 8.

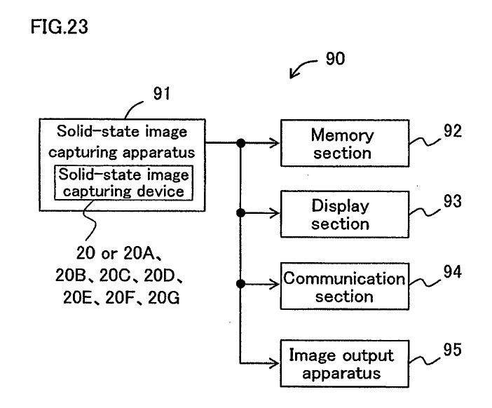

FIG. 23 is a block diagram showing an exemplary schematic structure of an electronic information device according to Embodiment 9 of the present invention using the solid-state image capturing apparatus as an image capturing section, the electronic information device including any one of the solid-state image capturing devices 20 and 20A-20G in Embodiments 1-8.

The electronic information device 90 according to Embodiment 9 in FIG. 23 includes at least one of the following: an solid-state image capturing apparatus 91 which performs various signal processes for high-quality image capturing signals with no image quality deterioration obtained by using any one of the solid-state image capturing devices 20 and 20A-20G according to Embodiments 1-8 as an image input device for an image capturing section in order to obtain color image signals; a memory section 92 (e.g., recording media) for data-recording color image signals from the solid-state image capturing apparatus 91 after a predetermined signal process for recording; a display section 93 (e.g., liquid crystal display device) for displaying the color image signals on a display screen (e.g., liquid crystal display screen) after a predetermined signal process is performed; a communication section 94 (e.g., transmitting and receiving device) for communicating image data after a predetermined signal process is performed on the color image signals; and an image output apparatus 95 for printing (typing out) and outputting (printing out) the color image signals.

Therefore, according to Embodiment 9 of the present invention, based on the color image signals from the solid-state image capturing apparatus 91, the color image signals can be: displayed on a display screen finely, printed out (printing) on a sheet of paper using the image output apparatus 95, communicated finely as communication data via a wire or a radio; stored finely at the memory section 92 by performing a predetermined data compression process; and various data processes can be finely performed.

Although not specifically described in Embodiments 1-9, if a plurality of optical waveguide tubes are configured as an optical waveguide according to the present invention using the same material as that of at least one of a plurality of conductive films, not only excellent effects on light focusing and light propagating will be obtained, but also the objective of not deteriorating image quality characteristics as conventionally can be achieved. Further, in the solid-state image capturing device for forming a plurality of conductive films via respective insulation films on a region other than a region right above a light receiving section and forming an optical waveguide above the light receiving section, a plurality of light receiving sections being provided in two dimensions in a top surface portion of a semiconductor substrate; a single-layered optical waveguide tube can be configured, as an optical waveguide according to the present invention, with the same material as that for any one of plural-layered conductive films or any one of contact plugs for electrically connecting between the semiconductor substrate and conductive films and/or between the conductive films. As a result, not only good effects on light focusing and light propagating will be obtained, but also the objective of not deteriorating image quality characteristics as conventionally can be achieved as well.

As described above, the present invention is exemplified by the use of its preferred Embodiments 1 to 9. However, the present invention should not be interpreted solely based on Embodiments 1 to 9 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 9 of the present invention. Furthermore, it is understood that any patent, any patent application and any references cited in the present specification should be incorporated by reference in the present specification in the same manner as the contents are specifically described therein.

### INDUSTRIAL APPLICABILITY

According to the present invention, in a field of a solid-state image capturing device (e.g., CMOS image sensor, CCD image sensor and the like) where an optical waveguide region is formed on each of the plurality of light receiving sections formed on a semiconductor substrate, a method for manufacturing the solid-state image capturing device, and an electronic information device, such as digital camera and a cell phone device equipped with camera, using the solid-state image capturing apparatus as an image capturing section; since a solid-state image capturing device having an optical waveguide region can be realized without providing a hole for forming a waveguide, the present invention can prevent the problem of a light receiving section from suffering etching damage, thus resulting in a deterioration of image quality characteristics in processing a hole for forming a waveguide while the present invention can enhance light usage efficiency. Further, since there is no need to coat a material with a high refractive index and a material with a low refractive index with CVD and the like and to form an optical waveguide region in a hole for forming a waveguide, it is possible to prevent a problem that impurities included in such materials are diffused toward the receiving section side, thus deteriorating the image quality characteristics, as conventionally occurred. Further, since there is no need to form multi-layered films by using a material with a high refractive index and a material with a low refractive index in order to obtain an effect of an optical waveguide, the conventional problem of leakage current and crack occurring due to stress thereby deteriorating image quality characteristics can be prevented. Further, according to the present invention, there is no need for a step exclusive for forming an optical waveguide, and an optical waveguide region is formed using a conventional processing step only with a design change for a resist film therefore significantly reducing a cost for processing semiconductors thus reducing a price for a solid-state image capturing device.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A solid-state image capturing device, in which, on a semiconductor substrate having a plurality of light receiving sections in two dimensions at a surface portion thereof, a plurality of conductive films is formed via respective insulation films on a region other than a region right above the light receiving section and an optical waveguide is formed above a light receiving section,
wherein a plural-layered optical waveguide tube is formed as the optical waveguide, with the same material as at least one of the plural-layered conductive films.

2. A solid-state image capturing device, in which, on a semiconductor substrate having a plurality of light receiving sections in two dimensions at a surface portion thereof, a plurality of conductive films is formed via respective insulation films on a region other than a region right above the light receiving section and an optical waveguide is formed above a light receiving section,
wherein a single-layered or plural-layered optical waveguide tube is formed as the optical waveguide, with the same material as that of either a conductive film or a contact plug among the conductive films of the plural-layered conductive films and the contact plugs electrically connecting between the semiconductor substrate and the conductive films and/or between the conductive films.

3. A solid-state image capturing device according to claim 1, wherein at least one of between the semiconductor substrate and the conductive layers, and between the plural-layered conductive films is electrically connected by a contact plug made from a conductive material, and at least one of the plural-layered optical waveguide tube portions is formed using the same material as the contact plug.

4. A solid-state image capturing device according to claim 1, wherein a gate electrode film is formed adjacent to the light receiving section, at least one of between the semiconductor substrate and the conductive films, between the gate electrode film and the conductive films and between the plural-layered conductive films is electrically connected by a contact plug made from a conductive material,
wherein at least one of the plural-layered optical waveguide tube portions is formed using the same material as the contact plug.

5. A solid-state image capturing device according to claim 3, wherein the plural-layered optical waveguide tube is configured by sequentially laminating the optical waveguide tube portions formed at the same time with each of the plural-layered conductive films and the contact plugs.

6. A solid-state image capturing device according to claim 4, wherein the plural-layered optical waveguide tube is configured by sequentially laminating the optical waveguide tube portions formed at the same time with each of the plural-layered conductive films and the contact plugs.

7. A solid-state image capturing device according to claim 3, wherein the plural-layered optical waveguide tube is configured by sequentially laminating the optical waveguide tube portions formed at the same time with each of the sequentially laminated conductive films and the contact plugs.

8. A solid-state image capturing device according to claim 4, wherein the plural-layered optical waveguide tube is configured by sequentially laminating the optical waveguide tube portions formed at the same time with each of the sequentially laminated conductive films and the contact plugs.

9. A solid-state image capturing device according to claim 1, wherein a conductive film is at least a wiring film of the wiring films and a shading film.

10. A solid-state image capturing device according to claim 2, wherein a conductive film is at least a wiring film of the wiring films and a shading film.

11. A solid-state image capturing device according to claim 1, wherein the conductive film is a metal film.

12. A solid-state image capturing device according to claim 2, wherein the conductive film is a metal film.

13. A solid-state image capturing device according to claim 1, wherein the conductive film is made from at least one of copper, silver, aluminum and tungsten, or the alloy thereof.

14. A solid-state image capturing device according to claim 2, wherein the conductive film is made from at least one of copper, silver, aluminum and tungsten, or the alloy thereof.

15. A solid-state image capturing device according to claim 3, wherein the contact plug is made from the same material as the conductive film or the contact plug is made from a metal material different from the conductive film.

16. A solid-state image capturing device according to claim 4, wherein the contact plug is made from the same material as the conductive film or the contact plug is made from a metal material different from the conductive film.

17. A solid-state image capturing device according to claim 2, wherein the contact plug is made from the same material as the conductive film or the contact plug is made from a metal material different from the conductive film.

18. A solid-state image capturing device according to claim 1, wherein inner circumference surfaces of the plural-layered optical waveguide tube portions of the optical waveguide tube are at least aligned.

19. A solid-state image capturing device according to claim 1, wherein outer circumference surfaces of the plural-layered optical waveguide tube portions of the optical waveguide tube are not aligned.

20. A solid-state image capturing device according to claim 18, wherein each of the optical waveguide tube portions is adjusted to a size of the conductive film and the contact plug in the same layer.

21. A solid-state image capturing device according to claim 19, wherein each of the optical waveguide tube portions is adjusted to a size of the conductive film and the contact plug in the same layer.

22. A solid-state image capturing device according to claim 18, wherein an inner circumference of the optical waveguide tube is circular or elliptical and an external circumference of the optical waveguide tube is circular, elliptical, squared, or rectangular in the plain view.

23. A solid-state image capturing device according to claim 19, wherein an inner circumference of the optical waveguide tube is circular or elliptical and an external circumference of the optical waveguide tube is circular, elliptical, squared, or rectangular in the plain view.

24. A solid-state image capturing device according to claim 1, wherein the inner circumferential surface of the optical waveguide tube becomes wider as it get closer to an opening of the optical waveguide tube.

25. A solid-state image capturing device according to claim 1, wherein a taper is formed at an opening of the optical waveguide tube.

26. A solid-state image capturing device according to claim 24, wherein a taper is formed at an opening of the optical waveguide tube.

27. A solid-state image capturing device according to claim 1, wherein the optical waveguide tube is used as a part of one of a power supply line, a control line, a clock line and a signal line that are provided together with a signal reading circuit.

28. A solid-state image capturing device according to claim 2, wherein the optical waveguide tube is used as a part of one of a power supply line, a control line, a clock line and a signal line that are provided together with a signal reading circuit.

29. A solid-state image capturing device according to claim 1, wherein the plural-layered optical waveguide portions of the optical waveguide tube are used, besides as wirings of a signal reading circuit, as a part of one of a power supply line, control line, a clock line and a signal line provided in the signal reading circuit.

30. A solid-state image capturing device according to claim 2, wherein the plural-layered optical waveguide portions of the optical waveguide tube are used, besides as wirings of a signal reading circuit, as a part of one of a power supply line, control line, a clock line and a signal line provided in the signal reading circuit.

31. A solid-state image capturing device according to claim 1, wherein one layer or a plurality of layers of the optical waveguide tube portions are insulated from another adjacent optical waveguide tube portion by an insulation film that is as thin enough to insulate as possible for every wiring, power supply line, control line, clock line and signal line provided together with the signal reading circuit, the wirings of the signal reading circuit being also used for the optical waveguide tube portions.

32. A solid-state image capturing device according to claim 1, wherein the insulation film is an interlayer insulation film formed between a conductive film and another conductive film different from the conductive film.

33. A solid-state image capturing device according to claim 2, wherein the insulation film is an interlayer insulation film formed between a conductive film and another conductive film different from the conductive film.

34. A solid-state image capturing device according to claim 1, wherein a color filter is provided on the upper most layer of the insulation film, so that respective color corresponds to each of the light receiving sections, and a planarization film is formed on the color filter before forming a microlens, and a microlens is formed on the planarization film to correspond to each of the light receiving sections.

35. A solid-state image capturing device according to claim 2, wherein a color filter is provided on the upper most layer of the insulation film, so that respective color corresponds to each of the light receiving sections, and a planarization film is formed on the color filter before forming a microlens, and a microlens is formed on the planarization film to correspond to each of the light receiving sections.

36. A solid-state image capturing device manufacturing method for, on a semiconductor substrate having a plurality of light receiving sections in two dimensions at a surface portion thereof, forming a plural-layered conductive films via respective insulation films on a region other than a region right above the light receiving section, and forming an optical waveguide above a light receiving section, the method comprising:
a conductive film/optical waveguide tube portion forming step of forming an optical waveguide tube portion that configures a part of the optical waveguide using the same material as a single-layered conductive film or the plural-layered conductive films at the same time when at least one of the single-layered conductive film or the plural-layered conductive films is processed.

37. A solid-state image capturing device manufacturing method according to claim 36, wherein at least one of between the semiconductor substrate and the conductive films, and between plural-layers of the conductive films is electrically connected by a contact plug made from a conductive material, the method further comprising:
a contact plug/optical waveguide tube portion forming step of forming an optical waveguide tube portion with the same material as the contact plug at the same time when the contact plug is processed and formed.

38. A solid-state image capturing device manufacturing method according to claim 36, wherein gate electrode films are formed adjacent to the light receiving section, and at least one of between the semiconductor substrate and the conductive films, between the gate electrode films and conductive films, and between a plural-layers of the conductive films is electrically connected by a contact plug made from a conductive material, the method further comprising:
a contact plug/optical waveguide tube portion forming step of forming an optical waveguide tube portion with the same material as the contact plug at the same time when processing and forming the contact plug.

39. A solid-state image capturing device manufacturing method according to claim 37, comprising:
a first insulation film forming step of forming a first insulation film on the semiconductor substrate having the plurality of light receiving sections formed in a surface portion thereof in two dimensions;
a first contact plug/first optical waveguide tube portion forming step of forming a first contact plug and a first optical waveguide tube portion simultaneously in the first insulation film; and
a first wiring film/second optical waveguide tube portion forming step of forming a first wiring film and a second optical waveguide tube portion on the first insulation film having the first contact plug and the first optical waveguide tube portion formed therein.

40. A solid-state image capturing device manufacturing method according to claim 38, comprising:
a first insulation film forming step of forming a first insulation film on the semiconductor substrate having the plurality of light receiving sections formed in a surface portion thereof in two dimensions;
a first contact plug/first optical waveguide tube portion forming step of forming a first contact plug and a first optical waveguide tube portion simultaneously in the first insulation film; and
a first wiring film/second optical waveguide tube portion forming step of forming a first wiring film and a second optical waveguide tube portion on the first insulation film having the first contact plug and the first optical waveguide tube portion formed therein.

41. A solid-state image capturing device manufacturing method according to claim 37, comprising:
a first insulation film forming step of forming a first insulation film on the semiconductor substrate having the plurality of light receiving sections formed in two dimensions in a surface portion thereof;
a first contact plug forming step of forming a first contact plug in the first insulation film; and
a first wiring film/second optical waveguide tube portion forming step of simultaneously forming a first wiring film and a second optical waveguide tube portion on the first insulation film having the first contact plug formed therein.

42. A solid-state image capturing device manufacturing method according to claim 38, comprising:
a first insulation film forming step of forming a first insulation film on the semiconductor substrate having the plurality of light receiving sections formed in two dimensions in a surface portion thereof;
a first contact plug forming step of forming a first contact plug in the first insulation film; and
a first wiring film/second optical waveguide tube portion forming step of simultaneously forming a first wiring film and a second optical waveguide tube portion on the first insulation film having the first contact plug formed therein.

43. A solid-state image capturing device manufacturing method according to claim 39, wherein the first contact plug/first optical waveguide tube portion forming step includes:
a first resist film forming step of patterning a first resist film in the first insulation film to have shapes corresponding to the first contact plug and the first optical waveguide tube portion;
a first recess shape forming step of processing first recess shapes corresponding to the first contact plug and the first optical waveguide tube portion in the first insulation film using the first resist film as a mask;
a first metal film coating step of coating a first metal film on the first insulation film having the first recess shape formed therein; and
a step of removing the first metal film on the entire first insulation film such that the first metal film remains in the first recess so as to form the first contact plug and the first optical waveguide tube portion in the first recess.

44. A solid-state image capturing device manufacturing method according to claim 40, wherein the first contact plug/first optical waveguide tube portion forming step includes:
a first resist film forming step of patterning a first resist film in the first insulation film to have shapes corresponding to the first contact plug and the first optical waveguide tube portion;
a first recess shape forming step of processing first recess shapes corresponding to the first contact plug and the first optical waveguide tube portion in the first insulation film using the first resist film as a mask;
a first metal film coating step of coating a first metal film on the first insulation film having the first recess shape formed therein; and
a step of removing the first metal film on the entire first insulation film such that the first metal film remains in the first recess so as to form the first contact plug and the first optical waveguide tube portion in the first recess.

45. A solid-state image capturing device manufacturing method according to claim 41, wherein the first contact plug forming step includes:
a first resist film forming step of patterning a first resist film on the first insulation film to have a shape corresponding to the first contact plug;
a first recess shape forming step of processing a first recess shape corresponding to the first contact plug in the first insulation film using the first resist film as a mask;
a first metal film coating step of coating a first metal film in the first insulation film having the first recess shape formed therein; and
a step of removing the first metal film on the entire first insulation film such that the first metal film remains in the first recess so as to form the first contact plug in the first recess.

46. A solid-state image capturing device manufacturing method according to claim 42, wherein the first contact plug forming step includes:
a first resist film forming step of patterning a first resist film on the first insulation film to have a shape corresponding to the first contact plug;
a first recess shape forming step of processing a first recess shape corresponding to the first contact plug in the first insulation film using the first resist film as a mask;
a first metal film coating step of coating a first metal film in the first insulation film having the first recess shape formed therein; and
a step of removing the first metal film on the entire first insulation film such that the first metal film remains in the first recess so as to form the first contact plug in the first recess.

47. A solid-state image capturing device manufacturing method according to claim 39, wherein the first wiring film/second optical waveguide tube portion forming step includes:
a second metal film coating step of coating a second metal film on the first insulation film having the first contact plug and the first optical waveguide tube portion formed therein;
a second resist film forming step of patterning a second resist film on the second metal film to have shapes corresponding to the first wiring and the second optical waveguide tube portion; and
a step of forming the first wiring and the second optical waveguide tube portion from the second metal film using the second resist film as a mask.

48. A solid-state image capturing device manufacturing method according to claim 41, wherein the first wiring film/second optical waveguide tube portion forming step includes:
a second metal film coating step of coating a second metal film on the first insulation film having the first contact plug and the first optical waveguide tube portion formed therein;
a second resist film forming step of patterning a second resist film on the second metal film to have shapes corresponding to the first wiring and the second optical waveguide tube portion; and
a step of forming the first wiring and the second optical waveguide tube portion from the second metal film using the second resist film as a mask.

49. A solid-state image capturing device manufacturing method according to claim 40, wherein the first wiring film/second optical waveguide tube portion forming step includes:
a second metal film coating step of coating a second metal film on the first insulation film having the first contact plug and the first optical waveguide tube portion formed therein;
a second resist film forming step of patterning a second resist film on the second metal film to have shapes corresponding to the first wiring and the second optical waveguide tube portion; and
a step of forming the first wiring and the second optical waveguide tube portion from the second metal film using the second resist film as a mask.

50. A solid-state image capturing device manufacturing method according to claim 42, wherein the first wiring film/second optical waveguide tube portion forming step includes:
a second metal film coating step of coating a second metal film on the first insulation film having the first contact plug and the first optical waveguide tube portion formed therein;
a second resist film forming step of patterning a second resist film on the second metal film to have shapes corresponding to the first wiring and the second optical waveguide tube portion; and
a step of forming the first wiring and the second optical waveguide tube portion from the second metal film using the second resist film as a mask.

51. A solid-state image capturing device manufacturing method according to claim 43, wherein the first recess shapes are a recess shape for the first contact plug and a recess shape for the first optical waveguide tube portion.

52. A solid-state image capturing device manufacturing method according to claim 44, wherein the first recess shapes are a recess shape for the first contact plug and a recess shape for the first optical waveguide tube portion.

53. A solid-state image capturing device manufacturing method according to claim 45, wherein the first recess shapes are a recess shape for the first contact plug and a recess shape for the first optical waveguide tube portion.

54. A solid-state image capturing device manufacturing method according to claim 46, wherein the first recess shapes are a recess shape for the first contact plug and a recess shape for the first optical waveguide tube portion.

55. A solid-state image capturing device manufacturing method according to claim 39, comprising:
a second insulation film forming step of forming a second insulation film on the substrate having the first wiring and the second optical waveguide tube portion formed thereon;
a second contact plug/third optical waveguide tube portion forming step of forming a second contact plug and a third optical waveguide tube portion simultaneously in the second insulation film; and
a second wiring/fourth optical waveguide tube portion forming step of forming a second wiring and a fourth optical waveguide tube portion simultaneously on the second insulation film having the second contact plug and the third optical waveguide tube portion formed therein.

56. A solid-state image capturing device manufacturing method according to claim 40, comprising:
a second insulation film forming step of forming a second insulation film on the substrate having the first wiring and the second optical waveguide tube portion formed thereon;
a second contact plug/third optical waveguide tube portion forming step of forming a second contact plug and a third optical waveguide tube portion simultaneously in the second insulation film; and
a second wiring/fourth optical waveguide tube portion forming step of forming a second wiring and a fourth optical waveguide tube portion simultaneously on the second insulation film having the second contact plug and the third optical waveguide tube portion formed therein.

57. A solid-state image capturing device manufacturing method according to claim 41, comprising:
a second insulation film forming step of forming a second insulation film on the substrate having the first wiring and the second optical waveguide tube portion formed thereon;
a second contact plug/third optical waveguide tube portion forming step of forming a second contact plug and a third optical waveguide tube portion simultaneously in the second insulation film; and
a second wiring/fourth optical waveguide tube portion forming step of forming a second wiring and a fourth optical waveguide tube portion simultaneously on the second insulation film having the second contact plug and the third optical waveguide tube portion formed therein.

58. A solid-state image capturing device manufacturing method according to claim 42, comprising:
a second insulation film forming step of forming a second insulation film on the substrate having the first wiring and the second optical waveguide tube portion formed thereon;
a second contact plug/third optical waveguide tube portion forming step of forming a second contact plug and a third optical waveguide tube portion simultaneously in the second insulation film; and
a second wiring/fourth optical waveguide tube portion forming step of forming a second wiring and a fourth optical waveguide tube portion simultaneously on the second insulation film having the second contact plug and the third optical waveguide tube portion formed therein.

59. A solid-state image capturing device manufacturing method according to claim 55, wherein the second contact plug/third optical waveguide tube portion forming step includes:
a third resist film forming step of patterning a third resist film on the second insulation film to have shapes corresponding to the second contact plug and the third optical waveguide tube portion;
a second recess shape forming step of processing second recess shapes corresponding to the second contact plug and the third optical waveguide tube portion in the second insulation film using the third resist film as a mask;
a third metal film coating step of coating a third metal film in the second insulation film having the second recess shape formed therein; and
a step of removing the third metal film on the entire second insulation film such that the third metal film remains in the second recesses so as to form the second contact plug and the third optical waveguide tube portion in the respective second recesses.

60. A solid-state image capturing device manufacturing method according to claim 56, wherein the second contact plug/third optical waveguide tube portion forming step includes:
a third resist film forming step of patterning a third resist film on the second insulation film to have shapes corresponding to the second contact plug and the third optical waveguide tube portion;
a second recess shape forming step of processing second recess shapes corresponding to the second contact plug and the third optical waveguide tube portion in the second insulation film using the third resist film as a mask,
a third metal film coating step of coating a third metal film in the second insulation film having the second recess shape formed therein; and
a step of removing the third metal film on the entire second insulation film such that the third metal film remains in the second recesses so as to form the second contact plug and the third optical waveguide tube portion in the respective second recesses.

61. A solid-state image capturing device manufacturing method according to claim 57, wherein the second contact plug/third optical waveguide tube portion forming step includes:
a third resist film forming step of patterning a third resist film on the second insulation film to have shapes corresponding to the second contact plug and the third optical waveguide tube portion;
a second recess shape forming step of processing second recess shapes corresponding to the second contact plug and the third optical waveguide tube portion in the second insulation film using the third resist film as a mask;
a third metal film coating step of coating a third metal film in the second insulation film having the second recess shape formed therein; and
a step of removing the third metal film on the entire second insulation film such that the third metal film remains in the second recesses so as to form the second contact plug and the third optical waveguide tube portion in the respective second recesses.

62. A solid-state image capturing device manufacturing method according to claim 58, wherein the second contact plug/third optical waveguide tube portion forming step includes:
a third resist film forming step of patterning a third resist film on the second insulation film to have shapes corresponding to the second contact plug and the third optical waveguide tube portion;
a second recess shape forming step of processing second recess shapes corresponding to the second contact plug and the third optical waveguide tube portion in the second insulation film using the third resist film as a mask;
a third metal film coating step of coating a third metal film in the second insulation film having the second recess shape formed therein; and
a step of removing the third metal film on the entire second insulation film such that the third metal film remains in the second recesses so as to form the second contact plug and the third optical waveguide tube portion in the respective second recesses.

63. A solid-state image capturing device manufacturing method according to claim 55, wherein the second wiring/fourth optical waveguide tube portion forming step includes:
a fourth metal film coating step of coating a fourth metal film on the substrate having the second contact plug and the third optical waveguide tube portion formed therein;
a fourth resist film forming step of patterning a fourth resist film on the fourth metal film to have shapes corresponding to the second wiring and the fourth optical waveguide tube portion;
a step of forming the second wiring and the fourth optical waveguide tube portion from the fourth metal film using the fourth resist film as a mask.

64. A solid-state image capturing device manufacturing method according to claim 56, wherein the second wiring/fourth optical waveguide tube portion forming step includes:
a fourth metal film coating step of coating a fourth metal film on the substrate having the second contact plug and the third optical waveguide tube portion formed therein;
a fourth resist film forming step of patterning a fourth resist film on the fourth metal film to have shapes corresponding to the second wiring and the fourth optical waveguide tube portion;
a step of forming the second wiring and the fourth optical waveguide tube portion from the fourth metal film using the fourth resist film as a mask.

65. A solid-state image capturing device manufacturing method according to claim 57, wherein the second wiring/fourth optical waveguide tube portion forming step includes:
a fourth metal film coating step of coating a fourth metal film on the substrate having the second contact plug and the third optical waveguide tube portion formed therein;
a fourth resist film forming step of patterning a fourth resist film on the fourth metal film to have shapes corresponding to the second wiring and the fourth optical waveguide tube portion;
a step of forming the second wiring and the fourth optical waveguide tube portion from the fourth metal film using the fourth resist film as a mask.

66. A solid-state image capturing device manufacturing method according to claim 58, wherein the second wiring/fourth optical waveguide tube portion forming step includes:
a fourth metal film coating step of coating a fourth metal film on the substrate having the second contact plug and the third optical waveguide tube portion formed therein;
a fourth resist film forming step of patterning a fourth resist film on the fourth metal film to have shapes corresponding to the second wiring and the fourth optical waveguide tube portion;
a step of forming the second wiring and the fourth optical waveguide tube portion from the fourth metal film using the fourth resist film as a mask.

67. A solid-state image capturing device manufacturing method according to claim 59, wherein the second recess shapes are a recess shape for the second contact plug and a recess shape for the third optical waveguide tube portion.

68. A solid-state image capturing device manufacturing method according to claim 60, wherein the second recess shapes are a recess shape for the second contact plug and a recess shape for the third optical waveguide tube portion.

69. A solid-state image capturing device manufacturing method according to claim 61, wherein the second recess shapes are a recess shape for the second contact plug and a recess shape for the third optical waveguide tube portion.

70. A solid-state image capturing device manufacturing method according to claim 62, wherein the second recess shapes are a recess shape for the second contact plug and a recess shape for the third optical waveguide tube portion.

71. A solid-state image capturing device manufacturing method according to claim 55, comprising:
a third insulation film forming step of forming a third insulation film on the substrate having the second wiring and the fourth optical waveguide tube portion formed thereon;
a third contact plug/fifth optical waveguide tube portion forming step of forming a third contact plug and a fifth optical waveguide tube portion simultaneously in the third insulation film; and
a third wiring/sixth optical waveguide tube forming step of forming a third insulation film and a sixth optical waveguide tube portion on the third insulation film having the third contact plug and the fifth optical waveguide tube portion formed therein.

72. A solid-state image capturing device manufacturing method according to claim 56, comprising:
a third insulation film forming step of forming a third insulation film on the substrate having the second wiring and the fourth optical waveguide tube portion formed thereon;
a third contact plug/fifth optical waveguide tube portion forming step of forming a third contact plug and a fifth optical waveguide tube portion simultaneously in the third insulation film; and
a third wiring/sixth optical waveguide tube forming step of forming a third insulation film and a sixth optical waveguide tube portion on the third insulation film having the third contact plug and the fifth optical waveguide tube portion formed therein.

73. A solid-state image capturing device manufacturing method according to claim 57, comprising:
a third insulation film forming step of forming a third insulation film on the substrate having the second wiring and the fourth optical waveguide tube portion formed thereon;
a third contact plug/fifth optical waveguide tube portion forming step of forming a third contact plug and a fifth optical waveguide tube portion simultaneously in the third insulation film; and
a third wiring/sixth optical waveguide tube forming step of forming a third insulation film and a sixth optical waveguide tube portion on the third insulation film having the third contact plug and the fifth optical waveguide tube portion formed therein.

74. A solid-state image capturing device manufacturing method according to claim 58, comprising:
a third insulation film forming step of forming a third insulation film on the substrate having the second wiring and the fourth optical waveguide tube portion formed thereon;
a third contact plug/fifth optical waveguide tube portion forming step of forming a third contact plug and a fifth optical waveguide tube portion simultaneously in the third insulation film; and
a third wiring/sixth optical waveguide tube forming step of forming a third insulation film and a sixth optical waveguide tube portion on the third insulation film having the third contact plug and the fifth optical waveguide tube portion formed therein.

75. A solid-state image capturing device manufacturing method according to claim 71, wherein the third contact plug/fifth optical waveguide tube portion forming step includes:
a fifth resist film forming step of patterning a fifth resist film on the third insulation film to have shapes corresponding to the third contact plug and the fifth optical waveguide tube portion;
a third recess shape forming step of processing third recess shapes corresponding to the third contact plug and the fifth optical waveguide tube portion in the third insulation film using the fifth resist film as a mask;
a fifth metal film coating step of coating a fifth metal film on the substrate having the third recess shape formed thereon; and
a step of removing the fifth metal film on the entire third insulation film such that the fifth metal film remains in third recesses so as to form the third contact plug and the fifth optical waveguide tube portion in the respective third recesses.

76. A solid-state image capturing device manufacturing method according to claim 72, wherein the third contact plug/fifth optical waveguide tube portion forming step includes:
a fifth resist film forming step of patterning a fifth resist film on the third insulation film to have shapes corresponding to the third contact plug and the fifth optical waveguide tube portion;
a third recess shape forming step of processing third recess shapes corresponding to the third contact plug and the fifth optical waveguide tube portion in the third insulation film using the fifth resist film as a mask;
a fifth metal film coating step of coating a fifth metal film on the substrate having the third recess shape formed thereon; and
a step of removing the fifth metal film on the entire third insulation film such that the fifth metal film remains in third recesses so as to form the third contact plug and the fifth optical waveguide tube portion in the respective third recesses.

77. A solid-state image capturing device manufacturing method according to claim 73, wherein the third contact plug/fifth optical waveguide tube portion forming step includes:
a fifth resist film forming step of patterning a fifth resist film on the third insulation film to have shapes corresponding to the third contact plug and the fifth optical waveguide tube portion;
a third recess shape forming step of processing third recess shapes corresponding to the third contact plug and the fifth optical waveguide tube portion in the third insulation film using the fifth resist film as a mask;
a fifth metal film coating step of coating a fifth metal film on the substrate having the third recess shape formed thereon; and
a step of removing the fifth metal film on the entire third insulation film such that the fifth metal film remains in third recesses so as to form the third contact plug and the fifth optical waveguide tube portion in the respective third recesses.

78. A solid-state image capturing device manufacturing method according to claim 74, wherein the third contact plug/fifth optical waveguide tube portion forming step includes:
a fifth resist film forming step of patterning a fifth resist film on the third insulation film to have shapes corresponding to the third contact plug and the fifth optical waveguide tube portion;
a third recess shape forming step of processing third recess shapes corresponding to the third contact plug and the fifth optical waveguide tube portion in the third insulation film using the fifth resist film as a mask;
a fifth metal film coating step of coating a fifth metal film on the substrate having the third recess shape formed thereon; and
a step of removing the fifth metal film on the entire third insulation film such that the fifth metal film remains in third recesses so as to form the third contact plug and the fifth optical waveguide tube portion in the respective third recesses.

79. A solid-state image capturing device manufacturing method according to claim 71, wherein the third wiring/sixth optical waveguide tube portion forming step includes:
a sixth metal film coating step of coating a sixth metal film on the substrate having the third contact plug and the fifth optical waveguide tube portion formed therein; a sixth resist film forming step of patterning a sixth resist film in the sixth metal film to have shapes corresponding to the third wiring and the sixth optical waveguide tube portion; and
a step of forming the third wiring and the sixth optical waveguide tube portion from the sixth metal film using the sixth resist film as a mask.

80. A solid-state image capturing device manufacturing method according to claim 72, wherein the third wiring/sixth optical waveguide tube portion forming step includes:
a sixth metal film coating step of coating a sixth metal film on the substrate having the third contact plug and the fifth optical waveguide tube portion formed therein; a sixth resist film forming step of patterning a sixth resist film in the sixth metal film to have shapes corresponding to the third wiring and the sixth optical waveguide tube portion; and
a step of forming the third wiring and the sixth optical waveguide tube portion from the sixth metal film using the sixth resist film as a mask.

81. A solid-state image capturing device manufacturing method according to claim 73, wherein the third wiring/sixth optical waveguide tube portion forming step includes:
a sixth metal film coating step of coating a sixth metal film on the substrate having the third contact plug and the fifth optical waveguide tube portion formed therein; a sixth resist film forming step of patterning a sixth resist film in the sixth metal film to have shapes corresponding to the third wiring and the sixth optical waveguide tube portion; and
a step of forming the third wiring and the sixth optical waveguide tube portion from the sixth metal film using the sixth resist film as a mask.

82. A solid-state image capturing device manufacturing method according to claim 74, wherein the third wiring/sixth optical waveguide tube portion forming step includes:
a sixth metal film coating step of coating a sixth metal film on the substrate having the third contact plug and the fifth optical waveguide tube portion formed therein; a sixth resist film forming step of patterning a sixth resist film in the sixth metal film to have shapes corresponding to the third wiring and the sixth optical waveguide tube portion; and
a step of forming the third wiring and the sixth optical waveguide tube portion from the sixth metal film using the sixth resist film as a mask.

83. A solid-state image capturing device manufacturing method according to claim 75, wherein the third recess shape is a recess shape for the third contact plug and a recess shape for the fifth optical waveguide tube portion.

84. A solid-state image capturing device manufacturing method according to claim 76, wherein the third recess shape is a recess shape for the third contact plug and a recess shape for the fifth optical waveguide tube portion.

85. A solid-state image capturing device manufacturing method according to claim 77, wherein the third recess shape is a recess shape for the third contact plug and a recess shape for the fifth optical waveguide tube portion.

86. A solid-state image capturing device manufacturing method according to claim 78, wherein the third recess shape is a recess shape for the third contact plug and a recess shape for the fifth optical waveguide tube portion.

87. A solid-state image capturing device manufacturing method according to claim 39, comprising:
an Nth (N is an integer greater than or equal to 2) insulation film forming step of forming an Nth insulation film on the substrate having the first wiring and the second optical waveguide tube portion formed thereon;
an Nth contact plug/(2N−1)th optical waveguide tube portion forming step of simultaneously forming an Nth contact plug and a (2N−1)th optical waveguide tube portion in the Nth insulation film; and
an Nth wiring/2Nth optical waveguide tube portion forming step of simultaneously forming an Nth wiring and a 2Nth optical waveguide tube portion on the substrate having the Nth contact plug and the (2N−1)th optical waveguide tube portion formed therein.

88. A solid-state image capturing device manufacturing method according to claim 40, comprising:
an Nth (N is an integer greater than or equal to 2) insulation film forming step of forming an Nth insulation film on the substrate having the first wiring and the second optical waveguide tube portion formed thereon;
an Nth contact plug/(2N−1)th optical waveguide tube portion forming step of simultaneously forming an Nth contact plug and a (2N−1)th optical waveguide tube portion in the Nth insulation film; and
an Nth wiring/2Nth optical waveguide tube portion forming step of simultaneously forming an Nth wiring and a 2Nth optical waveguide tube portion on the substrate having the Nth contact plug and the (2N−1)th optical waveguide tube portion formed therein.

89. A solid-state image capturing device manufacturing method according to claim 41, comprising:
an Nth (N is an integer greater than or equal to 2) insulation film forming step of forming an Nth insulation film on the substrate having the first wiring and the second optical waveguide tube portion formed thereon;
an Nth contact plug/(2N−1)th optical waveguide tube portion forming step of simultaneously forming an Nth contact plug and a (2N−1)th optical waveguide tube portion in the Nth insulation film; and
an Nth wiring/2Nth optical waveguide tube portion forming step of simultaneously forming an Nth wiring and a 2Nth optical waveguide tube portion on the substrate having the Nth contact plug and the (2N−1)th optical waveguide tube portion formed therein.

90. A solid-state image capturing device manufacturing method according to claim 38, comprising:
an Nth (N is an integer greater than or equal to 2) insulation film forming step of forming an Nth insulation film on the substrate having the first wiring and the second optical waveguide tube portion formed thereon;
an Nth contact plug/(2N−1)th optical waveguide tube portion forming step of simultaneously forming an Nth contact plug and a (2N−1)th optical waveguide tube portion in the Nth insulation film; and
an Nth-wiring/2Nth optical waveguide tube portion forming step of simultaneously forming an Nth wiring and a 2Nth optical waveguide tube portion on the substrate having the Nth contact plug and the (2N−1)th optical waveguide tube portion formed therein.

91. A solid-state image capturing device manufacturing method according to claim 87, wherein the Nth contact plug/(2N−1) optical waveguide tube portion forming step includes:
a (2N−1)th resist film forming step of patterning a (2N−1)th resist film on the N insulation film to have shapes corresponding to an Nth contact plug and a (2N−1)th optical waveguide tube portion;
an Nth recess shape forming step of processing Nth recess shapes corresponding to the Nth contact plug and the (2N−1)th optical waveguide tube portion in the Nth insulation film using the (2N−1)th resist film as a mask;
a (2N−1)th metal film coating step of coating a (2N−1)th metal film on the substrate having the Nth recess shape formed therein;
a step of removing the (2N−1)th metal film on the entire Nth insulation film such that the (2N−1)th metal film remains in the Nth recesses so as to form the Nth contact plug and the (2N−1)th optical waveguide tube portion in the respective Nth recesses.

92. A solid-state image capturing device manufacturing method according to claim 88, wherein the Nth contact plug/(2N−1) optical waveguide tube portion forming step includes:
a (2N−1)th resist film forming step of patterning a (2N−1)th resist film on the N insulation film to have shapes corresponding to an Nth contact plug and a (2N−1)th optical waveguide tube portion;
an Nth recess shape forming step of processing Nth recess shapes corresponding to the Nth contact plug and the (2N−1)th optical waveguide tube portion in the Nth insulation film using the (2N−1)th resist film as a mask;
a (2N−1)th metal film coating step of coating a (2N−1) th metal film on the substrate having the Nth recess shape formed therein;
a step of removing the (2N−1)th metal film on the entire Nth insulation film such that the (2N−1)th metal film remains in the Nth recesses so as to form the Nth contact plug and the (2N−1)th optical waveguide tube portion in the respective Nth recesses.

93. A solid-state image capturing device manufacturing method according to claim 89, wherein the Nth contact plug/(2N−1) optical waveguide tube portion forming step includes:
a (2N−1)th resist film forming step of patterning a (2N−1)th resist film on the N insulation film to have shapes corresponding to an Nth contact plug and a (2N−1)th optical waveguide tube portion;
an Nth recess shape forming step of processing Nth recess shapes corresponding to the Nth contact plug and the (2N−1)th optical waveguide tube portion in the Nth insulation film using the (2N−1)th resist film as a mask;
a (2N−1)th metal film coating step of coating a (2N−1)th metal film on the substrate having the Nth recess shape formed therein;
a step of removing the (2N−1)th metal film on the entire Nth insulation film such that the (2N−1)th metal film remains in the Nth recesses so as to form the Nth contact plug and the (2N−1)th optical waveguide tube portion in the respective Nth recesses.

94. A solid-state image capturing device manufacturing method according to claim 90, wherein the Nth contact plug/(2N−1) optical waveguide tube portion forming step includes:
a (2N−1)th resist film forming step of patterning a (2N−1)th resist film on the N insulation film to have shapes corresponding to an Nth contact plug and a (2N−1) th optical waveguide tube portion;
an Nth recess shape forming step of processing Nth recess shapes corresponding to the Nth contact plug and the (2N−1)th optical waveguide tube portion in the Nth insulation film using the (2N−1)th resist film as a mask;
a (2N−1)th metal film coating step of coating a (2N−1) th metal film on the substrate having the Nth recess shape formed therein;
a step of removing the (2N−1)th metal film on the entire Nth insulation film such that the (2N−1)th metal film remains in the Nth recesses so as to form the Nth contact plug and the (2N−1)th optical waveguide tube portion in the respective Nth recesses.

95. A solid-state image capturing device manufacturing method according to claim 87, the Nth wiring/2Nth optical waveguide tube portion forming step includes:
a 2Nth metal film coating step of coating a 2Nth metal film on the substrate having the Nth contact plug and the (2N−1)th optical waveguide tube portion formed therein;
a 2Nth resist film forming step of patterning a 2Nth resist film on the 2Nth metal film to have shapes corresponding to the Nth wiring and the 2Nth optical waveguide tube portion;
a step of forming the Nth wiring and the 2Nth optical waveguide tube portion from the 2N metal film using the 2Nth resist film as a mask.

96. A solid-state image capturing device manufacturing method according to claim 88, the Nth wiring/2Nth optical waveguide tube portion forming step includes:
a 2Nth metal film coating step of coating a 2Nth metal film on the substrate having the Nth contact plug and the (2N−1)th optical waveguide tube portion formed therein;
a 2Nth resist film forming step of patterning a 2Nth resist film on the 2Nth metal film to have shapes corresponding to the Nth wiring and the 2Nth optical waveguide tube portion;
a step of forming the Nth wiring and the 2Nth optical waveguide tube portion from the 2N metal film using the 2Nth resist film as a mask.

97. A solid-state image capturing device manufacturing method according to claim 89, the Nth wiring/2Nth optical waveguide tube portion forming step includes:
a 2Nth metal film coating step of coating a 2Nth metal film on the substrate having the Nth contact plug and the (2N−1)th optical waveguide tube portion formed therein;
a 2Nth resist film forming step of patterning a 2Nth resist film on the 2Nth metal film to have shapes corresponding to the Nth wiring and the 2Nth optical waveguide tube portion;
a step of forming the Nth wiring and the 2Nth optical waveguide tube portion from the 2N metal film using the 2Nth resist film as a mask.

98. A solid-state image capturing device manufacturing method according to claim 90, the Nth wiring/2Nth optical waveguide tube portion forming step includes:
a 2Nth metal film coating step of coating a 2Nth metal film on the substrate having the Nth contact plug and the (2N−1)th optical waveguide tube portion formed therein;
a 2Nth resist film forming step of patterning a 2Nth resist film on the 2Nth metal film to have shapes corresponding to the Nth wiring and the 2Nth optical waveguide tube portion;
a step of forming the Nth wiring and the 2Nth optical waveguide tube portion from the 2N metal film using the 2Nth resist film as a mask.

99. A solid-state image capturing device manufacturing method according to claim 37, comprising:
a first insulation film forming step of forming a first insulation film on the semiconductor substrate having a plurality of light receiving sections formed in a surface portion thereof in two dimensions; and
a first wiring/first optical waveguide tube portion forming step of forming a first wiring and a first optical waveguide tube portion in the first insulation film.

100. A solid-state image capturing device manufacturing method according to claim 38, comprising:
a first insulation film forming step of forming a first insulation film on the semiconductor substrate having a plurality of light receiving sections formed in a surface portion thereof in two dimensions; and
a first wiring/first optical waveguide tube portion forming step of forming a first wiring and a first optical waveguide tube portion in the first insulation film.

101. A solid-state image capturing device manufacturing method according to claim 99, wherein the first wiring/first optical waveguide tube portion forming step includes:
a first resist film forming step of patterning a first resist film in the first insulation film to have shapes corresponding to a first contact plug and a part of a first optical waveguide tube portion;
a first recess shape forming step of processing first recess shapes corresponding to the first contact plug and the part of the first optical waveguide tube portion in the first insulation film using the first resist film as a mask;
a second resist film forming step of patterning a second resist film on the first insulation film to have shapes corresponding to the first wiring integrated with the first contact plug and the first optical waveguide tube portion integrated with the part of the first optical waveguide tube portion;
a second recess shape forming step of processing second recess shape corresponding to the first wiring and the first optical waveguide tube portion in the first insulation film using the second resist film as a mask;
a first metal film coating step of coating a first metal film on the first insulation film having the second recess shape formed therein; and
a step of removing the first metal film on the entire first insulation film such that the first metal film remains in the recess so as to form the first wiring and the first optical waveguide tube portion in the respective recesses.

102. A solid-state image capturing device manufacturing method according to claim 100, wherein the first wiring/first optical waveguide tube portion forming step includes:
a first resist film forming step of patterning a first resist film in the first insulation film to have shapes corresponding to a first contact plug and a part of a first optical waveguide tube portion;
a first recess shape forming step of processing first recess shapes corresponding to the first contact plug and the part of the first optical waveguide tube portion in the first insulation film using the first resist film as a mask;
a second resist film forming step of patterning a second resist film on the first insulation film to have shapes corresponding to the first wiring integrated with the first contact plug and the first optical waveguide tube portion integrated with the part of the first optical waveguide tube portion;
a second recess shape forming step of processing second recess shape corresponding to the first wiring and the first optical waveguide tube portion in the first insulation film using the second resist film as a mask;
a first metal film coating step of coating a first metal film on the first insulation film having the second recess shape formed therein; and
a step of removing the first metal film on the entire first insulation film such that the first metal film remains in the recess so as to form the first wiring and the first optical waveguide tube portion in the respective recesses.

103. A solid-state image capturing device manufacturing method according to claim 91, wherein the first wiring/first optical waveguide tube portion forming step includes:
a first resist film forming step of patterning a first resist film on the first insulation film to have a shape corresponding to the first contact plug;
a first recess shape forming step of processing a first recess shape corresponding to the first contact plug in the first insulation film using the first resist film as a mask;
a second resist film forming step of patterning a second resist film on the first insulation film to have shapes corresponding to the first wiring integrated with the contact plug and the first optical waveguide tube portion;
a second recess shape forming step of processing second recess shapes corresponding to the first wiring and the first optical waveguide tube portion in the first insulation film using the second resist film as a mask;
a first metal film coating step of coating a first metal film on the first insulation film having the second recess shape formed therein; and
a step of removing the first metal film on the entire first insulation film such that the first metal film remains in the recess so as to form the first wiring and the first optical waveguide tube portion in the respective recesses.

104. A solid-state image capturing device manufacturing method according to claim 92, wherein the first wiring/first optical waveguide tube portion forming step includes:
a first resist film forming step of patterning a first resist film on the first insulation film to have a shape corresponding to the first contact plug;
a first recess shape forming step of processing a first recess shape corresponding to the first contact plug in the first insulation film using the first resist film as a mask;
a second resist film forming step of patterning a second resist film on the first insulation film to have shapes corresponding to the first wiring integrated with the contact plug and the first optical waveguide tube portion;
a second recess shape forming step of processing second recess shapes corresponding to the first wiring and the first optical waveguide tube portion in the first insulation film using the second resist film as a mask;
a first metal film coating step of coating a first metal film on the first insulation film having the second recess shape formed therein; and
a step of removing the first metal film on the entire first insulation film such that the first metal film remains in the recess so as to form the first wiring and the first optical waveguide tube portion in the respective recesses.

105. A solid-state image capturing device manufacturing method according to claim 93, wherein the first wiring/first optical waveguide tube portion forming step includes:
a first resist film forming step of patterning a first resist film on the first insulation film to have a shape corresponding to the first contact plug;
a first recess shape forming step of processing a first recess shape corresponding to the first contact plug in the first insulation film using the first resist film as a mask;
a second resist film forming step of patterning a second resist film on the first insulation film to have shapes corresponding to the first wiring integrated with the contact plug and the first optical waveguide tube portion;
a second recess shape forming step of processing second recess shapes corresponding to the first wiring and the first optical waveguide tube portion in the first insulation film using the second resist film as a mask;
a first metal film coating step of coating a first metal film on the first insulation film having the second recess shape formed therein; and
a step of removing the first metal film on the entire first insulation film such that the first metal film remains in the recess so as to form the first wiring and the first optical waveguide tube portion in the respective recesses.

106. A solid-state image capturing device manufacturing method according to claim 94, wherein the first wiring/first optical waveguide tube portion forming step includes:
a first resist film forming step of patterning a first resist film on the first insulation film to have a shape corresponding to the first contact plug;
a first recess shape forming step of processing a first recess shape corresponding to the first contact plug in the first insulation film using the first resist film as a mask;
a second resist film forming step of patterning a second resist film on the first insulation film to have shapes corresponding to the first wiring integrated with the contact plug and the first optical waveguide tube portion;
a second recess shape forming step of processing second recess shapes corresponding to the first wiring and the first optical waveguide tube portion in the first insulation film using the second resist film as a mask;
a first metal film coating step of coating a first metal film on the first insulation film having the second recess shape formed therein; and
a step of removing the first metal film on the entire first insulation film such that the first metal film remains in the recess so as to form the first wiring and the first optical waveguide tube portion in the respective recesses.

107. A solid-state image capturing device manufacturing method according to claim 103, comprising:
a second insulation film forming step of forming a second insulation film on the first insulation film having the first wiring and the first optical waveguide tube portion provided therein; and
a second wiring/second optical waveguide tube portion forming step of forming a second wiring and a second optical waveguide tube portion in the second insulation film.

108. A solid-state image capturing device manufacturing method according to claim 105, comprising:
a second insulation film forming step of forming a second insulation film on the first insulation film having the first wiring and the first optical waveguide tube portion provided therein; and
a second wiring/second optical waveguide tube portion forming step of forming a second wiring and a second optical waveguide tube portion in the second insulation film.

109. A solid-state image capturing device manufacturing method according to claim 99, comprising:
a second insulation film forming step of forming a second insulation film on the first insulation film having the first wiring and the first optical waveguide tube portion provided therein; and
a second wiring/second optical waveguide tube portion forming step of forming a second wiring and a second optical waveguide tube portion in the second insulation film.

110. A solid-state image capturing device manufacturing method according to claim 100, comprising:
a second insulation film forming step of forming a second insulation film on the first insulation film having the first wiring and the first optical waveguide tube portion provided therein; and
a second wiring/second optical waveguide tube portion forming step of forming a second wiring and a second optical waveguide tube portion in the second insulation film.

111. A solid-state image capturing device manufacturing method according to claim 104, comprising:
a second insulation film forming step of forming a second insulation film on the first insulation film having the first wiring and the first optical waveguide tube portion provided therein; and
a second wiring/second optical waveguide tube portion forming step of forming a second wiring and a second optical waveguide tube portion in the second insulation film.

112. A solid-state image capturing device manufacturing method according to claim 106, comprising:
a second insulation film forming step of forming a second insulation film on the first insulation film having the first wiring and the first optical waveguide tube portion provided therein; and
a second wiring/second optical waveguide tube portion forming step of forming a second wiring and a second optical waveguide tube portion in the second insulation film.

113. A solid-state image capturing device manufacturing method according to claim 109, wherein the second wiring/second optical waveguide tube portion forming step includes:
a third resist film forming step of patterning a third resist film on the second insulation film to have shapes corresponding to a second contact plug and a part of a second optical waveguide tube portion;
a third recess shape forming step of processing third recess shapes corresponding to the second contact plug and the part of the second optical waveguide tube portion in the second insulation film using the third resist film as a mask;
a fourth resist film forming step of patterning a fourth resist film on the second insulation film to have shapes corresponding to the second wiring integrated with the second contact plug and the second optical waveguide tube portion integrated with the part of the second optical waveguide tube portion;
a fourth recess shape forming step of processing fourth recess shapes corresponding to the second wiring and the second optical waveguide tube portion in the second insulation film using the fourth resist film as a mask;
a second metal film coating step of coating a second metal film on the second insulation film having the fourth recess shapes formed therein; and
a step of removing the second metal film on the entire second insulation film such that the second metal film remains in recesses so as to form the second wiring and the second optical waveguide tube portion in the respective recesses.

114. A solid-state image capturing device manufacturing method according to claim 111, wherein the second wiring/second optical waveguide tube portion forming step includes:
a third resist film forming step of patterning a third resist film on the second insulation film to have shapes corresponding to a second contact plug and a part of a second optical waveguide tube portion;
a third recess shape forming step of processing third recess shapes corresponding to the second contact plug and the part of the second optical waveguide tube portion in the second insulation film using the third resist film as a mask;
a fourth resist film forming step of patterning a fourth resist film on the second insulation film to have shapes corresponding to the second wiring integrated with the second contact plug and the second optical waveguide tube portion integrated with the part of the second optical waveguide tube portion;
a fourth recess shape forming step of processing fourth recess shapes corresponding to the second wiring and the second optical waveguide tube portion in the second insulation film using the fourth resist film as a mask;
a second metal film coating step of coating a second metal film on the second insulation film having the fourth recess shapes formed therein; and
a step of removing the second metal film on the entire second insulation film such that the second metal film remains in recesses so as to form the second wiring and the second optical waveguide tube portion in the respective recesses.

115. A solid-state image capturing device manufacturing method according to claim 112, wherein the second wiring/second optical waveguide tube portion forming step includes:
a third resist film forming step of patterning a third resist film on the second insulation film to have shapes corresponding to a second contact plug and a part of a second optical waveguide tube portion;
a third recess shape forming step of processing third recess shapes corresponding to the second contact plug and the part of the second optical waveguide tube portion in the second insulation film using the third resist film as a mask;
a fourth resist film forming step of patterning a fourth resist film on the second insulation film to have shapes corresponding to the second wiring integrated with the second contact plug and the second optical waveguide tube portion integrated with the part of the second optical waveguide tube portion;
a fourth recess shape forming step of processing fourth recess shapes corresponding to the second wiring and the second optical waveguide tube portion in the second insulation film using the fourth resist film as a mask;
a second metal film coating step of coating a second metal film on the second insulation film having the fourth recess shapes formed therein; and
a step of removing the second metal film on the entire second insulation film such that the second metal film remains in recesses so as to form the second wiring and the second optical waveguide tube portion in the respective recesses.

116. A solid-state image capturing device manufacturing method according to claim 110, wherein the second wiring/second optical waveguide tube portion forming step includes:
a third resist film forming step of patterning a third resist film on the second insulation film to have shapes corresponding to a second contact plug and a part of a second optical waveguide tube portion;
a third recess shape forming step of processing third recess shapes corresponding to the second contact plug and the part of the second optical waveguide tube portion in the second insulation film using the third resist film as a mask;
a fourth resist film forming step of patterning a fourth resist film on the second insulation film to have shapes corresponding to the second wiring integrated with the second contact plug and the second optical waveguide tube portion integrated with the part of the second optical waveguide tube portion;
a fourth recess shape forming step of processing fourth recess shapes corresponding to the second wiring and the second optical waveguide tube portion in the second insulation film using the fourth resist film as a mask;
a second metal film coating step of coating a second metal film on the second insulation film having the fourth recess shapes formed therein; and
a step of removing the second metal film on the entire second insulation film such that the second metal film remains in recesses so as to form the second wiring and the second optical waveguide tube portion in the respective recesses.

117. A solid-state image capturing device manufacturing method according to claim 107, comprising:
a third insulation film forming step of forming a third insulation film on the second insulation film provided with the second wiring and the second optical waveguide tube portion; and
a third wiring/third optical waveguide tube portion forming step of forming a third wiring and a third optical waveguide tube portion in the third insulation film.

118. A solid-state image capturing device manufacturing method according to claim 108, comprising:
a third insulation film forming step of forming a third insulation film on the second insulation film provided with the second wiring and the second optical waveguide tube portion; and
a third wiring/third optical waveguide tube portion forming step of forming a third wiring and a third optical waveguide tube portion in the third insulation film.

119. A solid-state image capturing device manufacturing method according to claim 109, comprising:
a third insulation film forming step of forming a third insulation film on the second insulation film provided with the second wiring and the second optical waveguide tube portion; and
a third wiring/third optical waveguide tube portion forming step of forming a third wiring and a third optical waveguide tube portion in the third insulation film.

120. A solid-state image capturing device manufacturing method according to claim 111, comprising:
a third insulation film forming step of forming a third insulation film on the second insulation film provided with the second wiring and the second optical waveguide tube portion; and
a third wiring/third optical waveguide tube portion forming step of forming a third wiring and a third optical waveguide tube portion in the third insulation film.

121. A solid-state image capturing device manufacturing method according to claim 112, comprising:
a third insulation film forming step of forming a third insulation film on the second insulation film provided with the second wiring and the second optical waveguide tube portion; and
a third wiring/third optical waveguide tube portion forming step of forming a third wiring and a third optical waveguide tube portion in the third insulation film.

122. A solid-state image capturing device manufacturing method according to claim 110, comprising:
a third insulation film forming step of forming a third insulation film on the second insulation film provided with the second wiring and the second optical waveguide tube portion; and
a third wiring/third optical waveguide tube portion forming step of forming a third wiring and a third optical waveguide tube portion in the third insulation film.

123. A solid-state image capturing device manufacturing method according to claim 117, wherein the third wiring/third optical waveguide tube portion forming step includes:
a fifth resist film forming step of patterning a fifth resist film in the third insulation film to have shapes corresponding to a third contact plug and a part of a third optical waveguide tube portion;
a fifth recess shape forming step of processing fifth recess shapes corresponding to the third contact plug and the part of the third optical waveguide tube portion in the third insulation film using the fifth resist film as a mask;
a sixth resist film forming step of patterning a sixth resist film on the third insulation film to have shapes corresponding to the third wiring integrated with the third contact plug and the third optical waveguide tube portion integrated with the part of the third optical waveguide tube portion;
a sixth recess shape forming step of processing sixth recess shapes corresponding to the third wiring and the third optical waveguide tube portion in the third insulation film using the sixth resist film as a mask;
a third metal film coating step of coating a third metal film on the third insulation film having the sixth recess shape formed therein;
a step of removing the third metal film on the entire third insulation film such that the third metal film remains in the recess so as to form the third wiring and the third optical waveguide tube portion in the respective recesses.

124. A solid-state image capturing device manufacturing method according to claim 118, wherein the third wiring/third optical waveguide tube portion forming step includes:
a fifth resist film forming step of patterning a fifth resist film in the third insulation film to have shapes corresponding to a third contact plug and a part of a third optical waveguide tube portion;
a fifth recess shape forming step of processing fifth recess shapes corresponding to the third contact plug and the part of the third optical waveguide tube portion in the third insulation film using the fifth resist film as a mask;
a sixth resist film forming step of patterning a sixth resist film on the third insulation film to have shapes corresponding to the third wiring integrated with the third contact plug and the third optical waveguide tube portion integrated with the part of the third optical waveguide tube portion;
a sixth recess shape forming step of processing sixth recess shapes corresponding to the third wiring and the third optical waveguide tube portion in the third insulation film using the sixth resist film as a mask;
a third metal film coating step of coating a third metal film on the third insulation film having the sixth recess shape formed therein;
a step of removing the third metal film on the entire third insulation film such that the third metal film remains in the recess so as to form the third wiring and the third optical waveguide tube portion in the respective recesses.

125. A solid-state image capturing device manufacturing method according to claim 119, wherein the third wiring/third optical waveguide tube portion forming step includes:
a fifth resist film forming step of patterning a fifth resist film in the third insulation film to have shapes corresponding to a third contact plug and a part of a third optical waveguide tube portion;
a fifth recess shape forming step of processing fifth recess shapes corresponding to the third contact plug and the part of the third optical waveguide tube portion in the third insulation film using the fifth resist film as a mask;
a sixth resist film forming step of patterning a sixth resist film on the third insulation film to have shapes corresponding to the third wiring integrated with the third contact plug and the third optical waveguide tube portion integrated with the part of the third optical waveguide tube portion;
a sixth recess shape forming step of processing sixth recess shapes corresponding to the third wiring and the third optical waveguide tube portion in the third insulation film using the sixth resist film as a mask;
a third metal film coating step of coating a third metal film on the third insulation film having the sixth recess shape formed therein;
a step of removing the third metal film on the entire third insulation film such that the third metal film remains in the recess so as to form the third wiring and the third optical waveguide tube portion in the respective recesses.

126. A solid-state image capturing device manufacturing method according to claim 120, wherein the third wiring/third optical waveguide tube portion forming step includes:
a fifth resist film forming step of patterning a fifth resist film in the third insulation film to have shapes corresponding to a third contact plug and a part of a third optical waveguide tube portion;
a fifth recess shape forming step of processing fifth recess shapes corresponding to the third contact plug and the part of the third optical waveguide tube portion in the third insulation film using the fifth resist film as a mask;
a sixth resist film forming step of patterning a sixth resist film on the third insulation film to have shapes corresponding to the third wiring integrated with the third contact plug and the third optical waveguide tube portion integrated with the part of the third optical waveguide tube portion;
a sixth recess shape forming step of processing sixth recess shapes corresponding to the third wiring and the third optical waveguide tube portion in the third insulation film using the sixth resist film as a mask;
a third metal film coating step of coating a third metal film on the third insulation film having the sixth recess shape formed therein;
a step of removing the third metal film on the entire third insulation film such that the third metal film remains in the recess so as to form the third wiring and the third optical waveguide tube portion in the respective recesses.

127. A solid-state image capturing device manufacturing method according to claim 121, wherein the third wiring/third optical waveguide tube portion forming step includes:
a fifth resist film forming step of patterning a fifth resist film in the third insulation film to have shapes corresponding to a third contact plug and a part of a third optical waveguide tube portion;
a fifth recess shape forming step of processing fifth recess shapes corresponding to the third contact plug and the part of the third optical waveguide tube portion in the third insulation film using the fifth resist film as a mask;
a sixth resist film forming step of patterning a sixth resist film on the third insulation film to have shapes corresponding to the third wiring integrated with the third contact plug and the third optical waveguide tube portion integrated with the part of the third optical waveguide tube portion;
a sixth recess shape forming step of processing sixth recess shapes corresponding to the third wiring and the third optical waveguide tube portion in the third insulation film using the sixth resist film as a mask;
a third metal film coating step of coating a third metal film on the third insulation film having the sixth recess shape formed therein;
a step of removing the third metal film on the entire third insulation film such that the third metal film remains in the recess so as to form the third wiring and the third optical waveguide tube portion in the respective recesses.

128. A solid-state image capturing device manufacturing method according to claim 122, wherein the third wiring/third optical waveguide tube portion forming step includes:
a fifth resist film forming step of patterning a fifth resist film in the third insulation film to have shapes corresponding to a third contact plug and a part of a third optical waveguide tube portion;
a fifth recess shape forming step of processing fifth recess shapes corresponding to the third contact plug and the part of the third optical waveguide tube portion in the third insulation film using the fifth resist film as a mask;
a sixth resist film forming step of patterning a sixth resist film on the third insulation film to have shapes corresponding to the third wiring integrated with the third contact plug and the third optical waveguide tube portion integrated with the part of the third optical waveguide tube portion;
a sixth recess shape forming step of processing sixth recess shapes corresponding to the third wiring and the third optical waveguide tube portion in the third insulation film using the sixth resist film as a mask;
a third metal film coating step of coating a third metal film on the third insulation film having the sixth recess shape formed therein;
a step of removing the third metal film on the entire third insulation film such that the third metal film remains in the recess so as to form the third wiring and the third optical waveguide tube portion in the respective recesses.

129. A solid-state image capturing device manufacturing method according to claim 99, comprising:
an Nth (N is an integer greater than or equal to 2) insulation film forming step of forming an Nth insulation film on an (N−1)th insulation film provided with an (N−1)th wiring and an (N−1)th optical waveguide tube portion; and
an Nth wiring/Nth optical waveguide tube portion forming step of forming an Nth wiring and an Nth optical waveguide tube portion in the Nth insulation film.

130. A solid-state image capturing device manufacturing method according to claim 100, comprising:
an Nth (N is an integer greater than or equal to 2) insulation film forming step of forming an Nth insulation film on an (N−1)th insulation film provided with an (N−1)th wiring and an (N−1)th optical waveguide tube portion; and
an Nth wiring/Nth optical waveguide tube portion forming step of forming an Nth wiring and an Nth optical waveguide tube portion in the Nth insulation film.

131. A solid-state image capturing device manufacturing method according to claim 129, wherein the Nth wiring/Nth optical waveguide tube portion forming step includes:
a (2N−1)th resist film forming step of patterning a (2N−1)th resist film on the Nth insulation film to have shapes corresponding to an Nth contact plug and a part of a Nth optical waveguide tube portion;
a (2N−1) th recess shape forming step of processing (2N−1)th recess shapes corresponding to the Nth contact plug and the part of the Nth optical waveguide tube portion in the Nth insulation film using the (2N−1)th resist film as a mask;
a 2Nth resist film forming step of patterning a 2N resist film in the Nth insulation film to have shapes corresponding to an Nth wiring integrated with the Nth contact plug and an Nth optical waveguide tube portion integrated with the part of the Nth optical waveguide tube portion;
a 2Nth recess shape forming step of processing 2Nth recess shapes corresponding to the Nth wiring and the Nth optical waveguide tube portion in the Nth insulation film using the 2N resist film as a mask;
an Nth metal film coating step of coating an Nth metal film on the Nth insulation film having the (2N−1)th recess shape and the 2Nth recess shape formed therein; and
a step of removing the Nth metal film on the entire Nth insulation film such that the Nth metal film remains in the recesses so as to form the Nth wiring and the Nth optical waveguide tube portion in the respective recesses.

132. A solid-state image capturing device manufacturing method according to claim 130, wherein the Nth wiring/Nth optical waveguide tube portion forming step includes:
a (2N−1)th resist film forming step of patterning a (2N−1)th resist film on the Nth insulation film to have shapes corresponding to an Nth contact plug and a part of a Nth optical waveguide tube portion;
a (2N−1) th recess shape forming step of processing (2N−1)th recess shapes corresponding to the Nth contact plug and the part of the Nth optical waveguide tube portion in the Nth insulation film using the (2N−1)th resist film as a mask;
a 2Nth resist film forming step of patterning a 2N resist film in the Nth insulation film to have shapes corresponding to an Nth wiring integrated with the Nth contact plug and an Nth optical waveguide tube portion integrated with the part of the Nth optical waveguide tube portion;
a 2Nth recess shape forming step of processing 2Nth recess shapes corresponding to the Nth wiring and the Nth optical waveguide tube portion in the Nth insulation film using the 2N resist film as a mask;
an Nth metal film coating step of coating an Nth metal film on the Nth insulation film having the (2N−1)th recess shape and the 2Nth recess shape formed therein; and
a step of removing the Nth metal film on the entire Nth insulation film such that the Nth metal film remains in the recesses so as to form the Nth wiring and the Nth optical waveguide tube portion in the respective recesses.

133. A solid-state image capturing device manufacturing method according to claim 87, further comprising:
an (N+1)th insulation film forming step of forming an (N+1)th insulation film on the substrate having the Nth wiring and the 2Nth optical waveguide tube portion formed thereon;
a color filter forming step of forming color filters arranged for respective colors on the (N+1)th insulation film;
an (N+2)th insulation film forming step of forming an (N+2)th insulation film on the color filters; and
a microlens forming step of forming microlenses on the (N+2)th insulation film.

134. (51) A solid-state image capturing device manufacturing method according to claim 89, further comprising:
an (N+1)th insulation film forming step of forming an (N+1)th insulation film on the substrate having the Nth wiring and the 2Nth optical waveguide tube portion formed thereon;
a color filter forming step of forming color filters arranged for respective colors on the (N+1)th insulation film;
an (N+2)th insulation film forming step of forming an (N+2)th insulation film on the color filters; and
a microlens forming step of forming microlenses on the (N+2)th insulation film.

135. A solid-state image capturing device manufacturing method according to claim 129, further comprising:
an (N+1)th insulation film forming step of forming an (N+1)th insulation film on the substrate having the Nth wiring and the 2Nth optical waveguide tube portion formed thereon;
a color filter forming step of forming color filters arranged for respective colors on the (N+1)th insulation film;
an (N+2)th insulation film forming step of forming an (N+2)th insulation film on the color filters; and
a microlens forming step of forming microlenses on the (N+2)th insulation film.

136. A solid-state image capturing device manufacturing method according to claim 88, further comprising:
an (N+1)th insulation film forming step of forming an (N+1)th insulation film on the substrate having the Nth wiring and the 2Nth optical waveguide tube portion formed thereon;
a color filter forming step of forming color filters arranged for respective colors on the (N+1)th insulation film;
an (N+2)th insulation film forming step of forming an (N+2)th insulation film on the color filters; and
a microlens forming step of forming microlenses on the (N+2)th insulation film.

137. A solid-state image capturing device manufacturing method according to claim 90, further comprising:
an (N+1)th insulation film forming step of forming an (N+1)th insulation film on the substrate having the Nth wiring and the 2Nth optical waveguide tube portion formed thereon;
a color filter forming step of forming color filters arranged for respective colors on the (N+1)th insulation film;
an (N+2)th insulation film forming step of forming an (N+2)th insulation film on the color filters; and
a microlens forming step of forming microlenses on the (N+2)th insulation film.

138. (51) A solid-state image capturing device manufacturing method according to claim 130, further comprising:
an (N+1)th insulation film forming step of forming an (N+1)th insulation film on the substrate having the Nth wiring and the 2Nth optical waveguide tube portion formed thereon;
a color filter forming step of forming color filters arranged for respective colors on the (N+1)th insulation film;
an (N+2)th insulation film forming step of forming an (N+2)th insulation film on the color filters; and
a microlens forming step of forming microlenses on the (N+2)th insulation film.

139. A solid-state image capturing device manufacturing method for, on a semiconductor substrate having a plurality of light receiving sections in two dimensions at a surface portion thereof, forming a plural-layered conductive films via respective insulation films on a region other than a region right above the light receiving section, and forming an optical waveguide above a light receiving section, the method comprising:
a contact plug/first optical waveguide tube portion forming step of forming a first optical waveguide tube portion with the same material as the contact plug at the same time when the contact plug is processed and formed, the optical waveguide tube portion configuring a part of the optical waveguide and the contact plug electrically connecting at least one of between the semiconductor substrate and plural-layered conductive films, and between the plural-layered conductive films.

140. A solid-state image capturing device manufacturing method according to claim 139, comprising:
a conductive film/second optical waveguide tube portion forming step of forming a second optical waveguide tube portion so as to laminate it on the first optical waveguide tube portion simultaneously when a single-layered conductive film or at least one of plural-layered conductive films is formed, the second optical waveguide tube portion being formed using the same material as that for the conductive film, and the second optical waveguide tube portion configuring a part of the optical waveguide.

141. A solid-state image capturing device manufacturing method according to claim 139, wherein the contact plug/first optical waveguide tube portion forming step includes:
a first insulation film forming step of forming a first insulation film on the semiconductor substrate;
a first contact plug forming step of forming a first contact plug in the first insulation film;
a first wiring film forming step of forming a first wiring on the first insulation film having the first contact plug formed therein;
a second insulation film forming-step of forming a second insulation film on the substrate having the first wiring formed thereon; and
a second contact plug/first optical waveguide tube portion forming step of forming a second contact plug in the second insulation film and simultaneously forming a first optical waveguide tube portion in the second insulation film and the first insulation film or only in the second insulation film.

142. A solid-state image capturing device manufacturing method according to claim 139, wherein the contact plug/first optical waveguide tube portion forming step includes:
a first insulation film forming step of forming a first insulation film on the semiconductor substrate;
a first contact plug forming step of forming a first contact plug in the first insulation film;
a first wiring film forming step of forming a first wiring film on the first insulation film having the first contact plug formed therein;
a second insulation film forming step of forming a second insulation film on the substrate having the first wiring formed thereon;
a second contact plug forming step of forming a second contact plug in the second insulation film;
a second wiring film forming step of forming a second wiring on the second insulation film having the second contact plug formed therein;
a third insulation film forming step of forming a third insulation film on the substrate having the second wiring formed thereon; and
a third contact plug/first optical waveguide tube portion forming step of forming a first optical waveguide tube portion in the third insulation film, the second insulation film and the first insulation film or only in the third insulation film and the second insulation film simultaneously when a third contact plug is formed in the third insulation film.

143. A solid-state image capturing device manufacturing method according to claim 141, wherein the conductive film/second optical waveguide tube portion forming step includes:
a second wiring forming step of forming a second wiring on the second insulation film having the second contact plug and the first optical waveguide tube portion formed therein;
a third insulation film forming step of forming a third insulation film on the substrate having the second wiring formed thereon;
a third contact plug/second optical waveguide tube portion partially forming step of forming a third contact plug and a part of a second optical waveguide tube portion in the third insulation film; and
a third wiring/second optical waveguide tube forming step of forming a third wiring and the rest of the second optical waveguide tube portion on the third insulation film having the third contact plug and the part of the optical waveguide tube portion formed therein.

144. An electronic information device using the solid-state image capturing device according to claim 1 as an image capturing section.

145. An electronic information device using the solid-state image capturing device according to claim 2 as an image capturing section.
